(19) United States
(12) Patent Application Publication
(10) Pub. No.: US 2026/0196163 A1
(43) Pub. Date: Jul. 9, 2026

(54) DISPLAY DEVICE AND ELECTRONIC DEVICE INCLUDING THE SAME

(71) Applicant: Samsung Display Co., Ltd., Yongin-si (KR)

(72) Inventors: Sun Hwa LEE, Yongin-si (KR); Ji Sun KIM, Yongin-si (KR); Kwi Hyun KIM, Yongin-si (KR); Se Hyun LEE, Yongin-si (KR); Kyung Hoon CHUNG, Yongin-si (KR)

(21) Appl. No.: 19/348,431

(22) Filed: Oct. 2, 2025

(30) Foreign Application Priority Data
Jan. 6, 2025 (KR) 10-2025-0001687

(51) Int. Cl. G09G 3/32; G09G 3/3241; H10H 29/49

(52) U.S. Cl. CPC G09G 3/32; H10H 29/49; G09G 3/3241; G09G 2300/0426; G09G 2300/0819; G09G 2300/0852; G09G 2300/0861; G09G 2310/08; G09G 2320/0223; G09G 2320/045; G09G 2330/021

(57) ABSTRACT

A display device includes a pixel located in a display area where an image is displayed, and including a first sub-pixel including a first pixel circuit, a second sub-pixel including a second pixel circuit, and a third sub-pixel including a third pixel circuit, a first emission control line electrically connected to the first pixel circuit, a second emission control line electrically connected to the second pixel circuit and the third pixel circuit, and first power lines electrically connected to the first pixel circuit, the second pixel circuit, and the third pixel circuit, the first power lines arranged along a first direction in the display area and extending in a second direction, wherein the first pixel circuit, the second pixel circuit, and the third pixel circuit are arranged along the first direction in the display area, the first pixel circuit overlaps a first power line of the first power lines.

### CROSS-REFERENCE TO RELATED APPLICATION

This application claims priority to and the benefit of Korean Patent Application No. 10-2025-0001687, filed on Jan. 6, 2025, in the Korean Intellectual Property Office, the entire disclosure of which is incorporated by reference herein.

### BACKGROUND

### 1. Field

Embodiments of the present disclosure relate to a display device and an electronic device including the same.

### 2. Description of the Related Art

With the advance of information-oriented society, more and more demands are placed on display devices for displaying images in various ways. For example, display devices are included in various electronic devices and are used as display screens of the electronic devices. Along with this trend, various types of display devices including a light emitting display device are being developed.

### SUMMARY

Aspects of the present disclosure provide a display device capable of efficiently arranging pixel circuits and wires in a display area, and an electronic device including the same.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the present disclosure, there is provided a display device including a pixel located in a display area where an image is displayed, the pixel including a first sub-pixel including a first pixel circuit, a second sub-pixel including a second pixel circuit, and a third sub-pixel including a third pixel circuit, a first emission control line electrically connected to the first pixel circuit, a second emission control line electrically connected to the second pixel circuit and the third pixel circuit, and first power lines electrically connected to the first pixel circuit, the second pixel circuit, and the third pixel circuit, the first power lines being arranged along a first direction in the display area, and extending in a second direction, wherein the first pixel circuit, the second pixel circuit, and the third pixel circuit are arranged along the first direction in the display area, the first pixel circuit overlaps a first power line of the first power lines, and the second pixel circuit and the third pixel circuit overlap an other first power line of the first power lines and have a symmetrical shape with respect to the other first power line.

In one or more embodiments, the second pixel circuit and the third pixel circuit may be commonly connected to the other first power line and have a symmetrical shape with respect to the other first power line.

In one or more embodiments, display device may further include data lines arranged along the first direction in the display area, the data lines including a first data line electrically connected to the first pixel circuit, a second data line electrically connected to the second pixel circuit, and a third data line electrically connected to the third pixel circuit.

In one or more embodiments, each of the first pixel circuit, the second pixel circuit, and the third pixel circuit may include a first transistor configured to adjust a driving current in response to a data voltage transmitted from the first data line, the second data line or the third data line, and a second transistor electrically connected between the first data line, the second data line, or the third data line and the first transistor.

In one or more embodiments, the first transistor may include an active layer, a gate electrode overlapping a part of the active layer, and a source electrode and a drain electrode electrically connected to different portions of the active layer.

In one or more embodiments, the first transistors of the first pixel circuit, the second pixel circuit, and the third pixel circuit may be arranged sequentially along the first direction, the drain electrode of the first transistor in the first pixel circuit and the source electrode of the first transistor in the second pixel circuit may be adjacent to each other in the first direction, and the drain electrode of the first transistor in the second pixel circuit and the drain electrode of the first transistor in the third pixel circuit may be adjacent to each other in the first direction.

In one or more embodiments, a size of the first transistor in the first pixel circuit may be different from a size of the first transistor in each of the second pixel circuit and the third pixel circuit.

In one or more embodiments, each of the first pixel circuit, the second pixel circuit, and the third pixel circuit may further include a third transistor and a fourth transistor including an oxide semiconductor, which are commonly connected to the gate electrode of the first transistor through a first connection electrode, and the third transistor and the fourth transistor of the second pixel circuit may be adjacent to the third transistor and the fourth transistor of the third pixel circuit in the first direction.

In one or more embodiments, the first power line may cover the first transistor, the third transistor, and the fourth transistor in the first pixel circuit, and the other first power line may cover the first transistors, the third transistors, and the fourth transistors in the second pixel circuit and the third pixel circuit.

In one or more embodiments, the first emission control line and the second emission control line may be adjacent to each other in the second direction and each may extend in the first direction.

In one or more embodiments, each of the first pixel circuit, the second pixel circuit and the third pixel circuit may further include a fifth transistor and a sixth transistor including respective active layers crossing the first emission control line and the second emission control line and respective gate electrodes overlapping parts of the respective active layers.

In one or more embodiments, the active layer of the fifth transistor may extend from one end of the active layer of the first transistor, may have a U or Y shape around the first emission control line and the second emission control line, and may cross the first emission control line and the second emission control line, and the active layer of the sixth transistor may extend from an other end of the active layer of the first transistor, and may be electrically connected to a light emitting element located above the first pixel circuit, the second pixel circuit, or the third pixel circuit.

In one or more embodiments, one end of the active layer of the fifth transistor may be electrically connected to the first power line or the other first power line.

In one or more embodiments, the second sub-pixel and the third sub-pixel may further include one second connection electrode overlapping the other first power line and extending in the first direction in a region where the second pixel circuit and the third pixel circuit are located, and the active layers of the fifth transistors in the second pixel circuit and the third pixel circuit may be commonly connected to the one second connection electrode and may be electrically connected to the other first power line through the one second connection electrode.

In one or more embodiments, the gate electrodes of the fifth transistor and the sixth transistor in the first pixel circuit may be formed as one conductive pattern overlapping the first emission control line, and the one conductive pattern may be electrically connected to the first emission control line through one contact hole located between the fifth transistor and the sixth transistor.

In one or more embodiments, the gate electrodes of the fifth transistors and the sixth transistors in the second pixel circuit and the third pixel circuit may be formed as one conductive pattern overlapping the second emission control line, and the one conductive pattern may be electrically connected to the second emission control line through one contact hole located between the second pixel circuit and the third pixel circuit.

In one or more embodiments, the first data line may be located between a data line electrically connected to a third sub-pixel of another pixel adjacent to the first sub-pixel in the first direction and the first power line, the second data line may be located between the first power line and the other first power line, and the third data line may be located between the other first power line and a data line electrically connected to a first sub-pixel of another pixel adjacent to the third sub-pixel in the first direction.

In one or more embodiments, the first sub-pixel may be further include a first light emitting element electrically connected to the first pixel circuit through a first anode contact hole overlapping the first pixel circuit, the second sub-pixel may further include a second light emitting element electrically connected to the second pixel circuit through a second anode contact hole overlapping the second pixel circuit, the third sub-pixel may further include a third light emitting element electrically connected to the third pixel circuit through a third anode contact hole overlapping the third pixel circuit, and the other first power line may pass through a region between the second anode contact hole and the third anode contact hole.

In one or more embodiments, display device may further include a second power line located between the first pixel circuit and the second pixel circuit, or between the pixel and another pixel adjacent to the pixel in the first direction, and the second power line may be electrically connected to the first light emitting element, the second light emitting element, and the third light emitting element through a cathode contact hole.

According to one or more embodiments of the present disclosure, there is provided an electronic device including a display device including a display area where an image is displayed, wherein the display device includes a pixel located in the display area, the pixel including a first sub-pixel including a first pixel circuit, a second sub-pixel including a second pixel circuit, and a third sub-pixel including a third pixel circuit, a first emission control line electrically connected to the first pixel circuit, a second emission control line electrically connected to the second pixel circuit and the third pixel circuit, and first power lines electrically connected to the first pixel circuit, the second pixel circuit, and the third pixel circuit, the first power lines being arranged along a first direction in the display area, and extending in a second direction, wherein the first pixel circuit, the second pixel circuit, and the third pixel circuit are arranged along the first direction in the display area, the first pixel circuit overlaps a first power line of the first power lines, and the second pixel circuit and the third pixel circuit overlap an other first power line of the first power lines and have a symmetrical shape with respect to the other first power line.

In accordance with the display device and the electronic device including the same according to one or more embodiments, the design structure of the display area may be improved. For example, among first, second, and third sub-pixels constituting one pixel, the second sub-pixel and the third sub-pixel are designed to be symmetrical in a flipped shape, thereby efficiently arranging the pixel circuits and the wires in the display area. Accordingly, the design structure of the display area may be optimized and an additional design space may be secured.

In one or more embodiments, a second power line may be located in the space secured by efficiently arranging the pixel circuits and the wires. Accordingly, a voltage drop of a driving voltage applied to a common electrode through the second power line may be prevented, and the image quality and power consumption of the display device may be improved.

In one or more embodiments, the first sub-pixel and the second and third sub-pixels may be connected to different emission control lines. Accordingly, the emission period of the first sub-pixel and the emission period of the second and third sub-pixels may be controlled independently or individually. For example, the driving current of the first sub-pixel and the driving current of the second and third sub-pixels are appropriately adjusted or differentiated according to the optimal consumption efficiency of the light emitting elements included in the sub-pixels, and the emission period of the first sub-pixel and the emission period of the second and third sub-pixels are adjusted according to the respective driving currents, thereby the luminance of the sub-pixels may be maintained uniformly. Accordingly, the lifespan, image quality, and power consumption of the display device may be improved.

However, effects, aspects, and features of embodiments of the present disclosure are not limited to those discussed above and various other effects, aspects, and features are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to one or more embodiments;

FIG. 2 is a plan view illustrating a display panel according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is a waveform diagram showing driving signals of a sub-pixel according to one or more embodiments;

FIG. 6 is a plan view showing pixel circuits, signal lines, and power lines located in a backplane layer of a display panel according to one or more embodiments;

FIG. 7 is a plan view showing pixel circuits, signal lines, and power lines located in a backplane layer of a display panel according to one or more embodiments;

FIG. 8 is a plan view showing pixel circuits, signal lines, and power lines located in a backplane layer of a display panel according to one or more embodiments;

FIG. 9 is a layout diagram showing a backplane layer of a display panel according to one or more embodiments;

FIG. 10 is a layout diagram showing in detail the first pixel circuit of FIG. 9;

FIG. 11 is a layout diagram showing in detail the second pixel circuit of FIG. 9;

FIG. 12 is a layout diagram showing in detail the third pixel circuit of FIG. 9;

FIG. 13 is a layout diagram showing patterns included in a first semiconductor layer, a first gate conductive layer, a second semiconductor layer, and a third gate conductive layer of a backplane layer according to one or more embodiments;

FIG. 14 is a layout diagram showing patterns included in a first gate conductive layer and a second gate conductive layer according to one or more embodiments;

FIG. 15 is a layout diagram showing patterns included in a first source-drain conductive layer and a second source-drain conductive layer of a backplane layer according to one or more embodiments;

FIG. 16 is a layout diagram showing in detail a part of a first pixel circuit, a second pixel circuit, and a third pixel circuit according to one or more embodiments;

FIG. 17 is a layout diagram showing in detail a part of a first pixel circuit, a second pixel circuit, and a third pixel circuit according to one or more embodiments;

FIG. 18 is a layout diagram illustrating a light emitting element layer of a display panel according to one or more embodiments;

FIG. 19 is a cross-sectional view showing an example of a cross-section of the display panel corresponding to the line X1-X1′ of FIGS. 9 and 18;

FIG. 20 is a cross-sectional view showing an area A2 of FIG. 19 in detail;

FIG. 21 is a cross-sectional view showing an example of a cross-section of the display panel corresponding to the lines X2-X2′ and X3-X3′ of FIGS. 9 and 18;

FIG. 22 is a cross-sectional view showing an example of a cross-section of the display panel corresponding to the line X1-X1′ of FIGS. 9 and 18;

FIG. 23 is a diagram illustrating a smart watch including a display device according to one or more embodiments;

FIGS. 24 and 25 are views illustrating a head mounted display including a display device according to one or more embodiments;

FIG. 26 is a view illustrating a head mounted display including a display device according to one or more embodiments;

FIG. 27 is a diagram illustrating a center fascia and a dashboard of an automobile including display devices according to one or more embodiments; and

FIG. 28 is a diagram illustrating a transparent display device including a display device according to one or more embodiments.

FIG. 29 is a block diagram of an electronic device according to one or more embodiments of the present disclosure.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that the present disclosure will be thorough and complete, and will fully convey the scope of the present disclosure to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

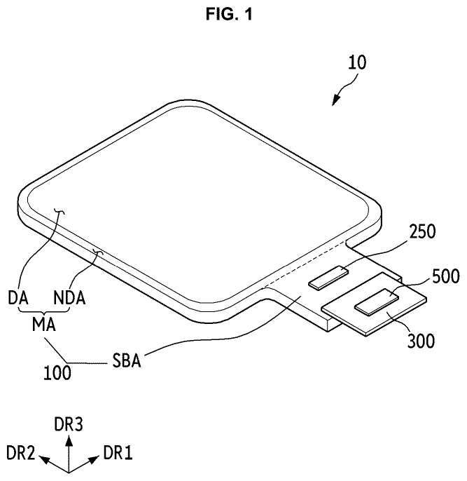

FIG. 1 is a perspective view illustrating a display device according to one or more embodiments.

Referring to FIG. 1, a display device 10, which is a device for displaying a moving image or a still image, may be included in various electronic devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC) and used as a display screen. In addition, the display device 10 may be included in other electronic devices such as a virtual reality (VR) device, an augmented reality (AR) device, and/or the like and used to display an image in the electronic device. In one or more embodiments, the electronic device including the display device 10 may further include a display device housing in which the display device 10 is accommodated and/or a case or cover for protecting the display device 10.

In one or more embodiments, the display device 10 may be a light emitting display device such as an organic light emitting display using an organic light emitting diode (OLED), a quantum dot light emitting display including a quantum dot light emitting layer, an inorganic light emitting display including an inorganic semiconductor, and a micro or nano light emitting display using a micro or nano light emitting diode (LED). In the following description, it is assumed that the display device 10 is a micro light emitting display device, but the present disclosure is not limited thereto. For simplicity of description, an ultra-small light emitting diode is referred to hereafter as a light emitting element.

The display device 10 may include a display panel 100, a display driving circuit 250, a circuit board 300, and a power supply circuit (e.g., a power supply unit) 500.

The display panel 100 may, in a plan view, be formed in a rectangular shape having short sides in a first direction DR1 and long sides in a second direction DR2 crossing the first direction DR1. The corner where the short side in the first direction DR1 and the long side in the second direction DR2 meet may be rounded or right-angled. The planar shape of the display panel 100 is not limited to the rectangular shape, and may be formed in another polygonal shape, a circular shape, or an elliptical shape. The display panel 100 may be formed to be flat, but is not limited thereto. For example, the display panel 100 may include a curved portion formed at left and right ends and having a constant curvature or a varying curvature. In one or more embodiments, the display panel 100 may be formed flexibly such that it may be curved, bent, folded, and/or rolled.

The display panel 100 may include a main region MA and a sub-region SBA.

The main region MA may include a display area DA for displaying an image and a non-display area NDA that is a peripheral area of the display area DA and disposed around the display area DA along an edge or a periphery of the display area DA. The display area DA may include pixels for displaying an image. Each of the pixels may include a plurality of sub-pixels. For example, each of the pixels may include a first sub-pixel that emits light of a first color (or first light), a second sub-pixel that emits light of a second color (or second light), and a third sub-pixel that emits light of a third color (or third light), but the present disclosure is not limited thereto.

The sub-region SBA may protrude from one side of the main region MA in the second direction DR2 (e.g., the longitudinal direction of the display panel 100). Although it is shown in FIG. 1 as an example that the sub-region SBA is unfolded, the sub-region SBA may be bent and, in this case, arranged on the bottom surface of the display panel 100. In the case where the sub-region SBA is bent, it may overlap the main region MA in a third direction DR3 that is a thickness direction of the display panel 100. The display driving circuit 250 may be arranged in the sub-region SBA.

The display driving circuit 250 may generate signals and voltages for driving the display panel 100. The display driving circuit 250 may be formed as an integrated circuit (IC) and attached onto the display panel 100 by a chip on glass (COG) method, a chip on plastic (COP) method, and/or an ultrasonic bonding method, but the present disclosure is not limited thereto. For example, the display driving circuit 250 may be attached onto the circuit board 300 by a chip on film (COF) method.

The circuit board 300 may be attached to one end of the sub-region SBA of the display panel 100. Thus, the circuit board 300 may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board (FPCB), a printed circuit board (PCB), or a flexible film such as a chip on film.

The power supply circuit 500 may generate panel driving voltages according to a power voltage supplied from the outside. The power supply circuit 500 may be formed as an integrated circuit (IC) and attached to the circuit board 300 by a COF method.

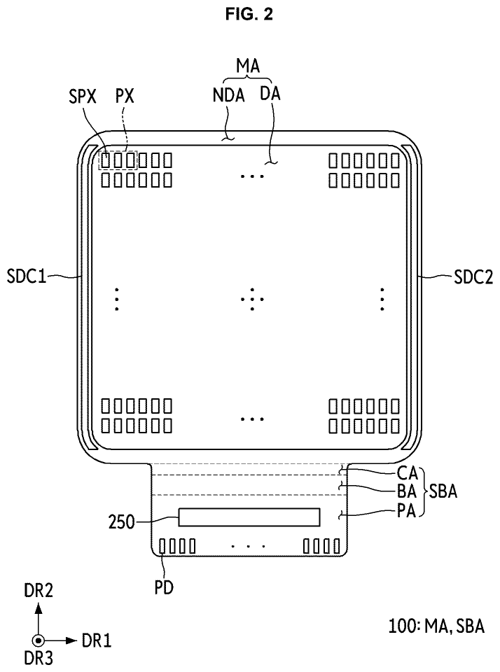

FIG. 2 is a plan view illustrating a display panel according to one or more embodiments. It is shown in FIG. 2 as an example that the sub-region SBA is unfolded without being bent.

Referring to FIGS. 1 and 2, the display panel 100 may include the main region MA and the sub-region SBA.

The main region MA may include the display area DA for displaying an image and the non-display area NDA that is a peripheral area of the display area DA. The display area DA may occupy most of the main region MA. The display area DA may be located at the center of the main region MA.

The display area DA may include pixels PX for displaying an image, and each of the pixels PX may include a plurality of sub-pixels SPX. The pixel PX may be defined as a minimum unit sub-pixel group capable of expressing a white grayscale.

The non-display area NDA may be located adjacent to the display area DA. The non-display area NDA may be an area outside the display area DA. The non-display area NDA may be located to surround the display area DA. The non-display area NDA may be an edge area of the display panel 100.

A first scan driver SDC1 and a second scan driver SDC2 may be located in the non-display area NDA. The first scan driver SDC1 may be located at one side (for example, left side) of the display panel 100, and the second scan driver SDC2 may be located at the other side (for example, right side) of the display panel 100, but the present disclosure is not limited thereto. Each of the first scan driver SDC1 and the second scan driver SDC2 may be electrically connected to the display driving circuit 250 through scan fan-out lines. Each of the first scan driver SDC1 and the second scan driver SDC2 may receive scan control signals inputted from the display driving circuit 250, generate scan signals in response to the scan control signals, and output the generated scan signals to scan lines.

The sub-region SBA may protrude from one side of the main region MA in the second direction DR2. The length of the sub-region SBA in the second direction DR2 may be less than the length of the main region MA in the second direction DR2. The length of the sub-region SBA in the first direction DR1 may be substantially equal to or less than the length of the main region MA in the first direction DR1. The sub-region SBA may be foldable to be located under the main region MA. In this case, the sub-region SBA may overlap the main region MA in the third direction DR3.

The sub-region SBA may include a connection area CA, a pad area PA, and a bending area BA.

The connection area CA is an area protruding from one side of the main region MA in the second direction DR2. One side of the connection area CA may be in contact with the non-display area NDA of the main region MA, and the other side of the connection area CA may be in contact with the bending area BA.

The pad area PA is an area on which pads PD and the display driving circuit 250 are arranged. The display driving circuit 250 may be attached to driving pads of the pad area PA using a conductive adhesive member such as an anisotropic conductive film. The circuit board 300 may be attached to the pads PD of the pad area PA using a conductive adhesive member such as an anisotropic conductive film. One side of the pad area PA may be in contact with the bending area BA.

The bending area BA is an area that is being bent. When the bending area BA is bent, the pad area PA may be located under the connection area CA and the main region MA. The bending area BA may be located between the connection area CA and the pad area PA. One side of the bending area BA may be in contact with the connection area CA, and the other side of the bending area BA may be in contact with the pad area PA.

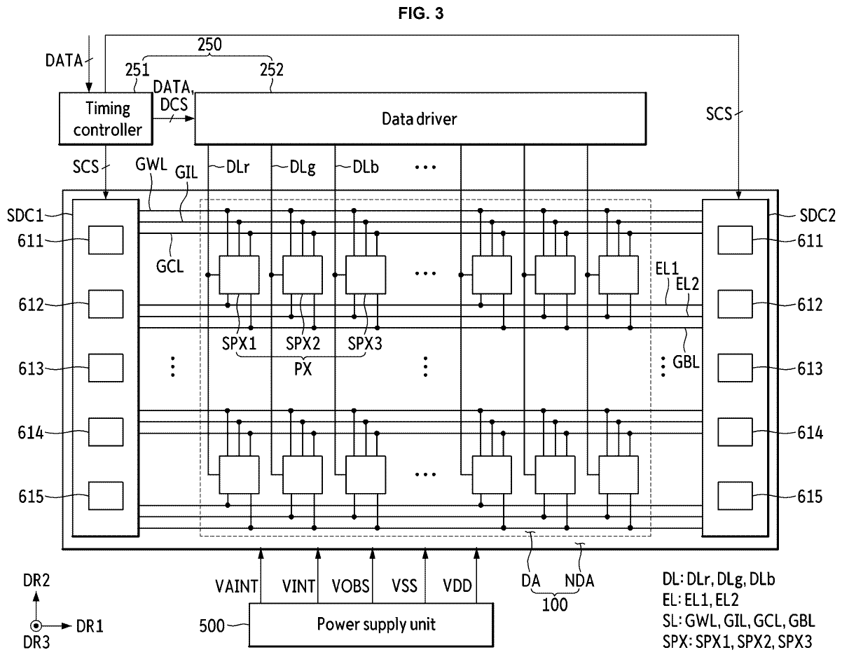

FIG. 3 is a block diagram illustrating a display device according to one or more embodiments.

Referring to FIG. 3, the display area DA may include pixels PX, scan lines SL, emission control lines EL, and data lines DL.

The pixels PX may be arranged along the first direction DR1 and the second direction DR2. For example, the pixels PX may be arranged in a matrix form along the first direction DR1 and the second direction DR2. For example, the pixels PX may be arranged along rows and columns of a matrix. The scan lines SL and the emission control lines EL may extend in the first direction DR1 and be arranged or located along the second direction DR2. The data lines DL may extend in the second direction DR2 and may be arranged or located along the first direction DR1. The scan lines SL may include write scan lines GWL, initialization scan lines GIL, control scan lines GCL, and bias scan lines GBL. The configuration or number of the scan lines SL may be different according to the structure and/or driving method of the pixels PX.

Each of the pixels PX may include a plurality of sub-pixels SPX. For example, each of the pixels PX may include a first sub-pixel SPX1, a second sub-pixel SPX2, and a third sub-pixel SPX3. The first sub-pixel SPX1, the second sub-pixel SPX2, and the third sub-pixel SPX3 may emit light of a first color, light of a second color, and light of a third color, respectively. The light of the first color, the light of the second color, and the light of the third color may be red light (for example, light in a red wavelength band having a main peak wavelength of about 600 nm to 750 nm), green light (for example, light in a green wavelength band having a main peak wavelength of about 480 nm to 560 nm), and blue light (for example, light in a blue wavelength band having a main peak wavelength of about 370 nm to 460 nm), respectively, but the present disclosure is not limited thereto. In one or more embodiments, the first sub-pixel SPX1, the second sub-pixel SPX2, and the third sub-pixel SPX3 of each of the pixels PX may be arranged along the first direction DR1. The number, type, arrangement structure, and/or emission wavelength of the sub-pixels SPX included in each of the pixels PX may vary depending on the embodiments.

Each of the sub-pixels SPX may be connected to one of the write scan lines GWL, one of the initialization scan lines GIL, one of the control scan lines GCL, one of the bias scan lines GBL, one of the emission control lines EL, and one of the data lines DL. In describing embodiments, “connection” may include “physical connection” and/or “electrical connection.”

Each of the plurality of sub-pixels SPX may receive the data voltage of the data line DL according to the write scan signal of the write scan line GWL, and may cause a light emitting element to emit light according to the data voltage. The plurality of sub-pixels SPX included in each pixel PX may be connected to the different data lines DL. For example, the first sub-pixel SPX1, the second sub-pixel SPX2, and the third sub-pixel SPX3 may be respectively connected to a first data line DLr, a second data line DLg, and a third data line DLb. Accordingly, the luminance of each of the first sub-pixel SPX1, the second sub-pixel SPX2, and the third sub-pixel SPX3 may be controlled individually.

In one or more embodiments, each of the pixels PX may be connected to two or more emission control lines EL, and an emission period (or on-duty ratio) of at least two of the sub-pixels SPX included in each pixel PX may be controlled independently and/or individually by different emission control signals supplied to the different emission control lines EL. For example, in each horizontal line (e.g., each pixel row) of the display area DA, a first emission control line EL1 and a second emission control line EL2, which are connected to different sub-pixels SPX from among the sub-pixels SPX of the pixels PX arranged on the corresponding horizontal line, may be located. For example, the first emission control line EL1 may be connected to the first sub-pixels SPX1 of the pixels PX arranged on the corresponding horizontal line, and the second emission control line EL2 may be connected to the second sub-pixels SPX2 and the third sub-pixels SPX3 included in the pixels PX of the corresponding horizontal line.

The first sub-pixel SPX1 may emit light during a first emission period in response to a first emission control signal supplied through the first emission control line EL1. The first emission period may be a period during which a driving current may flow through the first sub-pixel SPX1 by the first emission control signal. The second sub-pixel SPX2 and the third sub-pixel SPX3 may emit light during a second emission period in response to a second emission control signal supplied through the second emission control line EL2. The second emission period may be a period during which a driving current may flow through the second sub-pixel SPX2 and the third sub-pixel SPX3 by the second emission control signal. The first emission period and the second emission period may be controlled independently or individually, and may or may not temporally overlap each other.

In one or more embodiments, the duration of the first emission period may be different from the duration of the second emission period. For example, the duration of the first emission period may correspond to an on-duty ratio adjusted to allow the first sub-pixel SPX1 to emit light with a desired luminance according to a driving current optimized according to the luminous efficiency of the first sub-pixel SPX1 (e.g., a driving current in a range in which the light emitting element of the first sub-pixel SPX1 exhibits the optimal consumption efficiency). The duration of the second emission period may correspond to an on-duty ratio adjusted to allow the second sub-pixel SPX2 and the third sub-pixel SPX3 to emit light with a desired luminance according to a driving current optimized according to the luminous efficiency of the second sub-pixel SPX2 and the third sub-pixel SPX3 (e.g., a driving current in a range in which the light emitting elements of the second sub-pixel SPX2 and the third sub-pixel SPX3 exhibit the optimal consumption efficiency). In this case, an emission control signal output unit 615 included in the first scan driver SDC1 and the second scan driver SDC2 may output emission control signals having different pulse widths to the first emission control line EL1 and the second emission control line EL2.

The first scan driver SDC1, the second scan driver SDC2, and the display driving circuit 250 may be located in the non-display area NDA.

Each of the first scan driver SDC1 and the second scan driver SDC2 may include a write scan signal output unit 611, an initialization scan signal output unit 612, a control scan signal output unit 613, a bias scan signal output unit 614, and the emission control signal output unit 615. Each of the write scan signal output unit 611, the initialization scan signal output unit 612, the control scan signal output unit 613, the bias scan signal output unit 614, and the emission control signal output unit 615 may receive a scan timing control signal SCS from a timing control circuit (e.g., timing controller) 251.

The write scan signal output unit 611 may generate write scan signals in response to the scan timing control signal SCS and sequentially output them to the write scan lines GWL.

The initialization scan signal output unit 612 may generate initialization scan signals in response to the scan timing control signal SCS and sequentially output them to the initialization scan lines GIL.

The control scan signal output unit 613 may generate control scan signals in response to the scan timing control signal SCS and sequentially output them to the control scan lines GCL.

The bias scan signal output unit 614 may generate bias scan signals according to the scan timing control signal SCS and output them sequentially to the bias scan lines GBL.

The emission control signal output unit 615 may generate emission control signals according to the scan timing control signal SCS and sequentially output them to the emission control lines EL. In case that the sub-pixels SPX of each horizontal line are divided and connected to the plurality of emission control lines EL (e.g., the first emission control line EL1 and the second emission control line EL2 of each horizontal line), the emission control signal output unit 615 may output each emission control signal to the plurality of emission control lines EL for each horizontal period (or each emission period).

The display driving circuit 250 may include a timing control circuit (e.g., timing controller) 251 and a data driving circuit (e.g., data driver) 252.

The data driving circuit 252 may receive digital video data DATA and a data timing control signal DCS from the timing control circuit 251. The data driving circuit 252 converts the digital video data DATA into analog data voltages in response to the data timing control signal DCS, and outputs them to the data lines DL. In this case, the sub-pixels SPX may be selected by the write scan signal of the first scan driver SDC1 and the second scan driver SDC2, and data voltages may be supplied to the selected sub-pixels SPX.

The timing control circuit 251 may receive digital video data DATA and timing signals from the outside. The timing control circuit 251 may generate the scan timing control signal SCS and the data timing control signal DCS for controlling the display panel 100 in response to the timing signals. The timing control circuit 251 may output the scan timing control signal SCS to the first scan driver SDC1 and the second scan driver SDC2. The timing control circuit 251 may output the digital video data DATA and the data timing control signal DCS to the data driving circuit 252.

The power supply circuit (e.g., power supply unit) 500 may generate panel driving voltages according to a power voltage supplied from the outside. For example, the power supply circuit 500 may generate and supply a first driving voltage VDD, a second driving voltage VSS, a third driving voltage VINT, a fourth driving voltage VAINT, and a fifth driving voltage VOBS to the display panel 100. The first driving voltage VDD, the second driving voltage VSS, the third driving voltage VINT, the fourth driving voltage VAINT, and the fifth driving voltage VOBS may be supplied to the sub-pixels SPX and used to drive the sub-pixels SPX. According to the structure and/or method of operation of the sub-pixels SPX, the number and/or type of panel driving voltages outputted from the power supply circuit 500 may be changed.

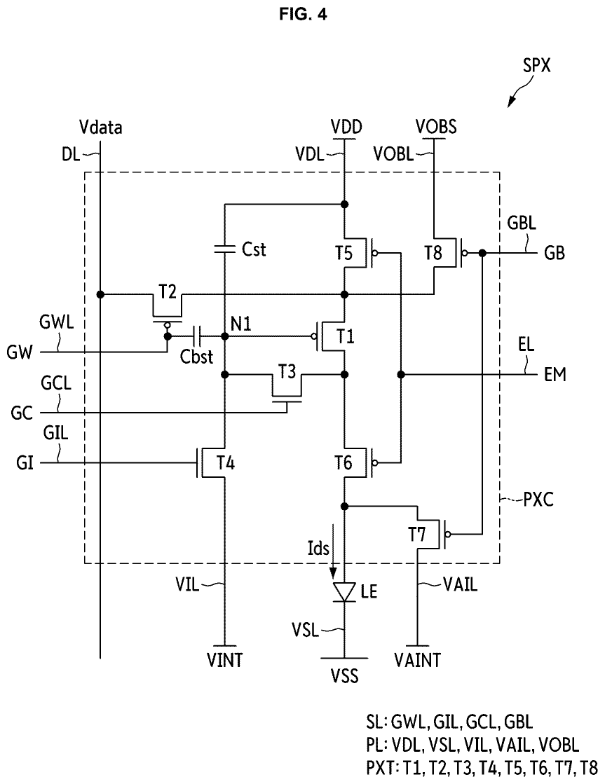

FIG. 4 is an equivalent circuit diagram illustrating a sub-pixel according to one or more embodiments. For example, FIG. 4 may be an equivalent circuit diagram showing one sub-pixel SPX from among the sub-pixels SPX of FIGS. 2 and 3. In one or more embodiments, the circuit configurations of the sub-pixels SPX constituting each pixel PX may be substantially the same. For example, the equivalent circuit diagrams of the first sub-pixel SPX1, the second sub-pixel SPX2, and the third sub-pixel SPX3 of FIG. 3 may be the same.

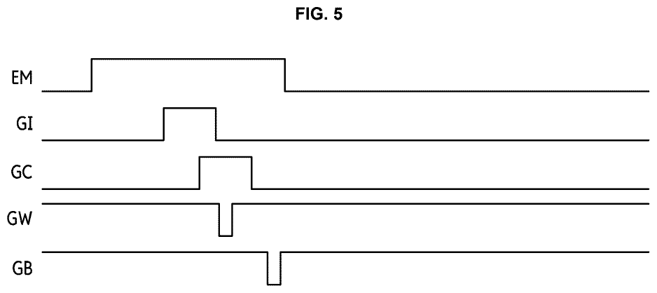

FIG. 5 is a waveform diagram showing driving signals of a sub-pixel according to one or more embodiments. For example, FIG. 5 shows a write scan signal GW, a control scan signal GC, an initialization scan signal GI, a bias scan signal GB and an emission control signal EM supplied to the scan lines SL and the emission control line EL of FIG. 4.

Referring to FIGS. 4 and 5 in addition to FIGS. 1-3, each of the sub-pixels SPX may include a pixel circuit PXC and a light emitting element LE electrically connected to the pixel circuit PXC.

The sub-pixel SPX may be connected to at least one scan driver through the scan lines SL and the emission control line EL. For example, the sub-pixel SPX may be connected to the first scan driver SDC1 and the second scan driver SDC2 through the write scan line GWL, the initialization scan line GIL, the control scan line GCL, the bias scan line GBL, and the emission control line EL. The first scan driver SDC1 and the second scan driver SDC2 may output the write scan signal GW, the initialization scan signal GI, the control scan signal GC, the bias scan signal GB, and the emission control signal EM to the write scan line GWL, the initialization scan line GIL, the control scan line GCL, the bias scan line GBL, and the emission control line EL, respectively.

When the sub-pixel SPX is the first sub-pixel SPX1, the sub-pixel SPX may be connected to the first emission control line EL1 located on the corresponding horizontal line, and may receive the emission control signal EM (also referred to as “first emission control signal”) from the first emission control line EL1. When the sub-pixel SPX is the second sub-pixel SPX2 or the third sub-pixel SPX3, the sub-pixel SPX may be connected to the second emission control line EL2 located on the corresponding horizontal line, and may receive the emission control signal EM (also referred to as “second emission control signal”) from the second emission control line EL2.

The sub-pixel SPX may be connected to the data driving circuit 252 through the data line DL. The data driving circuit 252 may output a data voltage Vdata corresponding to the image data of each frame to the data line DL.

When the sub-pixel SPX is the first sub-pixel SPX1, the sub-pixel SPX may be connected to the first data line DLr located in the corresponding pixel column. When the sub-pixel SPX is the second sub-pixel SPX2, the sub-pixel SPX may be connected to the second data line DLg located in the corresponding pixel column. When the sub-pixel SPX is the third sub-pixel SPX3, the sub-pixel SPX may be connected to the third data line DLb located in the corresponding pixel column.

The sub-pixel SPX may be connected to the power supply circuit 500 through power lines PL. For example, the sub-pixel SPX may be connected to the power supply circuit 500 through a first power line VDL, a second power line VSL, a third power line VIL, a fourth power line VAIL, and a fifth power line VOBL. The power supply circuit 500 may supply the first driving voltage VDD, the second driving voltage VSS, the third driving voltage VINT, the fourth driving voltage VAINT, and the fifth driving voltage VOBS to the first power line VDL, the second power line VSL, the third power line VIL, the fourth power line VAIL, and the fifth power line VOBL, respectively. In one or more embodiments, the first driving voltage VDD, the second driving voltage VSS, the third driving voltage VINT, the fourth driving voltage VAINT, and the fifth driving voltage VOBS may be a high potential pixel voltage (e.g., an anode voltage), a low potential pixel voltage (e.g., a cathode voltage or common voltage), a first initialization voltage (e.g., a gate initialization voltage), a second initialization voltage (e.g., an anode initialization voltage), and a bias voltage, respectively.

The pixel circuit PXC may control a driving current Ids supplied to the light emitting element LE in response to the driving signals (e.g., the write scan signal GW, the initialization scan signal GI, the control scan signal GC, the bias scan signal GB, the emission control signal EM, and the data voltage Vdata) supplied to the sub-pixel SPX. The emission timing and luminance of the light emitting element LE may be controlled by the pixel circuit PXC.

The pixel circuit PXC may include pixel transistors PXT and a storage capacitor Cst. In one or more embodiments, the pixel circuit PXC may further include a boosting capacitor Cbst.

In one or more embodiments, the pixel transistors PXT may include first to eighth transistors T1 to T8. The first transistor T1 may be a driving transistor of the sub-pixel SPX. The second to eighth transistors T2 to T8 may be switching transistors of the sub-pixel SPX.

In one or more embodiments, the sub-pixel SPX may include different types of pixel transistors PXT. For example, the first, second, fifth, sixth, seventh, and eighth transistors T1, T2, T5, T6, T7, and T8 may be P-type transistors (e.g., P-type polycrystalline silicon transistors including active layers containing polycrystalline silicon), and the third and fourth transistors T3 and T4 may be N-type transistors (e.g., N-type oxide transistors including active layers containing an oxide semiconductor). In one or more embodiments, the active layers of P-type transistors (e.g., the active layers containing polycrystalline silicon) and the active layers of N-type transistors (e.g., the active layers containing an oxide semiconductor) may be located in different layers within the display panel 100 (e.g., a backplane layer of the display panel 100).

The first transistor T1 may be connected between the fifth transistor T5 and the sixth transistor T6. The first transistor T1 may be connected to the first power line VDL via the fifth transistor T5, and may be connected to the light emitting element LE via the sixth transistor T6. The gate electrode of the first transistor T1 may be connected to a first node N1. The first transistor T1 may control the driving current Ids flowing through the sub-pixel SPX according to the voltage of the first node N1 applied to the gate electrode of the first transistor T1 (for example, a voltage corresponding to the data voltage Vdata).

The second transistor T2 may be connected between the data line DL and the first electrode of the first transistor T1 (e.g., the source electrode of the first transistor T1 connected to the fifth transistor T5). The gate electrode of the second transistor T2 may be connected to the write scan line GWL. The second transistor T2 may be turned on by the write scan signal GW of a gate-on voltage (for example, a low-level voltage at which the second transistor T2 can be turned on) supplied from the write scan line GWL. When the second transistor T2 is turned on, the data voltage Vdata supplied from the data line DL may be transmitted to the first electrode (e.g., the source electrode) of the first transistor T1.

The third transistor T3 may be connected between the second electrode of the first transistor T1 (e.g., the drain electrode of the first transistor T1 connected to the sixth transistor T6) and a first node N1. The gate electrode of the third transistor T3 may be connected to the control scan line GCL. The third transistor T3 may be turned on by the control scan signal GC of a gate-on voltage (e.g., a high level voltage at which the third transistor T3 can be turned on) supplied from the control scan line GCL to connect the gate electrode of the first transistor T1 to the second electrode of the first transistor T1. When the third transistor T3 is turned on, the first transistor T1 may be driven as a diode (e.g., the first transistor T1 may be diode-connected), and a voltage corresponding to the data voltage Vdata may be applied to the first node N1.

The fourth transistor T4 may be connected between the first node N1 and the third power line VIL. The gate electrode of the fourth transistor T4 may be connected to the initialization scan line GIL. The fourth transistor T4 may be turned on by the initialization scan signal GI of a gate-on voltage (e.g., a high level voltage at which the fourth transistor T4 can be turned on) supplied from the initialization scan line GIL to connect the first node N1 to the third power line VIL. When the fourth transistor T4 is turned on, the voltage of the first node N1 may be initialized to the third driving voltage VINT of the third power line VIL.

The fifth transistor T5 may be connected between the first power line VDL and the first electrode of the first transistor T1. The gate electrode of the fifth transistor T5 may be connected to the emission control line EL (e.g., the first emission control line EL1 or the second emission control line EL2 of FIG. 3). The fifth transistor T5 may be turned on by the emission control signal EM of a gate-on voltage (e.g., a low level voltage at which the fifth transistor T5 can be turned on) supplied from the emission control line EL to connect the first electrode of the first transistor T1 to the first power line VDL. When the fifth transistor T5 is turned on, the first power line VDL may be connected to the first electrode of the first transistor T1.

The sixth transistor T6 may be connected between the second electrode of the first transistor T1 and the light emitting element LE. The gate electrode of the sixth transistor T6 may be connected to the emission control line EL. The sixth transistor T6 may be turned on by the emission control signal EM of a gate-on voltage (e.g., a low level voltage at which the sixth transistor T6 can be turned on) supplied from the emission control line EL to connect the second electrode of the first transistor T1 to the light emitting element LE.

The seventh transistor T7 may be connected between the first electrode of the light emitting element LE (e.g., the anode electrode connected to the sixth transistor T6) and the fourth power line VAIL. The gate electrode of the seventh transistor T7 may be connected to the bias scan line GBL. The seventh transistor T7 may be turned on by the bias scan signal GB of a gate-on voltage (e.g., a low level voltage at which the seventh transistor T7 can be turned on) supplied from the bias scan line GBL to connect the first electrode of the light emitting element LE to the fourth power line VAIL. When the seventh transistor T7 is turned on, the voltage of the first electrode of the light emitting element LE may be initialized to the fourth driving voltage VAINT of the fourth power line VAIL.

The eighth transistor T8 may be connected between the fifth power line VOBL and the first electrode of the first transistor T1. The gate electrode of the eighth transistor T8 may be connected to the bias scan line GBL. The eighth transistor T8 may be turned on by the bias scan signal GB of a gate-on voltage supplied from the bias scan line GBL to connect the first electrode of the first transistor T1 to the fifth power line VOBL. When the eighth transistor T8 is turned on, the voltage of the first electrode of the first transistor T1 may be initialized to the fifth driving voltage VOBS of the fifth power line VOBL. In one or more embodiments, the fifth driving voltage VOBS may be a bias voltage having a voltage level suitable for compensating the hysteresis characteristics of the first transistor T1.

The storage capacitor Cst may be connected between the first node N1 and the first power line VDL. The storage capacitor Cst may be charged with a voltage corresponding to the data voltage Vdata applied to the first node N1.

The boosting capacitor Cbst may be connected between the first node N1 and the write scan line GWL. The voltage of the first node N1 may be stabilized by the coupling effect of the boosting capacitor Cbst, thereby stabilizing the operation of the first transistor T1. The boosting capacitor Cbst may be formed by a parasitic capacitance formed between the first node N1 and the write scan line GWL, or may be designed separately.

The sub-pixel SPX may emit light during a partial period of each frame period, which corresponds to the on-duty ratio, and may not emit light during the remaining period. The emission period and non-emission period of the sub-pixel SPX may be controlled by the emission control signal EM.

A period during which the fifth transistor T5 and the sixth transistor T6 are turned off (e.g., a period during which the emission control signal EM of a high level is supplied to the sub-pixel SPX) may be a non-emission period of the sub-pixel SPX. The non-emission period of the sub-pixel SPX may include an initialization period for initializing a voltage of a specific node (e.g., the first node N1 and/or the like) of the sub-pixel SPX, and a data write and storage period for charging the storage capacitor Cst with a voltage corresponding to the data voltage Vdata. In one or more embodiments, the initialization scan signal GI, the control scan signal GC, the write scan signal GW, and the bias scan signal GB of a gate-on voltage may be supplied during the non-emission period of the sub-pixel SPX. In one or more embodiments, the initialization scan signal GI, the control scan signal GC, and the bias scan signal GB of the gate-on voltage may be sequentially supplied during the non-emission period of the sub-pixel SPX. The periods in which the initialization scan signal GI and the control scan signal GC of the gate-on voltage are supplied may overlap, but the present disclosure is not limited thereto. The write scan signal GW of the gate-on voltage may be supplied during the period when the control scan signal GC of the gate-on voltage is supplied.

The period during which the fifth transistor T5 and the sixth transistor T6 are turned on (e.g., the period during which the emission control signal EM of a low level is supplied to the sub-pixel SPX) may be an emission period of the sub-pixel SPX. During the emission period of the sub-pixel SPX, the first transistor T1 may supply the driving current Ids corresponding to the voltage of the first node N1 to the light emitting element LE.

The light emitting element LE may be connected between the pixel circuit PXC and the second power line VSL. For example, the first electrode (e.g., the anode electrode or pixel electrode) of the light emitting element LE may be connected to a node between the sixth transistor T6 and the seventh transistor T7, and the second electrode (e.g., the cathode electrode or common electrode) of the light emitting element LE may be connected to the second power line VSL. The light emitting element LE may emit light corresponding to the driving current Ids supplied from the pixel circuit PXC.

In one or more embodiments, the sub-pixel SPX may include a single light emitting element LE, but is not limited thereto. For example, the sub-pixel SPX may include at least two light emitting elements LE. The at least two light emitting elements LE may be connected in a series, parallel, or series-parallel structure between the pixel circuit PXC and the second power line VSL.

In one or more embodiments, the light emitting element LE may be a micro light emitting diode containing an inorganic compound such as a nitride-based or phosphide-based semiconductor material, but is not limited thereto. For example, the light emitting element LE may be an organic light emitting element, a quantum dot light emitting element, or another type of light emitting element. In addition, the size or shape of the light emitting element LE may be different according to the embodiments.

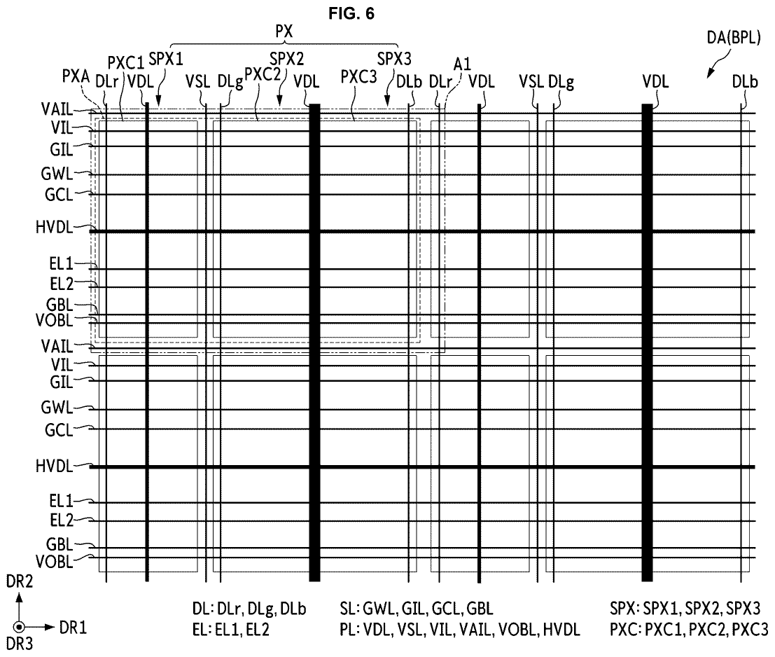

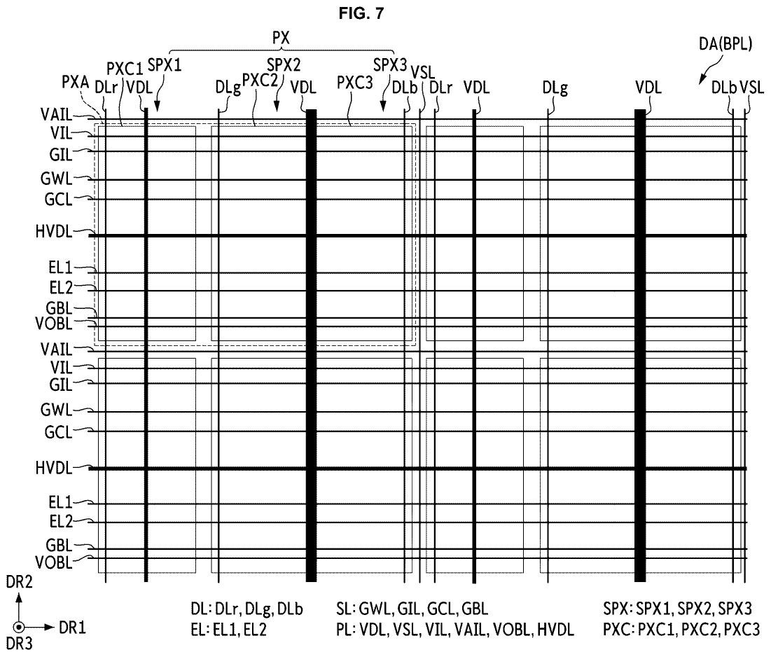

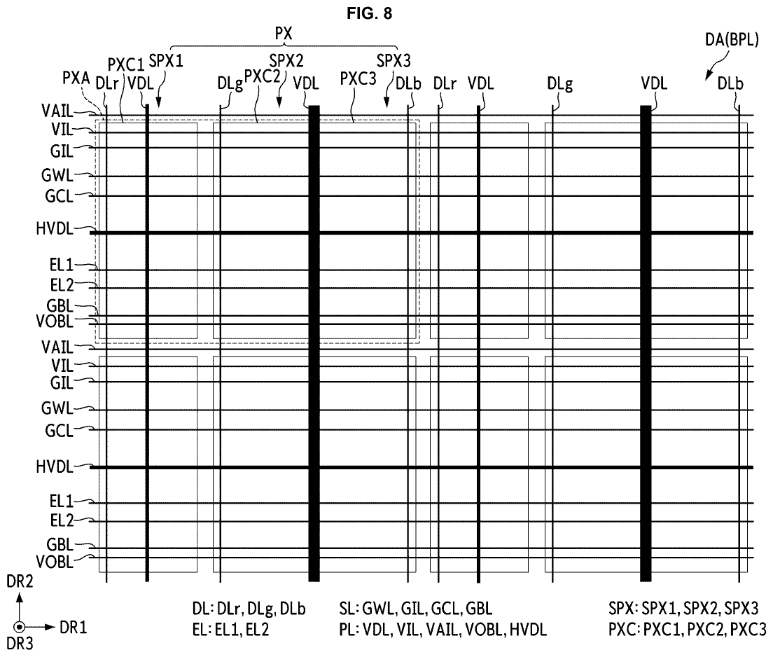

FIG. 6 is a plan view showing pixel circuits, signal lines, and power lines located in a backplane layer of a display panel according to one or more embodiments. FIG. 7 is a plan view showing pixel circuits, signal lines, and power lines located in a backplane layer of a display panel according to one or more embodiments. FIG. 8 is a plan view showing pixel circuits, signal lines, and power lines located in a backplane layer of a display panel according to one or more embodiments.

For example, FIGS. 6-8 show the approximate arrangement of the pixel circuits PXC, the signal lines, and the power lines PL located in a backplane layer BPL of the display panel 100 in a part of the display area DA including four pixel areas PXA in which four pixels PX are arranged along the first direction DR1 and the second direction DR2. FIGS. 6-8 show different embodiments with respect to the second power line VSL. For simplicity of description, FIGS. 6-8 show reference numerals only for the sub-pixels SPX arranged in one pixel area PXA and the pixels PX including the sub-pixels SPX.

Referring to FIGS. 6-8 in addition to FIGS. 1-5, each pixel area PXA of the display area DA may include the pixel circuits PXC of the pixel PX located in the corresponding pixel area PXA. For example, the pixel circuit PXC of the first sub-pixel SPX1 (hereinafter, referred to as “first pixel circuit PXC1”), the pixel circuit PXC of the second sub-pixel SPX2 (hereinafter, referred to as “second pixel circuit PXC2”), and the pixel circuit PXC of the third sub-pixel SPX3 (hereinafter, referred to as “third pixel circuit PXC3”) may be located in each pixel area PXA.

In each pixel area PXA of the display area DA and/or the vicinity thereof, the signal lines and the power lines PL, which are electrically connected to the sub-pixels SPX located in the corresponding pixel area PXA, may be located. The signal lines in the display area DA may include the scan lines SL, the emission control lines EL, and the data lines DL. The power lines PL of the display area DA may include the first power line VDL, the third power line VIL, the fourth power line VAIL, and the fifth power line VOBL. The power lines PL of the display area DA may or may not include the second power line VSL.

In one or more embodiments, the power lines PL of the display area DA may further include a horizontal power line HVDL connected to the first power line VDL and extending in the first direction DR1. The first power line VDL and the horizontal power line HVDL may be electrically connected to each other inside and/or outside the display area DA.

In one or more embodiments, the plurality of first power lines VDL arranged along the first direction DR1 may be located in the display area DA. For example, the plurality of first power lines VDL may be electrically connected to each other inside and/or outside the display area DA to constitute one electrical wire, but may be branched into multiple wires in the display area DA. Each of the first power lines VDL of the display area DA may extend in the second direction DR2.

The first pixel circuit PXC1, the second pixel circuit PXC2, and the third pixel circuit PXC3 may be arranged along the first direction DR1 in the display area DA. For example, the first pixel circuit PXC1, the second pixel circuit PXC2, and the third pixel circuit PXC3 may be sequentially arranged along the first direction DR1 in each pixel area PXA.

In one or more embodiments, the second pixel circuit PXC2 and the third pixel circuit PXC3 of each pixel PX may share one first power line VDL. The second pixel circuit PXC2 and the third pixel circuit PXC3 may be arranged close (e.g., adjacent) to each other. In one example, the second pixel circuit PXC2 and the third pixel circuit PXC3 may be arranged to substantially adjacent each other in a portion where the first power line VDL is located, and the separation distance between the second pixel circuit PXC2 and the third pixel circuit PXC3 may be reduced or removed (e.g., minimized). Accordingly, the first pixel circuit PXC1, the second pixel circuit PXC2, and the third pixel circuit PXC3 may be efficiently arranged in the pixel area PXA allocated to each pixel PX, and the design structure and/or space utilization of the pixel area PXA may be improved.

In one or more embodiments, each of the first pixel circuit PXC1, the second pixel circuit PXC2, and the third pixel circuit PXC3 may overlap one first power line VDL. For example, two first power lines VDL may be located in each pixel area PXA. The first pixel circuit PXC1 may overlap one of the two first power lines VDL, and the second pixel circuit PXC2 and the third pixel circuit PXC3 may overlap the other first power line VDL. Accordingly, the space utilization and/or integration of the backplane layer BPL may be improved.

In one or more embodiments, the power lines PL of the display area DA may further include the second power line VSL, as shown in FIGS. 6 and 7. For example, the second power line VSL may be located in the space secured by the close arrangement of the second pixel circuit PXC2 and the third pixel circuit PXC3 (e.g., the second power line VSL may be located in the space between the first pixel circuit PXC1 and the second pixel circuit PXC2). The second power line VSL may be electrically connected to a common electrode located on the backplane layer BPL in the display area DA and/or the non-display area NDA. The common electrode may be located at least in the display area DA. For example, the common electrode may be located in the display area DA and may also be located in a part of the non-display area NDA located around the display area DA. The common electrode may be electrically connected to the light emitting elements LE in the display area DA, and may be electrically connected to the second power line VSL in the display area DA and/or the non-display area NDA.

In another embodiment, the power lines PL of the display area DA may not include the second power line VSL as shown in FIG. 8. For example, the second power line VSL (or a bus line to which the second driving voltage VSS is applied) may be located only in the non-display area NDA and may be electrically connected to the common electrode around the display area DA. The second power line VSL may be located inside and/or above the backplane layer BPL in the non-display area NDA.

The scan lines SL and the emission control lines EL may extend in the first direction DR1 and may be arranged or located along the second direction DR2. In one or more embodiments, on each horizontal line where a row of the pixels PX are arranged, the write scan line GWL, the initialization scan line GIL, the control scan line GCL, the bias scan line GBL, the first emission control line EL1, and the second emission control line EL2 connected to the sub-pixels SPX of the corresponding horizontal line may be arranged.

The positions and/or arrangement order of the write scan line GWL, the initialization scan line GIL, the control scan line GCL, the bias scan line GBL, the first emission control line EL1, and the second emission control line EL2 may vary depending on the design structure and/or the like of each pixel circuit PXC. For example, the write scan line GWL may be located at a position corresponding to the second transistor T2 of each of the pixel circuits PXC. For example, the write scan line GWL may overlap the second transistor T2 of each of the pixel circuits PXC or may be located around the second transistor T2. The initialization scan line GIL may be located at a position corresponding to the fourth transistor T4 of each of the pixel circuits PXC. The control scan line GCL may be located at a position corresponding to the third transistor T3 of each of the pixel circuits PXC. The bias scan line GBL may be located at positions corresponding to the seventh and eighth transistors T7 and T8 of each of the pixel circuits PXC. The first emission control line EL1 and the second emission control line EL2 may be located at positions corresponding to the fifth and sixth transistors T5 and T6 of each of the pixel circuits PXC. The first emission control line EL1 and the second emission control line EL2 of each horizontal line may be adjacent to each other in the second direction DR2.

The data lines DL may extend in the second direction DR2 and may be arranged or located along the first direction DR1. In one or more embodiments, in each pixel column (or a vertical line) where a column of pixels PX are arranged, the first data line DLr, the second data line DLg, and the third data line DLb connected to the sub-pixels SPX of the corresponding pixel column may be arranged.

The first data line DLr may be located at a position corresponding to the second transistor T2 of each of the first pixel circuits PXC1. For example, the first data line DLr may overlap the second transistor T2 of each of the first pixel circuits PXC1 or may be located around the second transistor T2. The second data line DLg may be located at a position corresponding to the second transistor T2 of each of the second pixel circuits PXC2. The third data line DLb may be located at a position corresponding to the second transistor T2 of each of the third pixel circuits PXC3.

In one or more embodiments, the first data line DLr, the second data line DLg, and the third data line DLb may be located at one edges of the first pixel circuits PXC1, the second pixel circuits PXC2, and the third pixel circuits PXC3 of the corresponding pixel column, respectively. For example, the first data line DLr and the second data line DLg may be located at the left edges of the first pixel circuits PXC1 and the second pixel circuits PXC2 of the corresponding pixel column, respectively. In one or more embodiments, the second data line DLg and the third data line DLb may be located at opposite positions with respect to the first power line VDL located at the boundary between the second pixel circuits PXC2 and the third pixel circuits PXC3 of the corresponding pixel column. For example, the third data line DLb may be located at the right edge of the third pixel circuits PXC3 of the corresponding pixel column.

In the embodiments of FIGS. 6-8, the data lines DL of the sub-pixels SPX may be located in the vicinity of different wires. For example, in the embodiment of FIG. 6, the first data line DLr located in each pixel column may be located between the third data line DLb of the adjacent pixel column and the first power line VDL of the corresponding pixel column (e.g., one first power line VDL, overlapping the first pixel circuit PXC1, of two first power lines VDL located in each pixel column), the second data line DLg may be located between the second power line VSL located in the corresponding pixel column and the first power line VDL (e.g., the other first power line VDL, overlapping the second and third pixel circuits PXC2 and PXC3, of the two first power lines VDL located in each pixel column), and the third data line DLb may be located between the first power line VDL (e.g., the other first power line VDL of each pixel column) located in the corresponding pixel column and the first data line DLr of the adjacent pixel column. In the embodiment of FIG. 7, the first data line DLr located in each pixel column may be located between the second power line VSL and the first power line VDL (e.g., one first power line VDL of each pixel column), the second data line DLg may be located between two first power lines VDL of the corresponding pixel column, and the third data line DLb may be located between the first power line VDL (e.g., the other first power line VDL of each pixel column) and the second power line VSL. In the embodiment of FIG. 8, the first data line DLr located in each pixel column may be located between the third data line DLb of the adjacent pixel column and the first power line VDL of the corresponding pixel column (e.g., one first power line VDL of each pixel column), the second data line DLg may be located between two first power lines VDL of the corresponding pixel column, and the third data line DLb may be located between the first power line VDL located in the corresponding pixel column (e.g., the other first power line VDL of each pixel column) and the first data line DLr of the adjacent pixel column.

The first power line VDL may be located in each pixel column and may extend in the second direction DR2. In one or more embodiments, the plurality of first power lines VDL may be located in each pixel column. For example, in each pixel column, one first power line VDL overlapping the first pixel circuits PXC1 of the corresponding pixel column and connected to the first pixel circuits PXC1, and the other first power line VDL overlapping the second and third pixel circuits PXC2 and PXC3 in the corresponding pixel column and connected to the second and third pixel circuits PXC2 and PXC3 may be arranged. The first power line VDL may overlap the first transistor T1 and the storage capacitor Cst of each of the pixel circuits PXC. In one or more embodiments, the width of the first power line VDL connected to the second and third pixel circuits PXC2 and PXC3 may be greater than the width of the first power line VDL connected to the first pixel circuits PXC1, but the present disclosure is not limited thereto.

In describing the embodiments, the first power lines VDL that are spaced (e.g., spaced apart) from each other in at least a part of the display area DA are referred to as a plurality of first power lines, but the lines to which the same voltage or signal is applied may be regarded as one wire. For example, in FIG. 6, the first power lines VDL arranged along the first direction DR1 may be electrically connected to each other, and thus may substantially constitute one power line. For example, the first power lines VDL illustrated in FIG. 6 are parts substantially branched from one power line, and may be different parts of the one power line.

The horizontal power line HVDL may cross the first power lines VDL and may be located at a position corresponding to the storage capacitor Cst of each of the pixel circuits PXC. For example, the horizontal power line HVDL may be located on each horizontal line and extend in the first direction DR1. In one or more embodiments, the horizontal power line HVDL may be formed integrally with one electrode of the storage capacitors Cst (e.g., the electrode connected to the first power line VDL in FIG. 4) which is included in the pixel circuits PXC located on the corresponding horizontal line.

The third power line VIL may be located on each horizontal line and may extend in the first direction DR1. The third power line VIL may be located at a position corresponding to the fourth transistor T4 of each of the pixel circuits PXC.

The fourth power line VAIL may be located on each horizontal line and may extend in the first direction DR1. The fourth power line VAIL may be located at a position corresponding to the seventh transistor T7 of each of the pixel circuits PXC.

The fifth power line VOBL may be located on each horizontal line and may extend in the first direction DR1. The fifth power line VOBL may be located at a position corresponding to the eighth transistor T8 of each of the pixel circuits PXC.

As shown in FIGS. 6 and 7, in the embodiments where the backplane layer BPL includes the second power line VSL located in the display area DA, the second power line VSL may extend in the second direction DR2. In one or more embodiments, the plurality of second power lines VSL, which are located in each pixel column or between two adjacent pixel columns, may be located in the display area DA. The second power lines VSL may be arranged or located along the first direction DR1.

Each of the second power lines VSL may be located between the first pixel circuit PXC1 and the second and third pixel circuits PXC2 and PXC3. For example, each of the second power lines VSL may be located between the first pixel circuit PXC1 and the second pixel circuit PXC2 included in each pixel PX as shown in FIG. 6, or may be located between two adjacent pixels PX in the first direction DR1 (e.g., between the third pixel circuit PXC3 of the pixel PX located on the left side and the first pixel circuit PXC1 of the pixel PX located on the right side) as shown in FIG. 7. For example, each of the second power lines VSL may be located between the first power line VDL and the second data line DLg in the area where the first pixel circuit PXC1 is located as shown in FIG. 6 or located between the third data line DLb and the first data line DLr that are adjacent in the first direction DR1 as shown in FIG. 7.

In one or more embodiments, the second power lines VSL may not cross the data lines DL and the first power lines VDL at least in the display area DA, and may be located in (e.g., at) the same layer as the data lines DL and/or the first power lines VDL. For example, the conductive layer, which is located at the uppermost portion of the conductive layers included in the backplane layer BPL of the display panel 100, may include the data lines DL, the first power lines VDL, and second power lines VSL that are spaced (e.g., spaced apart) from each other in the first direction DR1.

In describing the embodiments, the second power lines VSL that are spaced (e.g., spaced apart) from each other in the display area DA are referred to as a plurality of second power lines, but the second power lines VSL may be electrically connected to each other to substantially constitute one power line. For example, the second power lines VSL shown in FIGS. 6 and 7 are parts substantially branched from one power line, and may be different parts of the one power line.

According to the embodiment of FIGS. 6 and 7, by locating (e.g., arranging) the second power line VSL between the pixel circuits PXC, the voltage drop of the second driving voltage VSS may be reduced or minimized. For example, the second power line VSL may be formed in the backplane layer BPL of the display panel 100 by using a low-resistance material having a low sheet resistance together with the first power line VDL and/or the like. Accordingly, the voltage drop of the second driving voltage VSS applied to the pixels PX through the second power line VSL may be reduced or minimized.

As shown in FIG. 8, in the embodiment including the backplane layer BPL that does not have the second power line VSL in the display area DA, the second power line VSL may be located in the non-display area NDA of the backplane layer BPL. For example, the second power line VSL may not be located in the display area DA but may be located only in the non-display area NDA to be electrically connected to a common electrode located on the backplane layer. Alternatively, the second power line VSL may also be located in the display area DA, but may be located above the backplane layer BPL in the display area DA.

According to the embodiment of FIG. 8, the design space secured between the pixel circuits PXC may be used as a space for arranging conductive patterns or wires than the second power line VSL, or may be used to improve electrical stability by ensuring a separation distance between the patterns located around the space.

In the embodiments of FIGS. 6-8, each of the signal lines and the power lines PL is shown as extending in a straight line along the first direction DR1 or the second direction DR2, but the present disclosure is not limited thereto. For example, FIGS. 6-8 illustrate the overall shape, extension direction, and arrangement direction of each of the signal lines and the power lines PL, but the shape, position, arrangement direction, size and/or the like of each of the signal lines and the power lines PL may be adjusted or changed in consideration of circuit density, minimization of interference between circuits, defect avoidance, arrangement form of the sub-pixels SPX and/or the like. For example, each of the signal lines and the power lines PL may extend along the first direction DR1 or the second direction DR2 entirely or substantially, but at least some of the signal lines and the power lines PL may have a partially bent shape and/or the like.

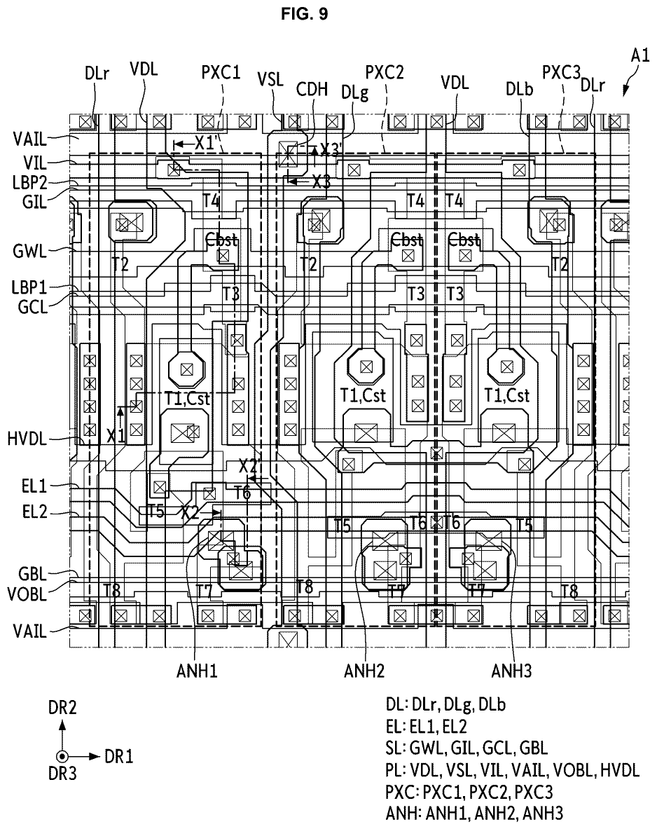

FIG. 9 is a layout diagram showing a backplane layer of a display panel according to one or more embodiments. For example, FIG. 9 shows an embodiment of a layout of the backplane layer BPL with respect to a part of the display area DA corresponding to area A1 of FIG. 6. The area A1 of FIGS. 6 and 9 may include one pixel area PXA having the first pixel circuit PXC1, the second pixel circuit PXC2, and the third pixel circuit PXC3 and the vicinity of the pixel area PXA.

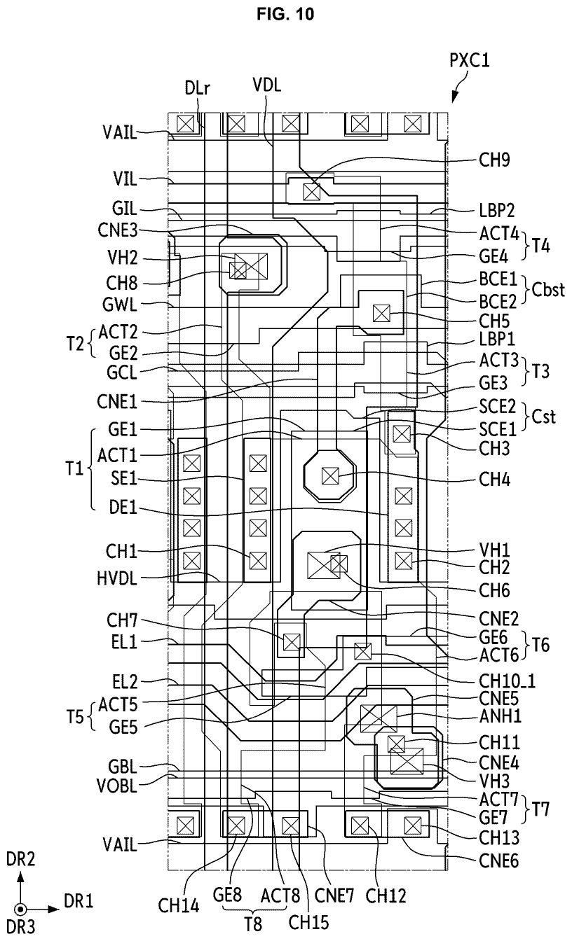

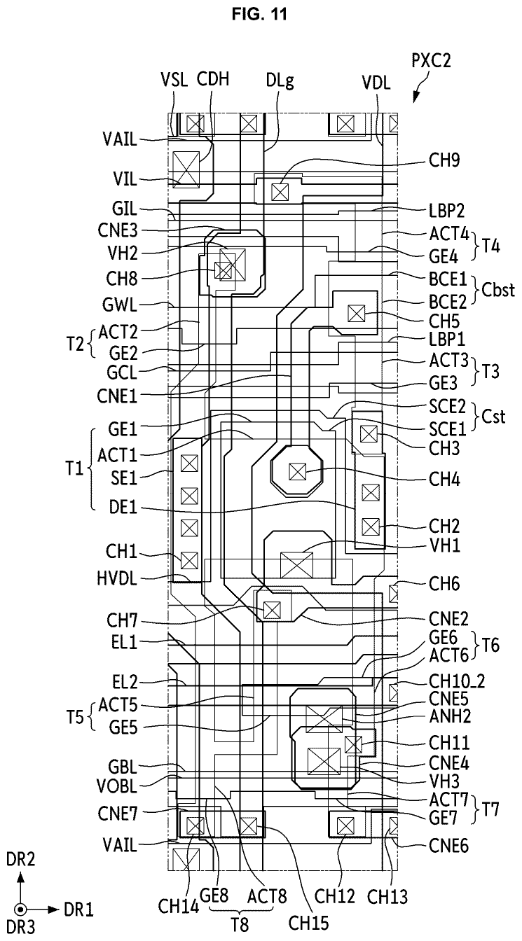

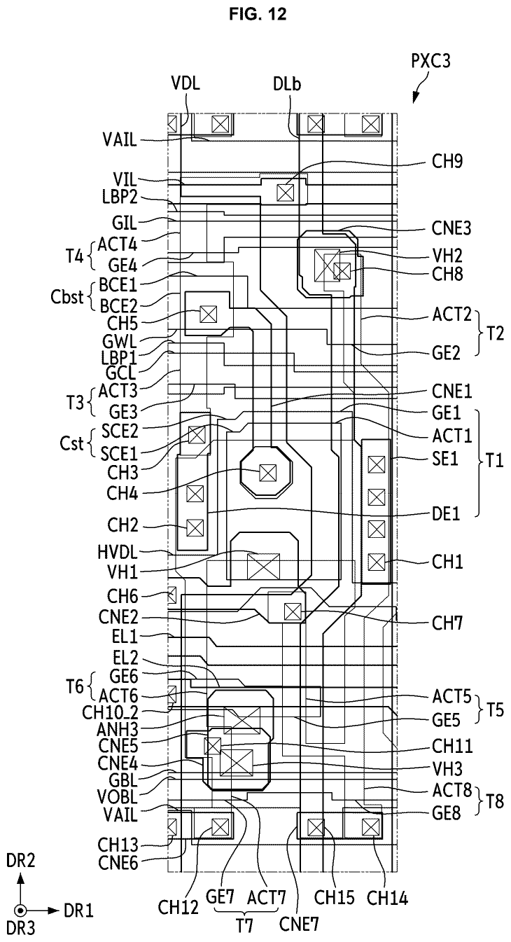

FIG. 10 is a layout diagram showing in detail the first pixel circuit of FIG. 9. FIG. 11 is a layout diagram showing in detail the second pixel circuit of FIG. 9. FIG. 12 is a layout diagram showing in detail the third pixel circuit of FIG. 9.

Referring to FIGS. 9-12 in addition to FIGS. 3-8, each of the first pixel circuit PXC1, the second pixel circuit PXC2, and the third pixel circuit PXC3 may include the first to eighth transistors T1 to T8, the storage capacitor Cst, and the boosting capacitor Cbst.

The first transistor T1 may include a first active layer ACT1 and a first gate electrode GE1. The first gate electrode GE1 may overlap a part of the first active layer ACT1. In one or more embodiments, the first transistor T1 may further include a source electrode SE1 and a drain electrode DE1. The source electrode SE1 and the drain electrode DE1 may be electrically connected to different parts of the first active layer ACT1, for example, the source region and drain region of the first active layer ACT1, respectively.

The first active layer ACT1 may include a channel region that overlaps the first gate electrode GE1, and a source region and a drain region located on opposite sides of the channel region. Including the first active layer ACT1, FIGS. 9-12 do not illustrate a distinction between the source region and the drain region included in the active layer of each transistor. However, according to the type (e.g., a P-type or an N-type) of each transistor and a voltage across each transistor, a part of the active layer included in each transistor may be a source region and the other part may be a drain region.

The source region of the first active layer ACT1 may be electrically connected to the second, fifth, and eighth active layers ACT2, ACT5, and ACT8 included in the second, fifth, and eighth transistors T2, T5, and T8. For example, the first active layer ACT1, the second active layer ACT2, the fifth active layer ACT5, and the eighth active layer ACT8 may be formed integrally, and the source region of the first active layer ACT1 may be electrically connected to a part (e.g., the drain region) of each of the second, fifth and eighth active layers ACT2, ACT5, and ACT8. The drain region of the first active layer ACT1 may be electrically connected to the third and sixth active layers ACT3 and ACT6 included in the third and sixth transistors T3 and T6. For example, the drain region of the first active layer ACT1 may be electrically connected to the drain electrode DE1 through at least one second contact hole CH2, and may be electrically connected to a part (e.g., the drain region) of the third active layer ACT3 through the drain electrode DE1. The first active layer ACT1 may also be formed integrally with the sixth and seventh active layers ACT6 and ACT7. The drain region of the first active layer ACT1 may be electrically connected to a part (e.g., the source region) of the sixth active layer ACT6.

The source electrode SE1 may be electrically connected to a part of the first active layer ACT1 through at least one first contact hole CH1. For example, the source electrode SE1 may be electrically connected to the source region of the first active layer ACT1 through a plurality of first contact holes CH1.

The drain electrode DE1 may be electrically connected to another portion of the first active layer ACT1 through at least one second contact hole CH2. For example, the drain electrode DE1 may be electrically connected to the drain region of the first active layer ACT1 through a plurality of second contact holes CH2. The drain electrode DE1 may be electrically connected to the third transistor T3 through a third contact hole CH3. For example, the drain electrode DE1 may be electrically connected to a part of the third active layer ACT3 (for example, the drain region of the third active layer ACT3) through the third contact hole CH3.

The first gate electrode GE1 may be electrically connected to a first electrode SCE1 of the storage capacitor Cst. For example, the first gate electrode GE1 and the first electrode SCE1 of the storage capacitor Cst may be formed integrally, and may be formed substantially as one conductive pattern. The first gate electrode GE1 may be electrically connected to a first connection electrode CNE1 through a fourth contact hole CH4, and may be electrically connected to the third and fourth transistors T3 and T4 through the first connection electrode CNE1. The first connection electrode CNE1 may be electrically connected to a part (for example, the source or drain region) of each of the third and fourth active layers ACT3 and ACT4 included in the third and fourth transistors T3 and T4 through a fifth contact hole CH5.

In one or more embodiments, the backplane layer BPL of the display panel 100 may further include a light blocking pattern located under the first active layer ACT1. For example, the backplane layer BPL may further include a lower conductive layer (for example, bottom metal layer) located between the substrate and the first semiconductor layer where the first active layer ACT1 is located, and the lower conductive layer may include a lower pattern overlapping the channel region of the first active layer ACT1 and/or the like. The lower pattern may block light incident from the lower side of the first active layer ACT1 (for example, the lower side of the backplane layer BPL) toward the channel region of the first active layer ACT1. Accordingly, the operating characteristics of the first transistor T1 may be stabilized. Further, the lower pattern may disperse charges accumulated around the first transistor T1.

The storage capacitor Cst may include the first electrode SCE1 and a second electrode SCE2 overlapping each other. The first electrode SCE1 of the storage capacitor Cst may be formed integrally with the first gate electrode GE1. The second electrode SCE2 of the storage capacitor Cst may be formed integrally with the horizontal power line HVDL, and may be electrically connected to the first power line VDL. For example, the second electrode SCE2 of the storage capacitor Cst may be electrically connected to the second connection electrode CNE2 through a sixth contact hole CH6, and may be electrically connected to the first power line VDL through the second connection electrode CNE2. The second connection electrode CNE2 may be electrically connected to the first power line VDL through a first via hole VH1 (or contact hole). Further, the second connection electrode CNE2 may be electrically connected to a part (for example, the source region) of the fifth active layer ACT5 included in the fifth transistor T5 through a seventh contact hole CH7.

The second transistor T2 may include the second active layer ACT2 and a second gate electrode GE2. The second gate electrode GE2 may overlap a part of the second active layer ACT2.

The second active layer ACT2 may include a channel region overlapping the second gate electrode GE2, and a source region and a drain region located on opposite sides of the channel region. The source region of the second active layer ACT2 may be electrically connected to the data line DL. For example, the source region of the second active layer ACT2 may be electrically connected to a third connection electrode CNE3 through an eighth contact hole CH8, and may be electrically connected to the data line DL (for example, the first data line DLr, the second data line DLg, or the third data line DLb) of each sub-pixel SPX through the third connection electrode CNE3. The third connection electrode CNE3 may be electrically connected to the data line DL of each sub-pixel SPX through a second via hole VH2 (or contact hole). The drain region of the second active layer ACT2 may be electrically connected to the first, fifth, and eighth active layers ACT1, ACT5, and ACT8 included in the first, fifth, and eighth transistors T1, T5, and T8. For example, the drain region of the second active layer ACT2 may be electrically connected to the source region of the first active layer ACT1 and the drain region of each of the fifth and eighth active layers ACT5 and ACT8.

The second gate electrode GE2 may be electrically connected to the write scan line GWL. For example, the second gate electrode GE2 and the write scan line GWL may be formed integrally, and may be formed substantially as one conductive pattern. In this case, a part of the write scan line GWL overlapping the second active layer ACT2 may function as the second gate electrode GE2.

The third transistor T3 may include the third active layer ACT3 and a third gate electrode GE3. The third gate electrode GE3 may overlap a part of the third active layer ACT3.

The third active layer ACT3 may include a channel region overlapping the third gate electrode GE3, and a source region and a drain region located on opposite sides of the channel region. The source region of the third active layer ACT3 may be electrically connected to the first gate electrode GE1 of the first transistor T1 and the fourth active layer ACT4 of the fourth transistor T4. For example, the source region of the third active layer ACT3 may be electrically connected to the first connection electrode CNE1 through the fifth contact hole CH5, and may be electrically connected to the first gate electrode GE1 of the first transistor T1 through the first connection electrode CNE1. Further, the third active layer ACT3 and the fourth active layer ACT4 may be formed integrally, and the source region of the third active layer ACT3 may be electrically connected to the drain region of the fourth active layer ACT4. The drain region of the third active layer ACT3 may be electrically connected to the first active layer ACT1 of the first transistor T1. For example, the drain region of the third active layer ACT3 may be connected to the drain electrode DE1 of the first transistor T1 through the third contact hole CH3, and may be electrically connected to the drain region of the first active layer ACT1 through the drain electrode DE1 of the first transistor T1.

The third gate electrode GE3 may be electrically connected to the control scan line GCL. For example, the third gate electrode GE3 and the control scan line GCL may be formed integrally, and may be formed substantially as one conductive pattern. In this case, a part of the control scan line GCL overlapping the third active layer ACT3 may function as the third gate electrode GE3.

In one or more embodiments, the backplane layer BPL of the display panel 100 may further include a first light blocking pattern LBP1 located under the third active layer ACT3. The first light blocking pattern LBP1 may extend in the first direction DR1 and may overlap the channel region of the third active layer ACT3 and the control scan line GCL. The first light blocking pattern LBP1 may block light incident from the lower side of the third active layer ACT3 toward the channel region of the third active layer ACT3. Accordingly, the operating characteristics of the third transistor T3 may be stabilized.

The fourth transistor T4 may include the fourth active layer ACT4 and a fourth gate electrode GE4. The fourth gate electrode GE4 may overlap a part of the fourth active layer ACT4.

The fourth active layer ACT4 may include a channel region overlapping the fourth gate electrode GE4, and a source region and a drain region located on opposite sides of the channel region. The source region of the fourth active layer ACT4 may be electrically connected to the third power line VIL. For example, the source region of the fourth active layer ACT4 may be electrically connected to the third power line VIL through a ninth contact hole CH9. Further, the drain region of the fourth active layer ACT4 may be electrically connected to the first gate electrode GE1 of the first transistor T1 and the third active layer ACT3 of the third transistor T3. For example, the drain region of the third active layer ACT3 may be electrically connected to the first gate electrode GE1 of the first transistor T1 through the first connection electrode CNE1, and may be formed integrally with the source region of the third active layer ACT3. For example, the third active layer ACT3 and the fourth active layer ACT4 of each of the first pixel circuit PXC1, the second pixel circuit PXC2, and the third pixel circuit PXC3 may be formed as one semiconductor pattern. In one or more embodiments, the third active layer ACT3 and the fourth active layer ACT4 may include an oxide semiconductor. Accordingly, the leakage current of the sub-pixels SPX may be reduced or prevented.

The fourth gate electrode GE4 may be electrically connected to the initialization scan line GIL. For example, the fourth gate electrode GE4 and the initialization scan line GIL may be formed integrally, and may be formed substantially as one conductive pattern. In this case, a part of the initialization scan line GIL overlapping the fourth active layer ACT4 may function as the fourth gate electrode GE4.

In one or more embodiments, the backplane layer BPL of the display panel 100 may further include a second light blocking pattern LBP2 located under the fourth active layer ACT4. The second light blocking pattern LBP2 may extend in the first direction DR1 and may overlap the channel region of the fourth active layer ACT4 and the initialization scan line GIL. The first light blocking pattern LBP1 and the second light blocking pattern LBP2 may be located in (e.g., at) the same layer in the backplane layer BPL, but are not limited thereto. The second light blocking pattern LBP2 may block light incident from the lower side of the fourth active layer ACT4 toward the channel region of the fourth active layer ACT4. Accordingly, the operating characteristics of the fourth transistor T4 may be stabilized.

In one or more embodiments, the third and fourth active layers ACT3 and ACT4 of the third and fourth transistors T3 and T4 may overlap the write scan line GWL. The boosting capacitor Cbst may be formed between the third and fourth active layers ACT3 and ACT4 and the write scan line GWL.

The boosting capacitor Cbst may include a first electrode BCE1 and a second electrode BCE2 overlapping each other. The first electrode BCE1 of the boosting capacitor Cbst may be formed integrally with the write scan line GWL. The second electrode BCE2 of the boosting capacitor Cbst may be formed integrally with a part (for example, the source or drain region) of each of the third and fourth active layers ACT3 and ACT4. In one or more embodiments, the capacitance of the boosting capacitor Cbst may be adjusted by adjusting the size of the area where the third and fourth active layers ACT3 and ACT4 and the write scan line GWL overlap. For example, in the area where the third and fourth active layers ACT3 and ACT4 and the write scan line GWL cross, the capacitance of the boosting capacitor Cbst may be increased by widening the width of the third and fourth active layers ACT3 and ACT4 and/or the write scan line GWL.

The fifth transistor T5 may include the fifth active layer ACT5 and a fifth gate electrode GE5. The fifth gate electrode GE5 may overlap a part of the fifth active layer ACT5.

The fifth active layer ACT5 may include a channel region overlapping the fifth gate electrode GE5, and a source region and a drain region located on opposite sides of the channel region. The source region of the fifth active layer ACT5 may be electrically connected to the first power line VDL. For example, the source region of the fifth active layer ACT5 may be electrically connected to the second connection electrode CNE2 through the seventh contact hole CH7, and may be electrically connected to the first power line VDL through the second connection electrode CNE2. The drain region of the fifth active layer ACT5 may be electrically connected to the first, second, and eighth active layers ACT1, ACT2, and ACT8 included in the first, second, and eighth transistors T1, T2, and T8. For example, the drain region of the fifth active layer ACT5 may be electrically connected to the source region of the first active layer ACT1 and the drain region of each of the second and eighth active layers ACT2 and ACT8.

In one or more embodiments, the fifth active layer ACT5 may cross the first emission control line EL1 and the second emission control line EL2 electrically connected to the sub-pixels SPX of the corresponding pixel PX. For example, the fifth active layer ACT5 may have an approximately “U” or “Y” shape around the first emission control line EL1 and the second emission control line EL2, and may cross the first emission control line EL1 and the second emission control line EL2.

The fifth gate electrode GE5 may be electrically connected to any one emission control line EL from among the first emission control line EL1 and the second emission control line EL2. For example, the fifth gate electrode GE5 may be electrically connected to the first emission control line EL1 or the second emission control line EL2 located on the corresponding horizontal line through a tenth contact hole CH10_1 or CH10_2. For example, the fifth gate electrode GE5 included in the first pixel circuit PXC1 may be electrically connected to the first emission control line EL1 through the tenth contact hole CH10_1 overlapping the first emission control line EL1, and the fifth gate electrode GE5 included in each of the second and third pixel circuits PXC2 and PXC3 may be electrically connected to the second emission control line EL2 through the tenth contact hole CH10_2 overlapping the second emission control line EL2.

The sixth transistor T6 may include the sixth active layer ACT6 and a sixth gate electrode GE6. The sixth gate electrode GE6 may overlap a part of the sixth active layer ACT6.

The sixth active layer ACT6 may include a channel region overlapping the sixth gate electrode GE6, and a source region and a drain region located on opposite sides of the channel region. The source region of the sixth active layer ACT6 may be electrically connected to the first and third active layers ACT1 and ACT3 included in the first and third transistors T1 and T3. For example, the source region of the sixth active layer ACT6 may be electrically connected to the drain region of each of the first and third active layers ACT1 and ACT3. The drain region of the sixth active layer ACT6 may be electrically connected to the light emitting element LE. For example, the drain region of the sixth active layer ACT6 may be electrically connected to the fourth connection electrode CNE4 through an eleventh contact hole CH11, and may be electrically connected to the pixel electrode of each sub-pixel SPX through the fourth and fifth connection electrodes CNE4 and CNE5. The fourth connection electrode CNE4 may be electrically connected to the fifth connection electrode CNE5 through a third via hole VH3 (or contact hole). The fifth connection electrode CNE5 may be electrically connected to the pixel electrode of each sub-pixel SPX through an anode contact hole ANH (cathode contact hole in the case of a display panel with a common-anode structure) of each sub-pixel SPX. For example, the fifth connection electrode CNE5 of the first pixel circuit PXC1 may be electrically connected to the first pixel electrode connected to the light emitting element LE of the first sub-pixel SPX1 through a first anode contact hole ANH1 overlapping the first pixel circuit PXC1. The fifth connection electrode CNE5 of the second pixel circuit PXC2 may be electrically connected to the second pixel electrode connected to the light emitting element LE of the second sub-pixel SPX2 through a second anode contact hole ANH2 overlapping the second pixel circuit PXC2. The fifth connection electrode CNE5 of the third pixel circuit PXC3 may be electrically connected to the third pixel electrode connected to the light emitting element LE of the third sub-pixel SPX3 through a third anode contact hole ANH3 overlapping the third pixel circuit PXC3. In one or more embodiments, the sixth active layer ACT6 may cross the first emission control line EL1 and the second emission control line EL2 electrically connected to the corresponding pixel PX.

The sixth gate electrode GE6 may be electrically connected to any one emission control line EL. For example, the sixth gate electrode GE6 may be electrically connected to the first emission control line EL1 or the second emission control line EL2 located on the corresponding horizontal line through the tenth contact hole CH10_1 or CH10_2. For example, the sixth gate electrode GE6 included in the first pixel circuit PXC1 may be electrically connected to the first emission control line EL1 through the tenth contact hole CH10_1 overlapping the first emission control line EL1, and the sixth gate electrode GE6 included in each of the second and third pixel circuits PXC2 and PXC3 may be electrically connected to the second emission control line EL2 through the tenth contact hole CH10_2 overlapping the second emission control line EL2.

In one or more embodiments, the fifth and sixth gate electrodes GE5 and GE6 of the first pixel circuit PXC1 may be formed as one conductive pattern overlapping the first emission control line EL1, and may be electrically connected to the first emission control line EL1 through one tenth contact hole CH10_1 located between the fifth gate electrode GE5 and the sixth gate electrode GE6 of the first pixel circuit PXC1. Further, the fifth and sixth gate electrodes GE5 and GE6 of the second and third pixel circuits PXC2 and PXC3 may be formed as one conductive pattern overlapping the second emission control line EL2, and may be electrically connected to the second emission control line EL2 through one tenth contact hole CH10_2 located between the second and third pixel circuits PXC2 and PXC3. Accordingly, the design structure of the pixel circuits PXC may be further simplified or optimized.

The seventh transistor T7 may include a seventh active layer ACT7 and a seventh gate electrode GE7. The seventh gate electrode GE7 may overlap a part of the seventh active layer ACT7.

The seventh active layer ACT7 may include a channel region overlapping the seventh gate electrode GE7, and a source region and a drain region located on opposite sides of the channel region. The source region of the seventh active layer ACT7 may be electrically connected to the sixth active layer ACT6 and the light emitting element LE. For example, the sixth and seventh active layers ACT6 and ACT7 may be formed integrally, and the source region of the seventh active layer ACT7 may be electrically connected to the drain region of the sixth active layer ACT6. Further, the source region of the seventh active layer ACT7 may be electrically connected to the fourth connection electrode CNE4 through an eleventh contact hole CH11, and may be electrically connected to the pixel electrode of each sub-pixel SPX through the fourth and fifth connection electrodes CNE4 and CNE5. The drain region of the seventh active layer ACT7 may be electrically connected to the fourth power line VAIL. For example, the drain region of the seventh active layer ACT7 may be electrically connected to the sixth connection electrode CNE6 through a twelfth contact hole CH12, and may be electrically connected to the fourth power line VAIL through the sixth connection electrode CNE6. The sixth connection electrode CNE6 may be electrically connected to the fourth power line VAIL through a thirteenth contact hole CH13.

The seventh gate electrode GE7 may be electrically connected to the bias scan line GBL. For example, the seventh gate electrode GE7 and the bias scan line GBL may be formed integrally, and may be formed substantially as one conductive pattern. In this case, a part of the bias scan line GBL overlapping the seventh active layer ACT7 may function as the seventh gate electrode GE7.

The eighth transistor T8 may include the eighth active layer ACT8 and an eighth gate electrode GE8. The eighth gate electrode GE8 may overlap a part of the eighth active layer ACT8.

The eighth active layer ACT8 may include a channel region overlapping the eighth gate electrode GE8, and a source region and a drain region located on opposite sides of the channel region. The source region of the eighth active layer ACT8 may be electrically connected to the fifth power line VOBL. For example, the source region of the eighth active layer ACT8 may be electrically connected to the seventh connection electrode CNE7 through a fourteenth contact hole CH14, and may be electrically connected to the fifth power line VOBL through the seventh connection electrode CNE7. The seventh connection electrode CNE7 may be electrically connected to the fifth power line VOBL through a fifteenth contact hole CH15. The drain region of the eighth active layer ACT8 may be electrically connected to the first, second, and fifth active layers ACT1, ACT2, and ACT5 included in the first, second, and fifth transistors T1, T2, and T5. For example, the drain region of the eighth active layer ACT8 may be electrically connected to the source region of the first active layer ACT1 and the drain region of each of the second and fifth active layers ACT2 and ACT5.

In one or more embodiments, the first active layer ACT1, the second active layer ACT2, the fifth active layer ACT5, the sixth active layer ACT6, the seventh active layer ACT7, and the eighth active layer ACT8 of each of the first pixel circuit PXC1, the second pixel circuit PXC2, and the third pixel circuit PXC3 may be formed integrally, and may be substantially formed as one semiconductor pattern. The first active layer ACT1, the second active layer ACT2, the fifth active layer ACT5, the sixth active layer ACT6, the seventh active layer ACT7, and the eighth active layer ACT8 may include the same semiconductor material, for example, polycrystalline silicon.

The eighth gate electrode GE8 may be electrically connected to the bias scan line GBL. For example, the eighth gate electrode GE8 and the bias scan line GBL may be formed integrally, and may be formed substantially as one conductive pattern. In this case, a part of the bias scan line GBL overlapping the eighth active layer ACT8 may function as the eighth gate electrode GE8.

When the backplane layer BPL further includes the second power line VSL located in the display area DA as in the embodiments of FIGS. 9-12, the second power line VSL may be electrically connected to a common electrode on the backplane layer BPL. For example, the second power line VSL may be electrically connected to the common electrode located in a light emitting element layer EDL on the backplane layer BPL through a cathode contact hole CDH (anode contact hole in the case of a display panel with a common-cathode structure) located in each pixel area PXA, and may be electrically connected to the light emitting elements LE of the sub-pixels SPX through the common electrode. In one or more embodiments, one cathode contact hole CDH may be formed for each pixel area PXA and may overlap the second pixel circuit PXC2, but is not limited thereto. The number or position of the cathode contact hole CDH located in each pixel area PXA or display area DA may vary depending on embodiments.

The power lines PL and the signal lines of the backplane layer BPL may be located around circuit elements where the respective lines are connected. In one or more embodiments, the first power line VDL may have a relatively large width at positions corresponding to the first transistor T1, the third transistor T3, and the fourth transistor T4, and may cover at least a part of each of the first transistor T1, the third transistor T3, and the fourth transistor T4. For example, the first power line VDL may entirely or partially cover the channel region of each of the first transistor T1, the third transistor T3, and the fourth transistor T4. For example, the first power line VDL overlapping the first pixel circuit PXC1 may cover the channel region of each of the first transistor T1, the third transistor T3, and the fourth transistor T4 of the first pixel circuit PXC1, and the first power line VDL overlapping the second and third pixel circuits PXC2 and PXC3 may cover the channel region of each of the first transistors T1, the third transistors T3, and the fourth transistors T4 of the second and third pixel circuits PXC2 and PXC3. Accordingly, light incident from the upper side of the backplane layer BPL toward the channel regions of the first transistor T1, the third transistor T3, and the fourth transistor T4 may be blocked or reduced. Accordingly, the operating characteristics of the first transistor T1, the third transistor T3, and the fourth transistor T4 may be stabilized. Further, by converting at least a part of the first transistors T1, the third transistors T3, and the fourth transistors T4 with the first power line VDL located on the first transistors T1, the third transistors T3, and the fourth transistors T4, the operating characteristics of the sub-pixels SPX may be improved without locating (e.g., arranging) a separate light blocking pattern above the first transistors T1, the third transistors T3, and the fourth transistors T4. For example, the first power line VDL may be formed integrally with the light blocking pattern located above the first transistors T1, the third transistors T3, and the fourth transistors T4. Accordingly, the design structure of the backplane layer BPL may be further optimized, and a space may be secured between the patterns included in the backplane layer BPL.

In one or more embodiments, the sub-pixels SPX may be driven with the driving current Ids that is differentiated or optimized according to the optimal consumption efficiency of the light emitting elements LE. Further, the pixel transistors PXT located in a current path through which the driving current Ids flows in the sub-pixels SPX may have differentiated sizes according to each driving current Ids. For example, the sizes (for example, the ratio of the channel width to the channel length) of the first transistors T1 of at least two sub-pixels SPX from among the first sub-pixel SPX1, the second sub-pixel SPX2, and the third sub-pixel SPX3 may be different from each other.

In one or more embodiments, the first sub-pixel SPX1 may be driven with the driving current Ids higher than that of the second sub-pixel SPX2 and the third sub-pixel SPX3 in response to the data voltage Vdata of each grayscale. In this case, the size of the first transistor T1 of the first sub-pixel SPX1 may be greater than the size of the first transistor T1 of each of the second sub-pixel SPX2 and the third sub-pixel SPX3. For example, the ratio of the channel width to the channel length of the first transistor T1 of the first sub-pixel SPX1 may be greater than the ratio of the channel width to the channel length of the first transistor T1 of each of the second sub-pixel SPX2 and the third sub-pixel SPX3. Similarly, the size (e.g., the ratio of the channel width to the channel length) of the fifth transistor T5 of the first sub-pixel SPX1 may be greater than the size (e.g., the ratio of the channel width to the channel length) of the fifth transistor T5 of each of the second sub-pixel SPX2 and the third sub-pixel SPX3, and the size of the sixth transistor T6 of the first sub-pixel SPX1 may be greater than the size of the sixth transistor T6 of each of the second sub-pixel SPX2 and the third sub-pixel SPX3. Accordingly, the current handling capability of the first transistor T1 included in the first sub-pixel SPX1 may be increased.

When the sub-pixels SPX are driven with the driving current Ids optimized according to the optimal consumption efficiency of the respective light emitting elements LE, the consumption efficiency and lifespan of the light emitting elements LE may be improved. Accordingly, the power consumption and lifespan of the display device 10 may be improved.

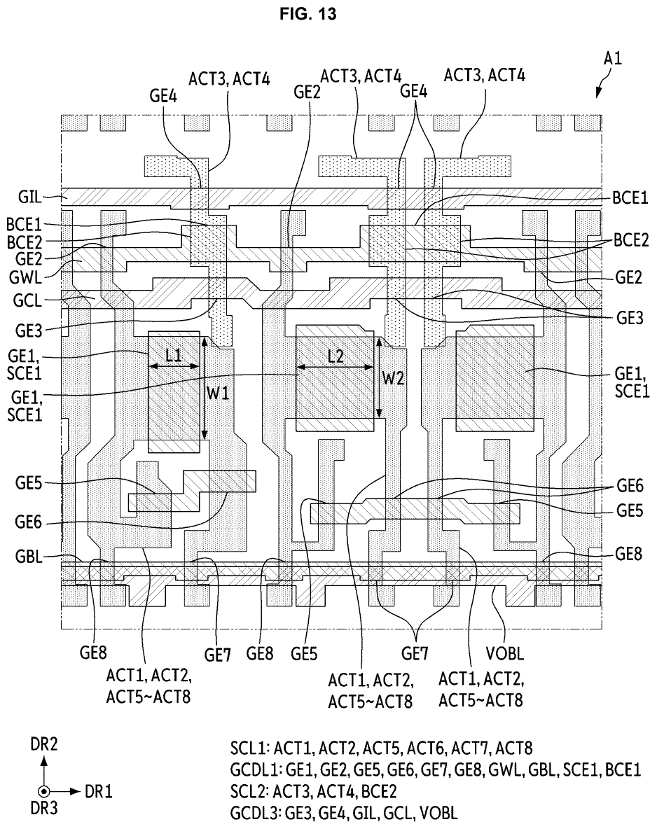

FIG. 13 is a layout diagram showing patterns included in a first semiconductor layer, a first gate conductive layer, a second semiconductor layer, and a third gate conductive layer of a backplane layer according to one or more embodiments. For example, FIG. 13 shows in detail patterns of a first semiconductor layer SCL1, a first gate conductive layer GCDL1, a second semiconductor layer SCL2, and a third gate conductive layer GCDL3 located in area A1 of FIG. 9.

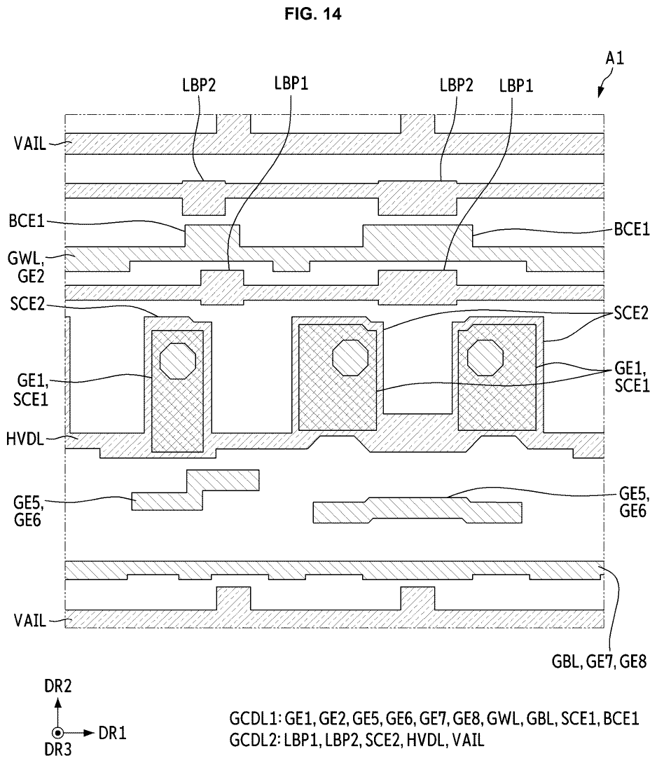

FIG. 14 is a layout diagram showing patterns included in a first gate conductive layer and a second gate conductive layer according to one or more embodiments. For example, FIG. 14 shows in detail patterns of the first gate conductive layer GCDL1 and a second gate conductive layer GCDL2 located in area A1 of FIG. 9.

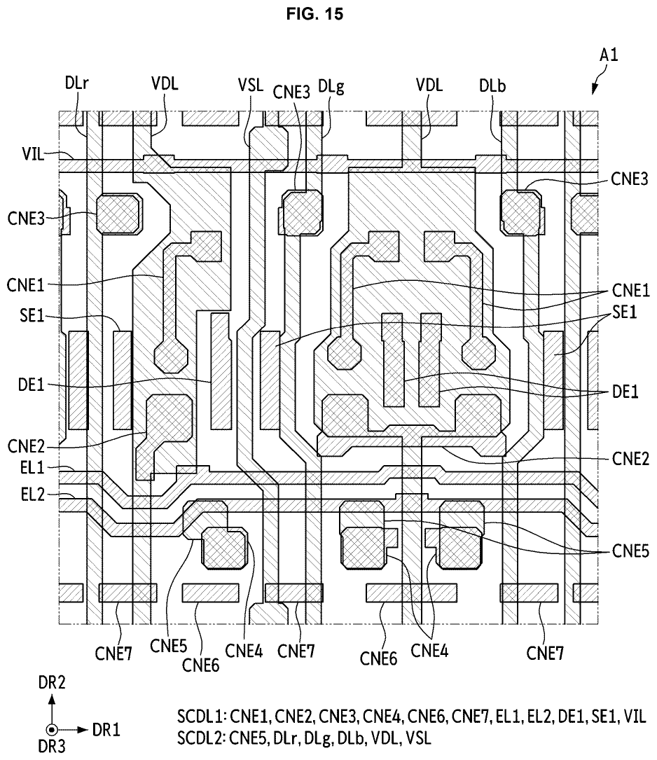

FIG. 15 is a layout diagram showing patterns included in a first source-drain conductive layer and a second source-drain conductive layer of a backplane layer according to one or more embodiments. For example, FIG. 15 shows in detail patterns of a first source-drain conductive layer SCDL1 and a second source-drain conductive layer SCDL2 located in area A1 of FIG. 9.

Referring to FIGS. 13-15 in addition to FIGS. 9-12, circuit elements and wires of the backplane layer BPL may be located in a plurality of semiconductor layers and conductive layers. For example, the circuit elements and wires of the backplane layer BPL may be formed as patterns of the first semiconductor layer SCL1, the first gate conductive layer GCDL1, the second gate conductive layer GCDL2, the second semiconductor layer SCL2, the third gate conductive layer GCDL3, the first source-drain conductive layer SCDL1, and the second source-drain conductive layer SCDL2 of the backplane layer BPL.

The first semiconductor layer SCL1 may include the first, second, fifth, sixth, seventh, and eighth active layers ACT1, ACT2, ACT5, ACT6, ACT7, and ACT8.

The first gate conductive layer GCDL1 may include the first, second, fifth, sixth, seventh, and eighth gate electrodes GE1, GE2, GE5, GE6, GE7, and GE8, the write scan line GWL, the bias scan line GBL, the first electrode SCE1 of the storage capacitor Cst, and the first electrode BCE1 of the boosting capacitor Cbst.

In each sub-pixel SPX, the region where the first active layer ACT1 and the first gate electrode GCDL1 overlap may include the channel region of the first transistor T1. In one or more embodiments, the first sub-pixel SPX1 may be driven with the driving current Ids higher than that of the second sub-pixel SPX2, and a ratio (W1/L1) of a width W1 to a length L1 of the channel region of the first transistor T1 included in the first sub-pixel SPX1 may be greater than a ratio (W2/L2) of a width W2 to a length L2 of the channel region of the first transistor T1 included in the second sub-pixel SPX2. For example, compared to the first active layer ACT1 of the second sub-pixel SPX2, the first active layer ACT1 of the first sub-pixel SPX1 may have a reduced size in the first direction DR1 corresponding to the longitudinal direction of the channel region, and may have an expanded size in the second direction DR2 corresponding to the width direction of the channel region. Accordingly, compared to the first transistor T1 of the second sub-pixel SPX2, the first transistor T1 of the first sub-pixel SPX1 may have a reduced size in the first direction DR1 and an expanded size in the second direction DR2. In one or more embodiments, because the width W1 of the channel region of the first transistor T1 of the first sub-pixel SPX1 is expanded, the first transistor T1 and the third and fourth transistors T3 and T4 may be located closer to each other.

Similarly, the first sub-pixel SPX1 may be driven with the driving current Ids higher than that of the third sub-pixel SPX3, and the ratio (W1/L1) of the width W1 to the length L1 of the channel region of the first transistor T1 included in the first sub-pixel SPX1 may be greater than the ratio of the width to the length of the channel region of the first transistor T1 included in the third sub-pixel SPX3. In one or more embodiments, the first transistor T1 of the second sub-pixel SPX2 and the first transistor T1 of the third sub-pixel SPX3 may have substantially the same size and may have a symmetrical shape, but are not limited thereto.

In one or more embodiments, because the first sub-pixel SPX1 is driven with the driving current Ids higher than that of the second and third sub-pixels SPX2 and SPX3, the sizes of the fifth and sixth transistors T5 and T6 of the first sub-pixel SPX1 may also be increased. For example, the ratios of the widths to the lengths of the channel regions of the fifth and sixth transistors T5 and T6 of the first sub-pixel SPX1 may be greater than the ratios of the widths to the lengths of the channel regions of the fifth and sixth transistors T5 and T6 of the second and third sub-pixels SPX2 and SPX3, respectively. For example, in the first sub-pixel SPX1, by expanding the width (for example, the horizontal length along the first direction DR1) of the channel regions of the fifth and sixth active layers ACT5 and ACT6 overlapping the fifth and sixth gate electrodes GE5 and GE6, the operating characteristics of the first sub-pixel SPX1 may be improved.

The second gate conductive layer GCDL2 may include the first light blocking pattern LBP1, the second light blocking pattern LBP2, the second electrode SCE2 of the storage capacitor Cst, the horizontal power line HVDL, and the fourth power line VAIL.

The second semiconductor layer SCL2 may include the third and fourth active layers ACT3 and ACT4, and the second electrode BCE2 of the boosting capacitor Cbst.

The third gate conductive layer GCDL3 may include the third and fourth gate electrodes GE3 and GE4, the initialization scan line GIL, the control scan line GCL, and the fifth power line VOBL.

The first source-drain conductive layer SCDL1 may include the first, second, third, fourth, sixth, and seventh connection electrodes CNE1, CNE2, CNE3, CNE4, CNE6, and CNE7, the first and second emission control lines EL1 and EL2, the source electrode SE1 and the drain electrode DE1 of the first transistor T1, and the third power line VIL.

The second source-drain conductive layer SCDL2 may include the fifth connection electrode CNE5, the first, second, and third data lines DLr, DLg, and DLb, and the first and second power lines VDL and VSL.

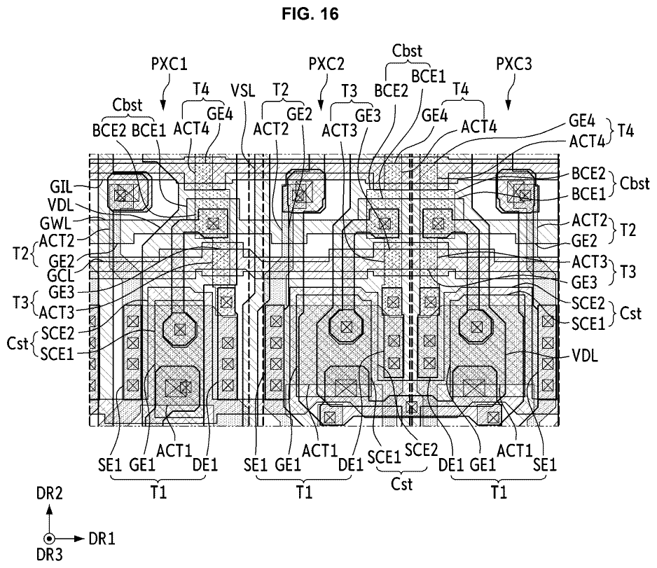

FIG. 16 is a layout diagram showing in detail a part of a first pixel circuit, a second pixel circuit, and a third pixel circuit according to one or more embodiments. For example, FIG. 16 shows in detail the first to fourth transistors T1, T2, T3, and T4, the storage capacitor Cst, and the boosting capacitor Cbst of each of the first pixel circuit PXC1, the second pixel circuit PXC2, and the third pixel circuit PXC3.

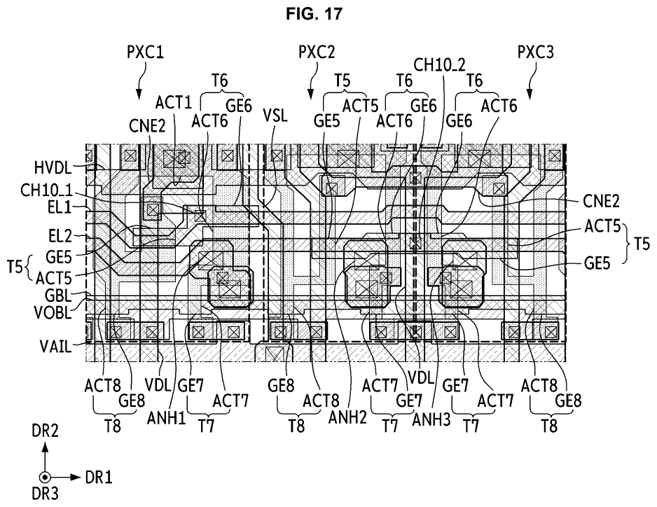

FIG. 17 is a layout diagram showing in detail a part of a first pixel circuit, a second pixel circuit, and a third pixel circuit according to one or more embodiments. For example, FIG. 17 shows in detail the fifth to eighth transistors T5, T6, T7, and T8 of each of the first pixel circuit PXC1, the second pixel circuit PXC2, and the third pixel circuit PXC3.

Referring to FIGS. 16 and 17 in addition to FIGS. 9-15, the second pixel circuit PXC2 and the third pixel circuit PXC3 may have a symmetrical shape. For example, the second pixel circuit PXC2 and the third pixel circuit PXC3 may share one first power line VDL, and may be arranged in a flipped shape with respect to the first power line VDL. For example, the second pixel circuit PXC2 and the third pixel circuit PXC3 may be commonly connected to one first power line VDL in each pixel area PXA, and may have a symmetrical shape with respect to the one first power line VDL.

In one or more embodiments, the second pixel circuit PXC2 and the third pixel circuit PXC3 may be designed symmetrically to be in contact with each other in the region where one first power line VDL is located and have a substantially symmetrical shape and/or an inverted shape with respect to the first power line VDL. For example, the second pixel circuit PXC2 and the third pixel circuit PXC3 may have a substantially symmetrical shape with respect to the central axis (for example, the vertical central axis extending in the second direction DR2) of the first power line VDL.

Specifically, the first to eighth transistors T1, T2, T3, T4, T5, T6, T7, and T8, the storage capacitor Cst, and the boosting capacitor Cbst of the second pixel circuit PXC2 may be located at positions facing the first to eighth transistors T1, T2, T3, T4, T5, T6, T7, and T8, the storage capacitor Cst, and the boosting capacitor Cbst of the third pixel circuit PXC3 in the first direction DR1, respectively. Further, the first to eighth transistors T1, T2, T3, T4, T5, T6, T7, and T8, the storage capacitor Cst, and the boosting capacitor Cbst of the second pixel circuit PXC2, and the first to eighth transistors T1, T2, T3, T4, T5, T6, T7, and T8, the storage capacitor Cst, and the boosting capacitor Cbst of the third pixel circuit PXC3 may have a substantially symmetrical shape with respect to the boundary between the second pixel circuit PXC2 and the third pixel circuit PXC3.

In one or more embodiments, the first transistors T1 of the first pixel circuit PXC1, the second pixel circuit PXC2, and the third pixel circuit PXC3 may be arranged sequentially along the first direction DR1. When the second pixel circuit PXC2 and the third pixel circuit PXC3 have a symmetrical shape, the drain electrode DE1 of the first transistor T1 included in the second pixel circuit PXC2 and the drain electrode DE1 of the first transistor T1 included in the third pixel circuit PXC3 may be located adjacent to each other in the first direction DR1. The drain electrode DE1 of the first transistor T1 included in the first pixel circuit PXC1 and the source electrode SE1 of the first transistor T1 included in the second pixel circuit PXC2 may be located adjacent to each other in the first direction DR1. The source electrode SE1 of the first transistor T1 included in the first pixel circuit PXC1 may be adjacent to the source electrode SE1 of the first transistor T1 included in the third pixel circuit PXC3 of another pixel PX adjacent in the first direction DR1. The source electrode SE1 of the first transistor T1 included in the third pixel circuit PXC3 may be adjacent to the source electrode SE1 of the first transistor T1 included in the first pixel circuit PXC1 of another pixel PX adjacent in the first direction DR1.

In one or more embodiments, the third and fourth transistors T3 and T4 of the second pixel circuit PXC2 and the third and fourth transistors T3 and T4 of the third pixel circuit PXC3 may be located adjacent to each other in the first direction DR1. For example, the third and fourth transistors T3 and T4 of the second pixel circuit PXC2 and the third and fourth transistors T3 and T4 of the third pixel circuit PXC3 may be located around the boundary between the second pixel circuit PXC2 and the third pixel circuit PXC3.

The first power line VDL shared by the second pixel circuit PXC2 and the third pixel circuit PXC3 may have a wider width at the central portions of the second and third pixel circuits PXC2 and PXC3 to overlap the first, third and fourth transistors T1, T3, and T4 of the second and third pixel circuits PXC2 and PXC3. Further, the first power line VDL shared by the second pixel circuit PXC2 and the third pixel circuit PXC3 may be located in the region between the second anode contact hole ANH2 and the third anode contact hole ANH3, and may extend in the second direction DR2 between the second anode contact hole ANH2 and the third anode contact hole ANH3. For example, the first power line VDL shared by the second pixel circuit PXC2 and the third pixel circuit PXC3 may pass through the region between the second anode contact hole ANH2 and the third anode contact hole ANH3 (for example, the center between the second anode contact hole ANH2 and the third anode contact hole ANH3).

The first and second emission control lines EL1 and EL2 may cross or overlap the fifth and sixth active layers ACT5 and ACT6 included in the fifth and sixth transistors T5 and T6 of each of the first pixel circuit PXC1, the second pixel circuit PXC2, and the third pixel circuit PXC3, respectively. However, the first and second emission control lines EL1 and EL2 and the fifth and sixth gate electrodes GE5 and GE6 included in the fifth and sixth transistors T5 and T6 of each of the first pixel circuit PXC1, the second pixel circuit PXC2, and the third pixel circuit PXC3 may be located in different conductive layers. For example, the first and second emission control lines EL1 and EL2 may be located in the first source-drain conductive layer SCDL1, and the fifth and sixth gate electrodes GE5 and GE6 may be located in the first gate conductive layer GCDL1.

The fifth and sixth gate electrodes GE5 and GE6 of the first pixel circuit PXC1 may overlap the first emission control line EL1, and may be electrically connected to the first emission control line EL1 through one tenth contact hole CH10_1. For example, the tenth contact hole CH10_1 of the first pixel circuit PXC1 may be located between the fifth gate electrode GE5 and the sixth gate electrode GE6 of the first pixel circuit PXC1.

The fifth and sixth gate electrodes GE5 and GE6 of the second pixel circuit PXC2 and the fifth and sixth gate electrodes GE5 and GE6 of the third pixel circuit PXC3 may overlap the second emission control line EL2, and may be electrically connected to the second emission control line EL2 through one tenth contact hole CH10_2. In one or more embodiments, the fifth and sixth gate electrodes GE5 and GE6 of the second pixel circuit PXC2 and the fifth and sixth gate electrodes GE5 and GE6 of the third pixel circuit PXC3 may be formed as one conductive pattern, and may share one tenth contact hole CH10_2. For example, the tenth contact hole CH10_2 of the second and third pixel circuits PXC2 and PXC3 may be located between the fifth and sixth gate electrodes GE5 and GE6 of the second pixel circuit PXC2 and the fifth and sixth gate electrodes GE5 and GE6 of the third pixel circuit PXC3 (for example, between the sixth gate electrode GE6 of the second pixel circuit PXC2 and the sixth gate electrode GE6 of the third pixel circuit PXC3).

The fifth and eighth active layers ACT5 and ACT8 of each of the pixel circuits PXC may extend downward from one end of the first active layer ACT1 of each of the pixel circuits PXC. For example, the fifth and eighth active layers ACT5 and ACT8 of each of the first pixel circuit PXC1 and the second pixel circuit PXC2 may be formed from a part of a semiconductor pattern, which extends downward from the left end of the first active layer ACT1 of each of the first pixel circuit PXC1 and the second pixel circuit PXC2, and may be located at the left lower portion of each of the first pixel circuit PXC1 and the second pixel circuit PXC2. On the other hand, the fifth and eighth active layers ACT5 and ACT8 of the third pixel circuit PXC3 may be formed from another part of the semiconductor pattern, which extends downward from the right end of the first active layer ACT1 of the third pixel circuit PXC3, and may be located at the right lower portion of the third pixel circuit PXC3. A part of the semiconductor pattern extending from one end (for example, an end connected to the source electrode SE1) of the first active layer ACT1 of each of the pixel circuits PXC to the fifth and eighth active layers ACT5 and ACT8 may have an approximately “U” or “Y” shape around the first and second emission control lines EL1 and EL2, and may cross or overlap the first and second emission control lines EL1 and EL2. Another portion of the semiconductor pattern extending from another end (for example, an end connected to the drain electrode DE1) of the first active layer ACT1 of each of the pixel circuits PXC to the sixth active layer ACT6 may have a shape extending approximately in the second direction DR2 around the first and second emission control lines EL1 and EL2, and may cross or overlap the first and second emission control lines EL1 and EL2. Because the first and second emission control lines EL1 and EL2 are located in a conductive layer different from that of the fifth and sixth gate electrodes GE5 and GE6, even if the semiconductor pattern of the first semiconductor layer SCL1 including the first, second, fifth, sixth, seventh and eighth active layers ACT1, ACT2, ACT5, ACT6, ACT7, and ACT8 of each of the pixel circuits PXC overlaps both the first and second emission control lines EL1 and EL2, the positions where the fifth and sixth transistors T5 and T6 are formed in each sub-pixel SPX may be appropriately adjusted or selected by adjusting the positions of the fifth and sixth gate electrodes GE5 and GE6.

The semiconductor pattern of the first semiconductor layer SCL1 included in each of the pixel circuits PXC may be electrically connected to the second connection electrode CNE2 around the first transistor T1. Further, the semiconductor pattern of the first semiconductor layer SCL1 included in each of the pixel circuits PXC may be electrically connected to the first power line VDL through the second connection electrode CNE2. In one or more embodiments, the second connection electrode CNE2 of each of the pixel circuits PXC may be adjacent to the first and second emission control lines EL1 and EL2. Accordingly, the size of the semiconductor pattern of the first semiconductor layer SCL1 may be reduced or minimized, and the design structure of the pixel circuits PXC may be improved.

In one or more embodiments, the second and third pixel circuits PXC2 and PXC3 may share one second connection electrode CNE2. For example, the second connection electrodes CNE2 of the second and third pixel circuits PXC2 and PXC3 may be formed as one conductive pattern.

In one or more embodiments, the second connection electrodes CNE2 of the second and third pixel circuits PXC2 and PXC3 may overlap the first power line VDL and the first transistors T1 of the second and third pixel circuits PXC2 and PXC3, and may have a shape extending in the first direction DR1 in a region where the second and third pixel circuits PXC2 and PXC3 are located. The second connection electrodes CNE2 of the second and third pixel circuits PXC2 and PXC3 may be electrically connected to the horizontal power line HVDL and the second electrode SCE2 of the storage capacitor Cst through one sixth contact hole CH6. Further, the second connection electrodes CNE2 of the second and third pixel circuits PXC2 and PXC3 may be commonly connected to the fifth active layers ACT5 of the fifth transistors T5 included in the second and third pixel circuits PXC2 and PXC3.

According to the above-described embodiments, the pixel circuits PXC of the sub-pixels SPX may be efficiently located in each pixel area PXA. For example, the second pixel circuit PXC2 and the third pixel circuit PXC3 may be arranged in a flipped shape, and the data lines DL and the power lines PL may be appropriately located according to the shapes of the second pixel circuit PXC2 and the third pixel circuit PXC3. Accordingly, a space for arranging additional wires or the like may be secured. For example, a space for arranging at least one wire may be created between the first pixel circuit PXC1 and the second and third pixel circuits PXC2 and PXC3 included in each pixel PX, and between the pixel circuits PXC of two pixels PX adjacent in the first direction DR1 (for example, between the third pixel circuit PXC3 of the pixel PX located on the left side and the first pixel circuit PXC1 of the pixel PX located on the right side).

In one or more embodiments, the second power line VSL may be located in the space. In one or more embodiments, the second power line VSL may be electrically connected to the common electrode CE in the display area DA. For example, the second power line VSL may be electrically connected to the common electrode CE located on the backplane layer BPL through the cathode contact hole CDH formed for at least one horizontal line. Accordingly, the second power line VSL and the common electrode CE may constitute a mesh-shaped power line in the display area DA. Accordingly, the voltage drop of the second driving voltage VSS may be reduced or minimized, and the power consumption of the display device 10 may be reduced or improved. In one or more embodiments, because the voltage drop of the second driving voltage VSS is reduced, the width of the power bus line connected to the second power line VSL around the display area DA may be reduced. Accordingly, the width of the non-display area NDA may be reduced, or the space utilization rate and/or the design structure of the non-display area NDA may be optimized.

In one or more embodiments, the size of the first transistor T1 included in the first pixel circuit PXC1 may be different from the size of the first transistor T1 included in each of the second sub-pixel SPX2 and the third sub-pixel SPX3. For example, when the first sub-pixel SPX1 is driven with the driving current Ids higher than that of the second sub-pixel SPX2 and the third sub-pixel SPX3 in response to the data voltage Vdata of each grayscale, the ratio (for example, W1/L1) of the channel width (for example, W1 of FIG. 13) to the channel length (for example, L1 of FIG. 13) of the first transistor T1 of the first sub-pixel SPX1 may be greater than the ratio (for example, W2/L2) of the channel width (for example, W2 of FIG. 13) to the channel length (for example, L2 of FIG. 13) of each of the second sub-pixel SPX2 and the third sub-pixel SPX3. For example, by adjusting the size (for example, area) of the region where the first active layer ACT1 and the first gate electrode GE1 overlap in each of the sub-pixels SPX, the size of the first transistor T1 of each of the sub-pixels SPX may be differentiated or optimized in response to the driving current Ids of each of the sub-pixels SPX. Similarly, the ratio of the channel width to the channel length of the fifth transistor T5 of the first sub-pixel SPX1 may be greater than the ratio of the channel width to the channel length of the fifth transistor T5 of each of the second sub-pixel SPX2 and the third sub-pixel SPX3, and the ratio of the channel width to the channel length of the sixth transistor T6 of the first sub-pixel SPX1 may be greater than the ratio of the channel width to the channel length of the sixth transistor T6 of each of the second sub-pixel SPX2 and the third sub-pixel SPX3. Accordingly, the operation of the sub-pixels SPX may be stabilized, and the power consumption of the display device 10 may be improved.

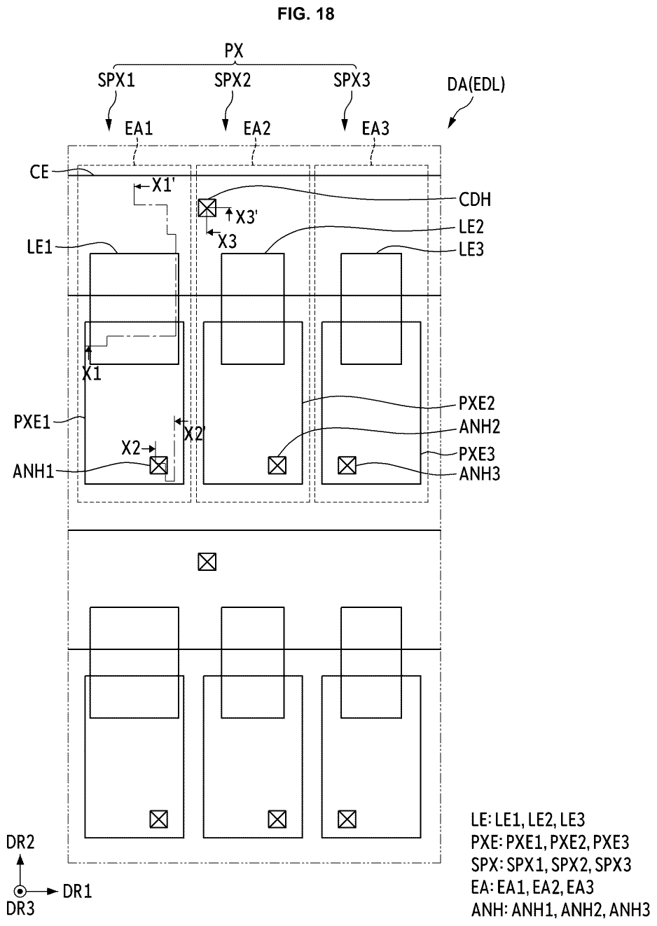

FIG. 18 is a layout diagram illustrating a light emitting element layer of a display panel according to one or more embodiments. For example, FIG. 18 shows the light emitting elements LE, the pixel electrodes PXE, and the common electrodes CE included in the sub-pixels SPX in a part of the display area DA where two adjacent pixels PX are located in the second direction DR2.

Referring to FIG. 18 in addition to FIGS. 3-17, each of the sub-pixels SPX may include the pixel electrode PXE and the light emitting element LE located in the emission area EA. In one or more embodiments, when the light emitting element LE is a micro LED of a flip-chip type or a lateral type, each of the sub-pixels SPX may further include the common electrode CE located on one surface (for example, a bottom surface or top surface) of the light emitting element LE together with the pixel electrode PXE.

Although FIG. 18 illustrates that the emission areas EA of the sub-pixels SPX have the same size, the present disclosure is not limited thereto. For example, the size of the emission areas EA of the sub-pixels SPX may be differentiated or optimized according to the light emission characteristics or the target luminance of each light emitting element LE and/or sub-pixel SPX.

Further, although FIG. 18 illustrates that the pixel electrodes PXE are located only in the respective emission areas EA, the present disclosure is not limited thereto. For example, at least a part of at least one pixel electrode PXE may be located in the non-emission area around the emission area EA. For example, the size, shape, and/or arrangement direction of the pixel electrodes PXE may vary depending on embodiments.

In one or more embodiments, the sub-pixels SPX of each pixel PX may be arranged along the first direction DR1. Further, the sub-pixels SPX of each pixel PX may share one common electrode CE. For example, the common electrode CE may extend in the first direction DR1 in each horizontal line of the display area DA, and the sub-pixels SPX of the pixels PX located on the corresponding horizontal line may share one common electrode CE.

The first sub-pixel SPX1 may include the first pixel electrode PXE1, the first light emitting element LE1, and the common electrode CE (or a part of the common electrode CE) located in the first emission area EA1. The first emission area EA1 may refer to the emission area EA of the first sub-pixel SPX1. The first pixel electrode PXE1 may refer to the pixel electrode PXE of the first sub-pixel SPX1. The first light emitting element LE1 may refer to the light emitting element LE of the first sub-pixel SPX1.

The second sub-pixel SPX2 may include a second pixel electrode PXE2, a second light emitting element LE2, and the common electrode CE located in the second emission area EA2. The second emission area EA2 may refer to the emission area EA of the second sub-pixel SPX2. The second pixel electrode PXE2 may refer to the pixel electrode PXE of the second sub-pixel SPX2. The second light emitting element LE2 may refer to the light emitting element LE of the second sub-pixel SPX2.

The third sub-pixel SPX3 may include a third pixel electrode PXE3, a third light emitting element LE3, and the common electrode CE located in a third emission area EA3. The third emission area EA3 may refer to the emission area EA of the third sub-pixel SPX3. The third pixel electrode PXE3 may refer to the pixel electrode PXE of the third sub-pixel SPX3. The third light emitting element LE3 may refer to the light emitting element LE of the third sub-pixel SPX3.

In each pixel PX, the first pixel electrode PXE1, the second pixel electrode PXE2, and the third pixel electrode PXE3 may be arranged along the first direction DR1. The first pixel electrode PXE1, the second pixel electrode PXE2, and the third pixel electrode PXE3 may be spaced (e.g., spaced apart) from the common electrode CE in the second direction DR2.

The pixel electrodes PXE may be electrically connected to the respective pixel circuits PXC through the respective anode contact holes ANH. For example, the first pixel electrode PXE1 may be electrically connected to the first pixel circuit PXC1 through the first anode contact hole ANH1. The second pixel electrode PXE2 may be electrically connected to the second pixel circuit PXC2 through the second anode contact hole ANH2. The third pixel electrode PXE3 may be electrically connected to the third pixel circuit PXC3 through the third anode contact hole ANH3.

The light emitting elements LE may be located between the respective pixel electrodes PXE and the common electrode CE. For example, the first light emitting element LE1 may be located on the first pixel electrode PXE1 and the common electrode CE, and a part of the first light emitting element LE1 may overlap the first pixel electrode PXE1 and another part of the first light emitting element LE1 may overlap the common electrode CE. The first light emitting element LE1 may be electrically connected between the first pixel electrode PXE1 and the common electrode CE. The second light emitting element LE2 may be located on the second pixel electrode PXE2 and the common electrode CE, and a part of the second light emitting element LE2 may overlap the second pixel electrode PXE2 and another part of the second light emitting element LE2 may overlap the common electrode CE. The second light emitting element LE2 may be electrically connected between the second pixel electrode PXE2 and the common electrode CE. The third light emitting element LE3 may be located on the third pixel electrode PXE3 and the common electrode CE, and a part of the third light emitting element LE3 may overlap the third pixel electrode PXE3 and another part of the third light emitting element LE3 may overlap the common electrode CE. The third light emitting element LE3 may be electrically connected between the third pixel electrode PXE3 and the common electrode CE.

Each of the light emitting elements LE may emit light of a specific color (for example, red light, green light, blue light, or white light). In one or more embodiments, the first light emitting element LE1, the second light emitting element LE2, and the third light emitting element LE3 may emit light of different colors. For example, the first light emitting element LE1, the second light emitting element LE2, and the third light emitting element LE3 may emit light of a first color (for example, red light), light of a second color (for example, green light), and light of a third color (for example, blue light), respectively.

In one embodiment, the light emitting elements LE of at least two sub-pixels SPX may have different sizes. For example, the size of the first light emitting element LE1 may be larger than the size of each of the second light emitting element LE2 and the third light emitting element LE3.

In one or more embodiments, the light emitting elements LE may have a differentiated or optimized size depending on the luminous efficiency of the light emitting elements LE and/or the like. For example, depending on the luminous efficiency of each of the first light emitting element LE1, the second light emitting element LE2, and the third light emitting element LE3, at least two light emitting elements LE from among the first light emitting element LE1, the second light emitting element LE2, and the third light emitting element LE3 may have different sizes. For example, when the luminous efficiency of the first light emitting element LE1 is less than the luminous efficiency of each of the second light emitting element LE2 and the third light emitting element LE3 based on the same size and shape, the size of the first light emitting element LE1 may be larger than the size of each of the second light emitting element LE2 and the third light emitting element LE3. Accordingly, the luminous efficiency of the first light emitting element LE1 may be improved, and the luminous efficiency deviation of the first light emitting element LE1, the second light emitting element LE2, and the third light emitting element LE3 may be reduced or prevented.

In another embodiment, the first light emitting element LE1, the second light emitting element LE2, and the third light emitting element LE3 may emit light of the same color. In this case, at least one of a color filter or a light conversion layer (for example, light conversion layer including wavelength conversion particles such as quantum dots and/or the like) for converting light emitted from the light emitting element LE of the corresponding sub-pixel SPX to light corresponding to the emission color of the corresponding sub-pixel SPX may be located on at least one light emitting element LE of the first sub-pixel SPX1, the second sub-pixel SPX2, and the third sub-pixel SPX3. When the first light emitting element LE1, the second light emitting element LE2, and the third light emitting element LE3 emit light of the same color, the first light emitting element LE1, the second light emitting element LE2, and the third light emitting element LE3 may have the same size or different sizes. For example, depending on the light conversion efficiency by the light conversion layer, at least one of the size of the light emitting elements LE of the sub-pixels SPX or the area of the emission areas EA of the sub-pixels SPX may be differentiated.

Although FIG. 18 shows an embodiment in which each of the first sub-pixel SPX1, the second sub-pixel SPX2, and the third sub-pixel SPX3 includes a single light emitting element LE, the present disclosure is not limited thereto. For example, at least one of the first sub-pixel SPX1, the second sub-pixel SPX2, or the third sub-pixel SPX3 may include a plurality of light emitting elements LE.

The common electrode CE may be electrically connected to the second power line VSL. The second driving voltage VSS may be applied to the common electrode CE and the second power line VSL.

In one or more embodiments, when the backplane layer BPL includes the second power line VSL located in the display area DA, as illustrated in FIGS. 6 and 9, the common electrode CE may be electrically connected to the second power line VSL of the backplane layer BPL through the cathode contact hole CDH in the display area DA. In one or more embodiments, the cathode contact hole CDH may be located in each pixel area PXA, but is not limited thereto. A mesh-shaped power line may be formed in the display area DA by the second power line VSL of the backplane layer BPL and the common electrode CE of the light emitting element layer EDL. Accordingly, the voltage drop of the second driving voltage VSS may be reduced or minimized.

In one or more embodiments, the common electrode CE may extend to the non-display area NDA around the display area DA, and may be electrically connected to a power bus line (for example, bus line to which the second driving voltage VSS is applied) located in the non-display area NDA. When the resistance of the second power line VSL is reduced by locating (or arranging) the second power line VSL in the backplane layer BPL in the display area DA, the width of the power bus line to which the second driving voltage VSS is applied may be reduced. Accordingly, a wiring area of the non-display area NDA may be reduced.

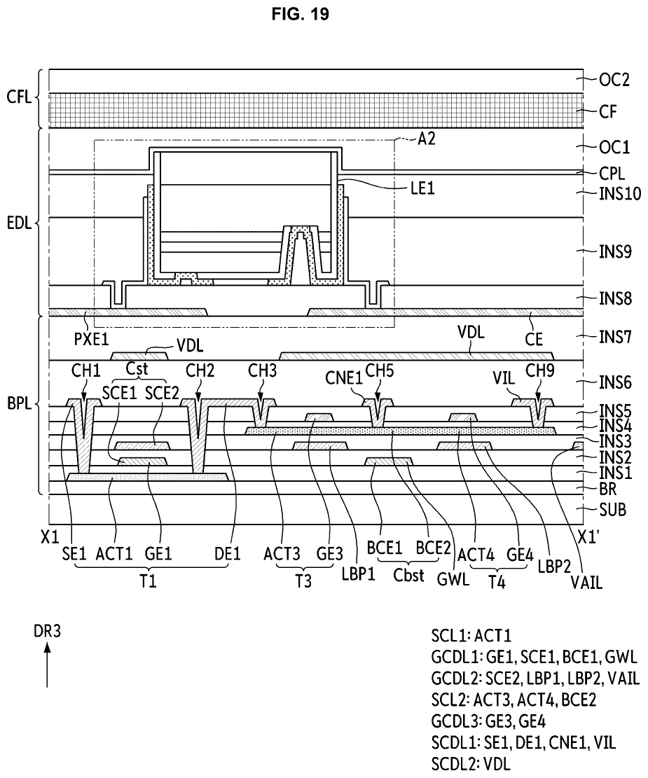

FIG. 19 is a cross-sectional view showing an example of a cross-section of the display panel corresponding to the line X1-X1′ of FIGS. 9 and 18. For example, FIG. 19 shows an example of the cross-section of the display panel 100 corresponding to a part of the first sub-pixel SPX1. In one or more embodiments, the first sub-pixel SPX1, the second sub-pixel SPX2, and the third sub-pixel SPX3 may have substantially the same or similar cross-sectional structures. For example, the corresponding circuit elements (for example, the first transistors T1 of the first sub-pixel SPX1, the second sub-pixel SPX2, and the third sub-pixel SPX3) of the first sub-pixel SPX1, the second sub-pixel SPX2, and the third sub-pixel SPX3 may be located in substantially the same layer, and may have substantially the same or similar cross-sectional structures.

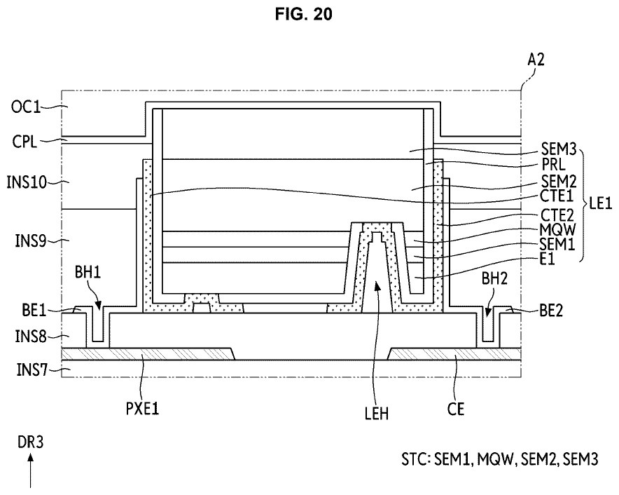

FIG. 20 is a cross-sectional view showing area A2 of FIG. 19 in detail. In one or more embodiments, the first light emitting element LE1, the second light emitting element LE2, and the third light emitting element LE3 may have substantially the same or similar cross-sectional structure.

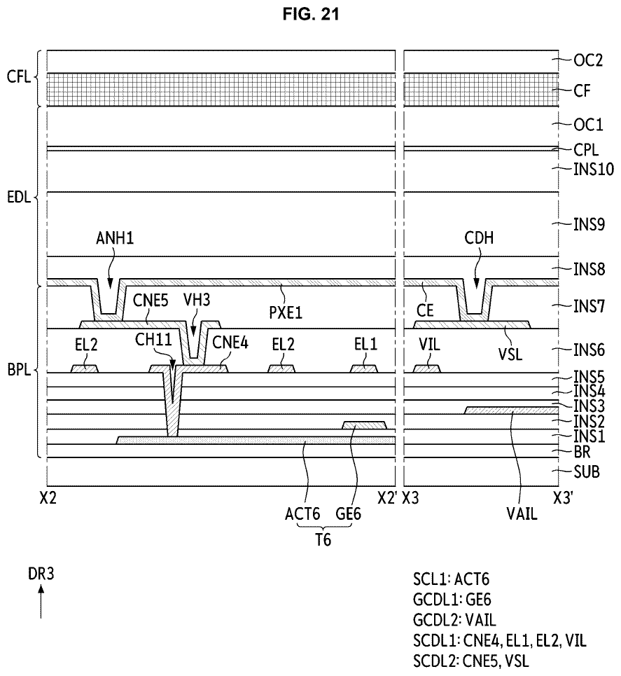

FIG. 21 is a cross-sectional view showing an example of a cross-section of the display panel corresponding to lines X2-X2′ and X3-X3′ of FIGS. 9 and 18.

Referring to FIGS. 19-21 in addition to FIGS. 9-18, the display panel 100 may include a substrate SUB, and the backplane layer BPL and the light emitting element layer EDL located on the substrate SUB. In one or more embodiments, the display panel 100 may further include the color filter layer CFL located on the light emitting element layer EDL. The backplane layer BPL, the light emitting element layer EDL, and the color filter layer CFL may be sequentially located on the substrate SUB along the third direction DR3 (e.g., a thickness direction of the substrate SUB).

The substrate SUB may include an insulating material such as glass and/or polymer resin. When the substrate SUB includes polymer resin, it may be a flexible substrate that can be stretched. The polymer resin may include acryl resin, epoxy resin, phenolic resin, polyamide resin, and/or polyimide resin.

The substrate SUB may include the display area DA and the non-display area NDA. The display area DA may include the pixel areas PXA where the pixels PX are arranged. Each of the pixel areas PXA may include the emission areas EA of the sub-pixels SPX.

The backplane layer BPL may include circuit elements included in the pixel circuits PXC of the sub-pixels SPX and wires connected to the sub-pixels SPX. In one or more embodiments, the backplane layer BPL may be formed entirely on one surface of the substrate SUB.

The backplane layer BPL may include at least one semiconductor layer, conductive layers, or insulating layers. In one or more embodiments, when the pixel circuits PXC include at least two types of pixel transistors PXT containing different materials, the backplane layer BPL may include a plurality of semiconductor layers.

For example, the backplane layer BPL may include a barrier layer BR (or a buffer layer), the first semiconductor layer SCL1 (e.g., a polycrystalline silicon semiconductor layer), a first insulating layer INS1 (e.g., a first inorganic insulating layer), the first gate conductive layer GCDL1 (or a first conductive layer), a second insulating layer INS2 (e.g., a second inorganic insulating layer), the second gate conductive layer GCDL2 (or a second conductive layer), a third insulating layer INS3 (e.g., a third inorganic insulating layer), the second semiconductor layer SCL2 (e.g., an oxide semiconductor layer), a fourth insulating layer INS4 (e.g., a fourth inorganic insulating layer), the third gate conductive layer GCDL3 (or a third conductive layer), a fifth insulating layer INS5 (e.g., a fifth inorganic insulating layer), the first source-drain conductive layer SCDL1 (or a fourth conductive layer), a sixth insulating layer INS6 (e.g., a first organic insulating layer), the second source-drain conductive layer SCDL2 (or a fifth conductive layer), and a seventh insulating layer INS7 (e.g., a second organic insulating layer) that are sequentially located on the substrate SUB along the third direction DR3.

The barrier layer BR may be located on the substrate SUB. The barrier layer BR may protect the circuit elements of the backplane layer BPL and the light emitting elements LE on the backplane layer BPL from moisture permeating through the substrate SUB that is susceptible to moisture permeation. In one or more embodiments, the barrier layer BR may be formed as a plurality of inorganic films.

The circuit elements of the backplane layer BPL may be located on the barrier layer BR. For example, in each of the pixel areas PXA on the barrier layer BR, the pixel transistors PXT, the storage capacitor Cst, and the boosting capacitors Cbst of each of the pixel circuits PXC included in the corresponding pixel PX may be located. Additionally, wires of the backplane layer BPL may be located on the barrier layer BR. For example, the write scan line GWL, the initialization scan line GIL, the control scan line GCL, the bias scan line GBL, the first emission control line EL1, the second emission control line EL2, the first data line DLr, the second data line DLg, the third data line DLb, the first power line VDL, the second power line VSL, the third power line VIL, the fourth power line VAIL, the fifth power line VOBL, and the horizontal power line HVDL may be located on the barrier layer BR.

In one or more embodiments, each of the pixel circuits PXC may include first type transistors and second type transistors. The first type transistors and the second type transistors may be located in different layers within the backplane layer BPL.

For example, each of the pixel circuits PXC may include the first, second, fifth, sixth, seventh, and eighth P-type transistors T1, T2, T5, T6, T7, and T8 and the third and fourth N-type transistors T3 and T4. The first, second, fifth, sixth, seventh, and eighth active layers ACT1, ACT2, ACT5, ACT6, ACT7, and ACT8 of the first, second, fifth, sixth, seventh, and eighth transistors T1, T2, T5, T6, T7, and T8 and the third and fourth active layers ACT3 and ACT4 of the third and fourth transistors T3 and T4 may be located in different semiconductor layers included in the backplane layer BPL. In one or more embodiments, the first, second, fifth, sixth, seventh, and eighth active layers ACT1, ACT2, ACT5, ACT6, ACT7, and ACT8 of the first, second, fifth, sixth, seventh, and eighth transistors T1, T2, T5, T6, T7, and T8 and the third and fourth active layers ACT3 and ACT4 of the third and fourth transistors T3 and T4 may include different semiconductor materials, but the present disclosure is not limited thereto. Additionally, the first, second, fifth, sixth, seventh, and eighth gate electrodes GE1, GE2, GE5, GE6, GE7, and GE8 of the first, second, fifth, sixth, seventh, and eighth transistors T1, T2, T5, T6, T7, and T8 and the third and fourth active layers ACT3 and ACT4 of the third and fourth transistors T3 and T4 may be located in different conductive layers included in the backplane layer BPL.

Specifically, the first semiconductor layer SCL1 may be located on the barrier layer BR. The first semiconductor layer SCL1 may include an active layer of each of the first type transistors. For example, the first semiconductor layer SCL1 may include the first, second, fifth, sixth, seventh, and eighth active layers ACT1, ACT2, ACT5, ACT6, ACT7, and ACT8 of the first, second, fifth, sixth, seventh, and eighth transistors T1, T2, T5, T6, T7, and T8. FIGS. 19 and 21 illustrate only some of the pixel transistors PXT included in each of the pixel circuits PXC, and FIGS. 19 and 21 illustrate the first active layer ACT1 and the sixth active layer ACT6 from among the active layers included in the first semiconductor layer SCL1. In one or more embodiments, the first, second, fifth, sixth, seventh, and eighth active layers ACT1, ACT2, ACT5, ACT6, ACT7, and ACT8 of each of the pixel circuits PXC may be integrally formed using the same semiconductor material. For example, as illustrated in FIGS. 9-17, the first, second, fifth, sixth, seventh, and eighth active layers ACT1, ACT2, ACT5, ACT6, ACT7, and ACT8 of each of the first pixel circuit PXC1, the second pixel circuit PXC2 and the third pixel circuit PXC3 may be formed as a single semiconductor pattern by being connected to each other.

The patterns (e.g., the first, second, fifth, sixth, seventh, and eighth active layers ACT1, ACT2, ACT5, ACT6, ACT7, and ACT8) of the first semiconductor layer SCL1 may include a first semiconductor material. In one or more embodiments, the first semiconductor material may be polycrystalline silicon (e.g., low temperature polycrystalline silicon), but is not limited thereto. For example, the first semiconductor material may be an oxide semiconductor (e.g., at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or another oxide semiconductor) and/or single crystal silicon.

The first insulating layer INS1 may be located on the first semiconductor layer SCL1 and the barrier layer BR. The first insulating layer INS1 may include at least one insulating material (e.g., silicon nitride (SiNx), silicon oxide (SiOx), silicon oxynitride (SiON), titanium oxide (TiOx), aluminum oxide (AlOx), and/or another inorganic insulating material) and may be formed as a single layer or multiple layers.

The first gate conductive layer GCDL1 may be located on the first insulating layer INS1. The first gate conductive layer GCDL1 may include a gate electrode of each of the first type transistors. For example, the first gate conductive layer GCDL1 may include the first, second, fifth, sixth, seventh, and eighth gate electrodes GE1, GE2, GE5, GE6, GE7, and GE8 of the first, second, fifth, sixth, seventh, and eighth transistors T1, T2, T5, T6, T7, and T8. The first gate conductive layer GCDL1 may further include at least one conductive pattern and/or wire. For example, the first gate conductive layer GCDL1 may further include the first electrode SCE1 of the storage capacitor Cst, the first electrode BCE1 of the boosting capacitor Cbst, the write scan line GWL, and the bias scan line GBL. FIG. 19 and FIG. 21 illustrate the first gate electrode GE1, the sixth gate electrode GE6, the first electrode SCE1 of the storage capacitor Cst, the first electrode BCE1 of the boosting capacitor Cbst, and the write scan line GWL, among the patterns of the first gate conductive layer GCDL1.

In one or more embodiments, the first gate electrode GE1 of each of the pixel circuits PXC and the first electrode SCE1 of the storage capacitor Cst may be formed integrally, and the second gate electrode GE2, the first electrode BCE1 of the boosting capacitor Cbst, and the write scan line GWL (e.g., the write scan line GWL connected to the sub-pixels SPX of the corresponding horizontal line) may be integrally formed. Additionally, the seventh gate electrode GE7, the eighth gate electrode GE8, and the bias scan line GBL (e.g., the bias scan line GBL connected to the sub-pixels SPX of the corresponding horizontal line) may be integrally formed.

The patterns (e.g., the first, second, fifth, sixth, seventh, and eighth gate electrodes GE1, GE2, GE5, GE6, GE7, and GE8, the first electrode SCE1 of the storage capacitor Cst, the first electrode BCE1 of the boosting capacitor Cbst, the write scan line GWL, and the bias scan line GBL) of the first gate conductive layer GCDL1 may include the same conductive material.

The second insulating layer INS2 may be located on the first gate conductive layer GCDL1 and the first insulating layer INS1. The second insulating layer INS2 may include at least one insulating material (e.g., an inorganic insulating material) and may be formed as a single layer or multiple layers.

The second gate conductive layer GCDL2 may be located on the second insulating layer INS2. The second gate conductive layer GCDL2 may include the second electrode SCE2 of the storage capacitor Cst. The first electrode SCE1 and the second electrode SCE2 of the storage capacitor Cst may overlap each other while the second insulating layer INS2 is interposed between the first electrode SCE1 and the second electrode SCE2. The second electrode SCE2 of the storage capacitor Cst may be opened in a portion (e.g., the fourth contact hole CH4 and its surroundings) in which the first electrode SCE1 of the storage capacitor Cst is connected to the first connection electrode CNE1. The second gate conductive layer GCDL2 may further include at least one conductive pattern and/or wire. For example, the second gate conductive layer GCDL2 may further include the first light blocking pattern LBP1, the second light blocking pattern LBP2, the horizontal power line HVDL, and the fourth power line VAIL. FIG. 19 and FIG. 21 illustrate the second electrode SCE2 of the storage capacitor Cst, the first light blocking pattern LBP1, the second light blocking pattern LBP2, and the fourth power line VAIL, among the patterns of the second gate conductive layer GCDL2,

In one or more embodiments, the first light blocking patterns LBP1 of the sub-pixels SPX located in each horizontal line may be integrally formed, and the second light blocking patterns LBP2 of the sub-pixels SPX located in each horizontal line may be integrally formed. Additionally, the second electrodes SCE2 of the storage capacitors Cst of the sub-pixels SPX located in each horizontal line and the horizontal power line HVDL may be integrally formed.

The patterns (e.g., the second electrode SCE2 of the storage capacitor Cst, the first light blocking pattern LBP1, the second light blocking pattern LBP2, the horizontal power line HVDL, and the fourth power line VAIL) of the second gate conductive layer GCDL2 may include the same conductive material.

The third insulating layer INS3 may be located on the second gate conductive layer GCDL2 and the second insulating layer INS2. The third insulating layer INS3 may include at least one insulating material (e.g., an inorganic insulating material) and may be formed as a single layer or multiple layers.

The second semiconductor layer SCL2 may be located on the third insulating layer INS3. The second semiconductor layer SCL2 may include the active layer of each of the second type transistors. For example, the second semiconductor layer SCL2 may include the third and fourth active layers ACT3 and ACT4 of third and fourth transistors T3 and T4. In one or more embodiments, the third and fourth active layers ACT3 and ACT4 of each of the pixel circuits PXC may be integrally formed using the same semiconductor material. For example, as illustrated in FIGS. 9-13, the third and fourth active layers ACT3 and ACT4 of each of the first pixel circuit PXC1, the second pixel circuit PXC2, and the third pixel circuit PXC3 may be formed as a single semiconductor pattern by being connected to each other. In one or more embodiments, the second semiconductor layer SCL2 may further include the second electrode BCE2 of the boosting capacitor Cbst, and the second electrode BCE2 of the boosting capacitor Cbst may be integrally formed with the third and fourth active layers ACT3 and ACT4.

The patterns (e.g., the third and fourth active layers ACT3 and ACT4 and the second electrode BCE2 of the boosting capacitor Cbst) of the second semiconductor layer SCL2 may include a second semiconductor material. In one or more embodiments, the second semiconductor material may be an oxide semiconductor, but is not limited thereto. For example, the second semiconductor material may be polycrystalline silicon or single crystal silicon.

The fourth insulating layer INS4 may be located on the second semiconductor layer SCL2 and the third insulating layer INS3. The fourth insulating layer INS4 may include at least one insulating material (e.g., an inorganic insulating material) and may be formed as a single layer or multiple layers.

The third gate conductive layer GCDL3 may be located on the fourth insulating layer INS4. The third gate conductive layer GCDL3 may include a gate electrode of each of the second type transistors. For example, the third gate conductive layer GCDL3 may include the third and fourth gate electrodes GE3 and GE4 of the third and fourth transistors T3 and T4. The third gate conductive layer GCDL3 may further include at least one conductive pattern and/or wire. For example, the third gate conductive layer GCDL3 may further include the initialization scan line GIL, the control scan line GCL, and the fifth power line VOBL. FIG. 19 and FIG. 21 illustrate the third gate electrode GE3 and the fourth gate electrode GE4 among the patterns of the third gate conductive layer GCDL3.

In one or more embodiments, the third gate electrode GE3 and the control scan line GCL (e.g., the control scan line GCL connected to the sub-pixels SPX of the corresponding horizontal line) may be integrally formed. Additionally, the fourth gate electrode GE4 and the initialization scan line GIL (e.g., the initialization scan line GIL connected to the sub-pixels SPX of the corresponding horizontal line) may be integrally formed.

The patterns (e.g., the third and fourth gate electrodes GE3 and GE4, the initialization scan line GIL, the control scan line GCL, and the fifth power line VOBL) of the third gate conductive layer GCDL3 may include the same conductive material.

The fifth insulating layer INS5 may be located on the third gate conductive layer GCDL3 and the fourth insulating layer INS4. The fifth insulating layer INS5 may include at least one insulating material (e.g., an inorganic insulating material) and may be formed as a single layer or multiple layers.

The first source-drain conductive layer SCDL1 may be located on the fifth insulating layer INS5. The first source-drain conductive layer SCDL1 may include at least one electrode, a conductive pattern and/or a wire. For example, the first source-drain conductive layer SCDL1 may include the source and drain electrodes SE1 and DE1 of the first transistor T1, the first, second, third, fourth, sixth and seventh connection electrodes CNE1, CNE2, CNE3, CNE4, CNE6, and CNE7, the first and second emission control lines EL1 and EL2, and the third power line VIL. FIGS. 19 and 21 illustrate the source and drain electrodes SE1 and DE1 of the first transistor T1, the first and fourth connection electrodes CNE1 and CNE4, the first and second emission control lines EL1 and EL2, and the third power line VIL, among the patterns of the first source-drain conductive layer SCDL1.

The patterns (e.g., the source and drain electrodes SE1 and DE1 of the first transistor T1, the first, second, third, fourth, sixth, and seventh connection electrodes CNE1, CNE2, CNE3, CNE4, CNE6, and CNE7, the first and second emission control lines EL1 and EL2, and the third power line VIL) of the first source-drain conductive layer SCDL1 may include the same conductive material.

The sixth insulating layer INS6 may be located on the first source-drain conductive layer SCDL1 and the fifth insulating layer INS5. The sixth insulating layer INS6 may include at least one insulating material (e.g., acrylic resin, epoxy resin, phenolic resin, polyamide resin, polyimide resin, or another organic insulating material) and may be formed as a single layer or multiple layers.

The second source-drain conductive layer SCDL2 may be located on the sixth insulating layer INS6. The second source-drain conductive layer SCDL2 may include at least one electrode, a conductive pattern and/or a wire. For example, the second source-drain conductive layer SCDL2 may include the fifth connection electrode CNE5, the first, second, and third data lines DLr, DLg, and DLb, and the first and second power lines VDL and VSL. FIG. 19 and FIG. 21 illustrate the fifth connection electrode CNE5, the first power line VDL, and the second power line VSL, among the patterns of the second source-drain conductive layer SCDL2.

The patterns (e.g., the fifth connection electrode CNE5, the first, second, and third data lines DLr, DLg, and DLb, and the first and second power lines VDL and VSL) of the second source-drain conductive layer SCDL2 may include the same conductive material.

The seventh insulating layer INS7 may be located on the second source-drain conductive layer SCDL2 and the sixth insulating layer INS6. The seventh insulating layer INS7 may include at least one insulating material (e.g., an organic insulating material) and may be formed as a single layer or multiple layers.

The patterns included in each of the conductive layers of the backplane layer BPL may include at least one conductive material. For example, the electrodes, the conductive patterns, and/or the wires included in each of the first gate conductive layer GCDL1, the second gate conductive layer GCDL2, the third gate conductive layer GCDL3, the first source-drain conductive layer SCDL1, and the second source-drain conductive layer SCDL2 may include copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and/or another metal, an alloy thereof, and/or another conductive material. In one or more embodiments, the electrodes, the conductive patterns, and/or the wires located in the same conductive layer may be concurrently (e.g., simultaneously) formed using the same conductive material. At least two conductive layers of the conductive layers of the backplane layer BPL may include the same conductive material or may include different conductive materials.

In one or more embodiments, the patterns included in each of the conductive layers of the backplane layer BPL may have a single-layer or multilayer structure. For example, each of the electrodes, conductive patterns and/or wires included in each of the first gate conductive layer GCDL1, the second gate conductive layer GCDL2, the third gate conductive layer GCDL3, the first source-drain conductive layer SCDL1, and the second source-drain conductive layer SCDL2 may have a single-layer or multilayer structure. At least two of the conductive layers of the backplane layer BPL may have the same cross-sectional structure or different cross-sectional structures.

In one or more embodiments, the patterns of the second source-drain conductive layer SCDL2 may include metal (e.g., at least one of molybdenum (Mo), aluminum (Al), chromium (Cr), gold (Au), titanium (Ti), nickel (Ni), neodymium (Nd), copper (Cu), or another metal, or an alloy thereof) and may have a single-layer or multilayer structure. For example, the electrodes, conductive patterns and/or wires included in the second source-drain conductive layer SCDL2 may be a low-resistance pattern formed in a triple-layer structure of titanium/aluminum/titanium (Ti/Al/Ti). Alternatively, the patterns of the second source-drain conductive layer SCDL2 may include other low-resistance materials and/or structures. When the resistance of the patterns included in the second source-drain conductive layer SCDL2 is reduced or minimized, the resistance of the first power line VDL and the second power line VSL through which the driving current Ids of each of the sub-pixels SPX flows may be reduced or minimized. Accordingly, the image quality of the display device 10 may become uniform and power consumption may be improved.

The light emitting element layer EDL may be located on the seventh insulating layer INS7. The light emitting element layer EDL may include the pixel electrodes PXE, the light emitting elements LE and the common electrode CE included in the sub-pixels SPX. Additionally, the light emitting element layer EDL may further include insulating layers. In one or more embodiments, the insulating layers of the light emitting element layer EDL may include eighth, ninth, and tenth insulating layers INS8, INS9, and INS10, a capping layer CPL, and a first overcoat layer OC1.

A pixel electrode layer including the pixel electrodes PXE of the sub-pixels SPX may be located on the seventh insulating layer INS7. For example, the pixel electrode layer may include the first pixel electrode PXE1, the second pixel electrode PXE2, and the third pixel electrode PXE3. In one or more embodiments, the light emitting element LE may be a flip-chip type micro LED. The flip-chip type micro LED refers to an LED in which first and second contact electrodes CTE1 and CTE2 are formed on one surface (e.g., the bottom surface) of the light emitting element LE. When the light emitting element LE is a flip-chip type micro LED, the pixel electrode layer may further include the common electrode CE. For example, the pixel electrodes PXE and the common electrode CE of the sub-pixels SPX may be located in (e.g., at) the same layer and may be concurrently (e.g., simultaneously) formed using the same conductive material.

The first pixel electrode PXE1 of the first sub-pixel SPX1 may be electrically connected to the fifth connection electrode CNE5 of the first sub-pixel SPX1 through the first anode contact hole ANH1 (e.g., a contact hole that penetrates the seventh insulating layer INS7 to expose the fifth connection electrode CNE5 of the first sub-pixel SPX1). The second pixel electrode PXE2 of the second sub-pixel SPX2 may be electrically connected to the fifth connection electrode CNE5 of the second sub-pixel SPX2 through the second anode contact hole ANH2 (e.g., a contact hole that penetrates the seventh insulating layer INS7 to expose the fifth connection electrode CNE5 of the second sub-pixel SPX2). The third pixel electrode PXE3 of the third sub-pixel SPX3 may be electrically connected to the fifth connection electrode CNE5 of the third sub-pixel SPX3 through the third anode contact hole ANH3 (e.g., a contact hole that penetrates the seventh insulating layer INS7 to expose the fifth connection electrode CNE5 of the third sub-pixel SPX3). Accordingly, the first pixel electrode PXE1, the second pixel electrode PXE2, and the third pixel electrode PXE3 may be electrically connected to the first pixel circuit PXC1, the second pixel circuit PXC2, and the third pixel circuit PXC3, respectively, and the first pixel circuit PXC1, the second pixel circuit PXC2, and the third pixel circuit PXC3 may control the voltages applied to the first pixel electrode PXE1, the second pixel electrode PXE2, and the third pixel electrode PXE3.

The common electrode CE shared by the first, second, and third sub-pixels SPX1, SPX2, and SPX3 may be electrically connected to the second power line VSL of the backplane layer BPL through the cathode contact hole CDH (e.g., a contact hole that penetrates the seventh insulating layer INS7 to expose the second power line VSL of the backplane layer BPL). Accordingly, the second driving voltage VSS to be applied to the second power line VSL may be transmitted to the common electrode CE.

In one or more embodiments, the patterns (e.g., the pixel electrodes PXE and the common electrode CE) of the pixel electrode layer may include the same conductive material. In one or more embodiments, the patterns (e.g., the pixel electrodes PXE and the common electrode CE) of the pixel electrode layer may include the same conductive material. In one or more embodiments, the patterns of the pixel electrode layer may include metal (e.g., at least one of molybdenum (Mo), aluminum (Al), chromium (Cr), gold (Au), titanium (Ti), nickel (Ni), neodymium (Nd), copper (Cu), or another metal, or an alloy thereof) and may have a single-layer or multilayer structure. For example, the patterns of the pixel electrode layer may be low-resistance patterns formed in a triple-layer structure of titanium/aluminum/titanium (Ti/Al/Ti). Alternatively, the patterns of the pixel electrode layer may include other low-resistance materials (e.g., copper (Cu)) and/or structures. When the resistance of the patterns included in the pixel electrode layer is reduced or minimized, the first driving voltage VDD and the second driving voltage VSS may be stably transmitted to the light emitting elements LE of the sub-pixels SPX.

The eighth insulating layer INS8 may be located on the pixel electrodes PXE and the common electrode CE. The eighth insulating layer INS8 temporarily fixes or adheres the light emitting elements LE to prevent the light emitting elements LE from tilting and falling over or tipping over during the process of transferring the light emitting elements LE to the display panel 100. For example, the eighth insulating layer INS8 may be a film for temporarily adhering the light emitting elements LE onto each of the pixel electrodes PXE and the common electrode CE. To facilitate temporary adhesion, the thickness of the eighth insulating layer INS8 may be greater than the thickness of each of the pixel electrodes PXE and the common electrode CE, and may be greater than the thickness of each of the first and second contact electrodes CTE1 and CTE2 of the light emitting elements LE.

Although FIGS. 19-21 illustrate that the eighth insulating layer INS8 is located entirely over the display area DA, the present disclosure is not limited thereto. For example, the eighth insulating layer INS8 may be located only on a portion of the pixel electrodes PXE and the common electrode CE that overlap the light emitting elements LE, and may expose other portions of the pixel electrodes PXE and the common electrode CE.

The eighth insulating layer INS8 may include at least one insulating material, for example, an organic insulating material. For example, the eighth insulating layer INS8 may be a photosensitive organic film such as a photoresist. Alternatively, the eighth insulating layer INS8 may include acryl resin, epoxy resin, phenolic resin, polyamide resin, polyimide resin, and/or the like.

The light emitting elements LE may be located on the eighth insulating layer INS8. For example, the first light emitting element LE1 may be located on the first pixel electrode PXE1 of the first sub-pixel SPX1 and the common electrode CE. The second light emitting element LE2 may be located on the second pixel electrode PXE2 of the second sub-pixel SPX2 and the common electrode CE. The third light emitting element LE3 may be located on the third pixel electrode PXE3 of the third sub-pixel SPX3 and the common electrode CE.

In one or more embodiments, each of the light emitting elements LE may be a micro LED including an inorganic material. For example, each of the light emitting elements LE may include an inorganic material such as gallium nitride (GaN), and the length in the first direction DR1, the length in the second direction DR2, and the length in the third direction DR3 of each of the light emitting elements LE may each be several μm to several hundred μm. For example, the length in the first direction DR1, the length in the second direction DR2, and the length in the third direction DR3 of each of the light emitting elements LE may each be approximately 100 μm or less.

The light emitting elements LE may be formed by growing on a semiconductor substrate such as a silicon substrate and/or sapphire substrate. The light emitting elements LE may be transferred directly from the semiconductor substrate onto the pixel electrodes PXE and the common electrode CE of the display panel 100. Alternatively, the light emitting elements LE may be transferred onto the common electrode CE and the pixel electrodes PXE of the display panel 100 through an electrostatic method using an electrostatic head or a stamping method using an elastic polymer material such as PDMS and/or silicon as a transfer substrate.

The light emitting element LE may include a conductive layer E1, a semiconductor stack STC, the contact electrodes CTE1 and CTE2, and a protective film PRL. The semiconductor stack STC may include a first semiconductor layer SEM1, an active layer MQW (e.g., light emitting layer), and a second semiconductor layer SEM2 sequentially located in the third direction DR3. In one or more embodiments, the semiconductor stack STC may further include a third semiconductor layer SEM3 on the second semiconductor layer SEM2.

The conductive layer E1 may be located on the bottom surface of the first semiconductor layer SEM1. FIG. 20 illustrates that the conductive layer E1 covers the entire bottom surface of the first semiconductor layer SEM1, but the present disclosure is not limited thereto. For example, the conductive layer E1 may be located on a portion of the bottom surface of the first semiconductor layer SEM1. The conductive layer E1 may include molybdenum (Mo), aluminum (Al), chromium (Cr), gold (Au), titanium (Ti), nickel (Ni), neodymium (Nd), and/or copper (Cu), and/or a transparent conductive material such as metal oxide.

The first semiconductor layer SEM1 may be located on the conductive layer E1. The first semiconductor layer SEM1 may be formed as a semiconductor material layer doped with a first conductivity type dopant such as magnesium (Mg), zinc (Zn), calcium (Ca), strontium (Sr), or barium (Ba), for example, gallium nitride (GaN).

The active layer MQW may be located on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include at least one of gallium nitride (GaN), indium gallium nitride (InGaN), or aluminum gallium nitride (AlGaN). The active layer MQW may emit light by recombination of electron-hole pairs according to an electrical signal applied through the first semiconductor layer SEM1 and the second semiconductor layer SEM2.

The active layer MQW may include a material having a single or multiple quantum well structure. When the active layer MQW contains a material having a multiple quantum well structure, the active layer MQW may have the structure in which a plurality of well layers and barrier layers are alternately stacked. At this time, the well layer may include InGaN, and the barrier layer may include GaN or AlGaN, but the present disclosure is not limited thereto. Alternatively, the active layer MQW may have a structure in which semiconductor materials having large band gap energy and semiconductor materials having small band gap energy are alternately stacked, and may include other Group III to Group V semiconductor materials according to the wavelength band of the emitted light.

When the active layer MQW includes indium gallium nitride (InGaN), the color of emitted light may vary depending on the content of indium (In). For example, as the content of indium (In) increases, the wavelength band of the light emitted by the active layer may shift to the red wavelength band, and as the content of indium (In) decreases, the wavelength band of the light emitted by the active layer may shift to the blue wavelength band. For example, the active layer MQW of the light emitting element LE that emits light of the third color (blue light) may contain about 10 wt % to 20 wt % of indium (In).

The second semiconductor layer SEM2 may be located on the active layer MQW. The second semiconductor layer SEM2 may be a semiconductor material layer doped with a second conductivity type dopant such as silicon (Si), germanium (Ge), and/or tin (Sn), for example, gallium nitride (GaN).

The third semiconductor layer SEM3 may be located on the second semiconductor layer SEM2. The third semiconductor layer SEM3 may be a semiconductor material layer having an n-type dopant lower than a selected critical value, and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) having an n-type dopant lower than a selected threshold value.

An electron blocking layer may be located between the first semiconductor layer SEM1 and the active layer MQW. The electron blocking layer may be a layer for suppressing or preventing too many electrons from flowing into the active layer MQW. For example, the electron blocking layer may be AlGaN and/or p-AlGaN doped with p-type Mg. The electron blocking layer may be omitted.

A superlattice layer may be located between the active layer MQW and the second semiconductor layer SEM2. The superlattice layer may be a layer for relieving stress between the second semiconductor layer SEM2 and the active layer MQW. For example, the superlattice layer may include InGaN and/or GaN. The superlattice layer may be omitted.

The protective film PRL may be located on the side surface and the bottom surface of the conductive layer E1, the side surface of the first semiconductor layer SEM1, the side surface of the active layer MQW, the side surface of the second semiconductor layer SEM2, and the side surface of the third semiconductor layer SEM3. The protective film PRL may be a film for protecting the side surface of the light emitting element LE. The protective film PRL may include an inorganic material, for example, silicon nitride (SiNx), silicon oxide (SiOx), silicon oxynitride (SiON), titanium oxide (TiOx), aluminum oxide (AlOx), and/or another inorganic insulating material.

FIG. 20 describes that the protective film PRL is located on the side surfaces of the first semiconductor layer SEM1, the side surfaces of the active layer MQW, the side surfaces of the second semiconductor layer SEM2, and the side surfaces of the third semiconductor layer SEM3 of the semiconductor stack STC. However, in one or more other embodiments, the protective film PRL may not be located on the side surfaces of the third semiconductor layer SEM3, but the present disclosure is not limited thereto. For example, the protective film PRL may be located on the side surfaces of the first semiconductor layer SEM1, the side surfaces of the active layer MQW, the side surfaces of the second semiconductor layer SEM2, and the side surfaces of the third semiconductor layer SEM3 of the semiconductor stack STC.

A hole LEH that penetrates the conductive layer E1, the first semiconductor layer SEM1, and the active layer MQW of the light emitting element LE to expose the second semiconductor layer SEM2 may be formed. The hole LEH may have a circular planar shape as shown in FIG. 2, but the present disclosure is not limited thereto. For example, the hole LEH may have a planar shape such as an elliptical shape or a polygonal shape, such as a quadrilateral shape.

The protective film PRL may be located on the sidewall of the conductive layer E1 exposed in the hole LEH, the sidewall of the first semiconductor layer SEM1, and the sidewall of the active layer MQW. The protective film PRL may not cover the second semiconductor layer SEM2 at the hole LEH. Accordingly, the second semiconductor layer SEM2 may be exposed without being covered by the protective film PRL.

The first contact electrode CTE1 may be located on at least one side surface of the semiconductor stack STC and at least one side surface and the bottom surface of the conductive layer E1. The first contact electrode CTE1 may be located on the bottom surface of the conductive layer E1 exposed without being covered by the protective film PRL. Accordingly, the first contact electrode CTE1 may be electrically connected to the conductive layer E1.

The second contact electrode CTE2 may be located on at least one side surface of the semiconductor stack STC and at least one side surface and the bottom surface of the conductive layer E1. At this time, the first contact electrode CTE1 may be located on the first side surface of the semiconductor stack STC and the first side surface of the conductive layer E1, while the second contact electrode CTE2 may be located on the second side surface of the semiconductor stack STC and the second side surface of the conductive layer E1.

The second contact electrode CTE2 may be located on the protective film PRL located in the hole LEH and the second semiconductor layer SEM2 exposed without being covered by the protective film PRL in the hole LEH. Accordingly, the second contact electrode CTE2 may be electrically connected to the second semiconductor layer SEM2 in the hole LEH.

FIGS. 19 and 20 illustrate that the first contact electrode CTE1 and the second contact electrode CTE2 of each of the light emitting elements LE are located on the eighth insulating layer INS8, but the present disclosure is not limited thereto. For example, the eighth insulating layer INS8 may be located on the bottom surface and a portion of the side surface of the first contact electrode CTE1 and the bottom surface and a portion of the side surface of the second contact electrode CTE2 of each of the light emitting elements LE. Alternatively, the eighth insulating layer INS8 may be located on the side surfaces of the conductive layer E1 of each of the light emitting elements LE. Alternatively, the eighth insulating layer INS8 may be located on the side surfaces of the first semiconductor layer SEM1, the side surfaces of the active layer MQW, and the side surfaces of the second semiconductor layer SEM2 of each of the light emitting elements LE. In this case, the eighth insulating layer INS8 may be located on a portion of each of the side surfaces of the second semiconductor layer SEM2.

Each of the first contact electrode CTE1 and the second contact electrode CTE2 may be located on three side surfaces of the semiconductor stack STC. For example, when the semiconductor stack STC includes first to fourth side surfaces, the first contact electrode CTE1 may be located on the first side surface, the second side surface, and the third side surface, and the second contact electrode CTE2 may be located on the second side surface, the third side surface, and the fourth side surface.

Each of the first contact electrode CTE1 and the second contact electrode CTE2 may include at least one conductive material, for example, molybdenum (Mo), aluminum (Al), chromium (Cr), gold (Au), titanium (Ti), nickel (Ni), neodymium (Nd), and/or copper (Cu). In one or more embodiments, the first contact electrode CTE1 and the second contact electrode CTE2 may be formed in a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

When each of the first contact electrode CTE1 and the second contact electrode CTE2 includes metal having high reflectivity, light emitted from the active layer MQW of the light emitting element LE, which propagates in the lateral direction of the light emitting element LE, may be reflected by the first contact electrode CTE1 and the second contact electrode CTE2 and emitted to the top surface of the light emitting element LE. Accordingly, because light loss from the light emitting element LE may be reduced, the light efficiency of the light emitting element LE may be increased. To increase the light efficiency of the light emitting element LE, the first contact electrode CTE1 and the second contact electrode CTE2 may be located to cover most of the side surface of the semiconductor stack STC.

A first bridge electrode BE1 (or eighth connection electrode) connects the first contact electrode CTE1 of the light emitting element LE and each of the pixel electrodes PXE. For example, the first bridge electrode BE1 of the first sub-pixel SPX1 may connect the first contact electrode CTE1 of the first light emitting element LE1 and the first pixel electrode PXE1. Similarly, the first bridge electrode BE1 of the second sub-pixel SPX2 may connect the first contact electrode CTE1 of the second light emitting element LE2 and the second pixel electrode PXE2, and the first bridge electrode BE1 of the third sub-pixel SPX3 may connect the first contact electrode CTE1 of the third light emitting element LE3 and the third pixel electrode PXE3.

The first bridge electrode BE1 may be connected to each of the pixel electrodes PXE exposed through the first connection hole BH1 penetrating the eighth insulating layer INS8. Additionally, the first bridge electrode BE1 may be located on the top surface of the eighth insulating layer INS8 and the first contact electrode CTE1 of the light emitting element LE. In another embodiment, when the eighth insulating layer INS8 is located only on a portion of the pixel electrode PXE overlapping the light emitting element LE, the first connection hole BH1 may be unnecessary. For example, the first bridge electrode BE1 may be located directly on the pixel electrode PXE exposed around the light emitting element LE.

The second bridge electrode BE2 (or ninth connection electrode) connects the second contact electrode CTE2 of the light emitting element LE and the common electrode CE. For example, the second bridge electrode BE2 of the first sub-pixel SPX1 may connect the second contact electrode CTE2 of the first light emitting element LE1 and the common electrode CE. Similarly, the second bridge electrode BE2 of the second sub-pixel SPX2 may connect the second contact electrode CTE2 of the second light emitting element LE2 and the common electrode CE, and the second bridge electrode BE2 of the third sub-pixel SPX3 may connect the second contact electrode CTE2 of the third light emitting element LE3 and the common electrode CE. In another embodiment, when the eighth insulating layer INS8 is located only on a portion of the common electrode CE overlapping the light emitting element LE, the second connection hole BH2 may be unnecessary. For example, the second bridge electrode BE2 may be located directly on the common electrode CE exposed around the light emitting element LE.

The second bridge electrode BE2 may be connected to the common electrode CE exposed through the second connection hole BH2 penetrating the eighth insulating layer INS8. Additionally, the second bridge electrode BE2 may be located on the top surface of the eighth insulating layer INS8 and the second contact electrode CTE2.

Each of the first bridge electrode BE1 and the second bridge electrode BE2 may include at least one conductive material, for example, molybdenum (Mo), aluminum (Al), chromium (Cr), gold (Au), titanium (Ti), nickel (Ni), neodymium (Nd), and/or copper (Cu). Alternatively, each of the first bridge electrode BE1 and the second bridge electrode BE2 may include a transparent conductive material (e.g., transparent conductive oxide (TCO)) such as indium tin oxide (ITO) and/or indium zinc oxide (IZO).

When each of the first bridge electrode BE1 and the second bridge electrode BE2 includes a metal material having high reflectivity, such as aluminum (Al), the light traveling in the lateral direction of the light emitting element LE from among the light emitted from the active layer MQW of the light emitting element LE may be reflected from the connection electrodes BE and travel in the upward direction of the light emitting element LE. Accordingly, because light loss from the light emitting element LE may be reduced, the light efficiency of the light emitting element LE may be increased.

As illustrated in FIGS. 19 and 20, the conductive layer E1 of the light emitting element LE may be electrically connected to each of the pixel electrodes PXE through the first contact electrode CTE1 and the first bridge electrode BE1. Additionally, the second semiconductor layer SEM2 of the light emitting element LE may be electrically connected to the common electrode CE through the second contact electrode CTE2 formed in the hole LEH and the second bridge electrode BE2. For example, the pixel electrodes PXE may be referred to as the anode electrode or the first electrode, and the common electrode CE may also be referred to as the cathode electrode or the second electrode.

The ninth insulating layer INS9 may be located on the eighth insulating layer INS8. The ninth insulating layer INS9 may be located to cover a portion of the side surface of the light emitting elements LE. Additionally, the ninth insulating layer INS9 may be located to cover the first and second bridge electrodes BE1 and BE2, but at least a portion of the first and second bridge electrodes BE1 and BE2 may be exposed without being covered by the ninth insulating layer INS9.

The tenth insulating layer INS10 may be located on the ninth insulating layer INS9. The tenth insulating layer INS10 may be located to cover a portion of the side surface of each of the light emitting elements LE. The tenth insulating layer INS10 may be located on at least a portion of the first and second bridge electrodes BE1 and BE2 exposed without being covered by the ninth insulating layer INS9. The top surface of each of the light emitting elements LE may be exposed without being covered by the tenth insulating layer INS10.

The ninth insulating layer INS9 and the tenth insulating layer INS10 may include at least one insulating material, for example, an organic insulating material. For example, each of the ninth insulating layer INS9 and the tenth insulating layer INS10 may include an organic layer such as acryl resin, epoxy resin, phenolic resin, polyamide resin, polyimide resin, and/or the like.

The ninth insulating layer INS9 and the tenth insulating layer INS10 may flatten the stepped portion caused by the light emitting elements LE. When the ninth insulating layer INS9 has a height (e.g., thickness) to cover most of the side surfaces of the light emitting elements LE, the tenth insulating layer INS10 may be omitted.

The capping layer CPL may be located on the light emitting elements LE, the ninth insulating layer INS9, and the tenth insulating layer INS10. The capping layer CPL may include at least one insulating material, for example, an inorganic insulating material.

In one or more embodiments, the display panel 100 may not include a light conversion layer when the light emitting elements LE of each of the sub-pixels SPX emit light of a color corresponding to (e.g., matching) the emission color (or emission wavelength) of the corresponding sub-pixel SPX. For example, the first overcoat layer OC1 may be located directly on the capping layer CPL.

When the sub-pixels SPX include the light emitting elements LE that emit light corresponding to each emission color, the light emitted from the light emitting elements LE may be utilized more efficiently. For example, it is possible to prevent a decrease in the light efficiency of the sub-pixels SPX due to light conversion. In addition, the color purity of light emitted from the sub-pixels SPX may be increased, and the color reproducibility of the sub-pixels SPX may be increased.

In another embodiment, when the light emitting element LE of at least one sub-pixel SPX emits light of a color different from the emission color (or emission wavelength) of the corresponding sub-pixel SPX, a light conversion layer may be further located at the upper side of the light emitting element LE. For example, when the first light emitting element LE1 emits blue light and the first sub-pixel SPX1 is a red sub-pixel that emits red light, a light conversion layer covering the first light emitting element LE1 may be located on the capping layer CPL. The light conversion layer may include light conversion particles (e.g., red quantum dots and/or the like) that convert blue light incident from the first light emitting element LE1 into red light. When the sub-pixels SPX include light emitting elements LE that emit light of the same color, the manufacturing efficiency of the light emitting element layer EDL and the display panel 100 including the same may be increased, and the manufacturing cost may be reduced.

The first overcoat layer OC1 may be located on the capping layer CPL (or light conversion layer). The first overcoat layer OC1 may be an organic film including an organic insulating material (e.g., acrylic resin, epoxy resin, phenolic resin, polyamide resin, and/or polyimide resin), and the top surface of the first overcoat layer OC1 may be substantially flat. However, the present disclosure is not limited thereto. For example, the first overcoat layer OC1 may be an inorganic film including an inorganic insulating material, and the first overcoat layer OC1 may be formed to have a sufficient thickness to include a substantially flat top surface or may be flattened through a separate planarization process. Accordingly, the top surface of the first overcoat layer OC1 may be substantially flat.

The color filter layer CFL may be located on the first overcoat layer OC1. The color filter layer CFL may further include the color filters CF located in the emission areas EA of the sub-pixels SPX, and a second overcoat layer OC2 covering the color filters CF.

The color filter layer CFL may include the color filters CF that selectively transmit light corresponding to the emission color (or emission wavelength) of each of the sub-pixels SPX. For example, when the first sub-pixel SPX1, the second sub-pixel SPX2, and the third sub-pixel SPX3 are the sub-pixels SPX that emit red light, green light, and blue light, respectively, a red color filter, a green color filter, and a blue color filter may be located in the first emission area EA1 of the first sub-pixel SPX1, the second emission area EA2 of the second sub-pixel SPX2, and the third emission area EA3 of the third sub-pixel SPX3, respectively. In one or more embodiments, the color filters CF of the sub-pixels SPX may overlap each other in a non-emission area around (e.g., surrounding) the emission areas EA of the sub-pixels SPX to form a light blocking pattern.

The second overcoat layer OC2 may be located on the color filters CF. The second overcoat layer OC2 may be an organic film including an organic insulating material, and the top surface of the second overcoat layer OC2 may be substantially flat. However, the present disclosure is not limited thereto. For example, the second overcoat layer OC2 may be an inorganic film including an inorganic insulating material, and the second overcoat layer OC2 may be formed to have a sufficient thickness to include a substantially flat top surface or may be flattened through a separate planarization process. Accordingly, the top surface of the second overcoat layer OC2 may be substantially flat.

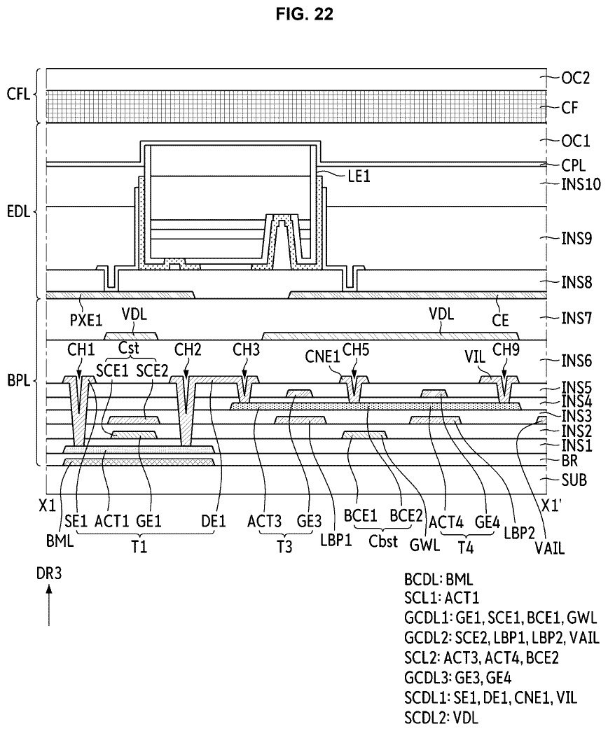

FIG. 22 is a cross-sectional view showing an example of a cross-section of the display panel corresponding to the line X1-X1′ of FIGS. 9 and 18. For example, FIG. 22 illustrates an example of the cross-section of the display panel 100 corresponding to a portion of the first sub-pixel SPX1. Compared to FIG. 19, FIG. 22 illustrates an embodiment in which the display panel 100 further includes a lower conductive layer BCDL.

Referring to FIG. 22 in addition to FIGS. 9-21, the display panel 100 may further include the lower conductive layer BCDL located on the substrate SUB. For example, the backplane layer BPL may include the lower conductive layer BCDL located between the substrate SUB and the barrier layer BR.

The lower conductive layer BCDL may include a lower pattern BML located below the first transistor T1. The lower pattern BML may entirely or partially cover the bottom surface of the first active layer ACT1. For example, the lower pattern BML may be located below the first active layer ACT1 to overlap a channel region (e.g., a portion of the first active layer ACT1 overlapping the first gate electrode GE1) of the first active layer ACT1.

In one or more embodiments, the lower conductive layer BCDL may include a light blocking material. For example, the lower conductive layer BCDL may include metal, and the lower pattern BML may be formed as a lower metal pattern. In one or more embodiments, the lower pattern BML may be electrically connected to a power line (e.g., the first power line VDL) to which a constant voltage is applied. In one or more embodiments, the lower pattern BML may be formed in the display area DA as a pattern that extends or is connected along at least one direction of the first direction DR1 or the second direction DR2 when viewed on a plane defined by the first direction DR1 and the second direction DR2, but the present disclosure is not limited thereto.

External light may be blocked from entering the channel region and/or the like of the first active layer ACT1 from the lower portion of the first transistor T1 by the lower pattern BML. Additionally, the charges accumulated around the first transistor T1 may be dispersed by the lower pattern BML. Accordingly, the operating characteristics of the first transistor T1 may be stabilized.

According to the embodiments described with reference to FIGS. 3-22, the design structure of the display area DA in which the pixels PX are located may be improved. For example, by designing the second sub-pixel SPX2 and the third sub-pixel SPX3 symmetrically in a flipped shape, the pixel circuits PXC and wires may be efficiently arranged in the display area DA, and the integration density of the pixels PX may be improved. Accordingly, the design structure (e.g., the design structure of the backplane layer BPL) of the display area DA may be optimized, and a space for arranging additional wires and/or the like may be secured.

For example, although each of the pixel circuits PXC includes a large number of circuit elements, at least two emission control lines EL may be located on each horizontal line, and an additional design space may be secured between the adjacent pixel circuits PXC (e.g., between the first pixel circuit PXC1 and the second pixel circuit PXC2 adjacent in the first direction DR1, or between the third pixel circuit PXC3 and the first pixel circuit PXC1 adjacent in the first direction DR1), and/or the like.

In one or more embodiments, the second power line VSL may be located in the space secured by efficiently arranging the pixel circuits PXC and wires. For example, the second power line VSL may be located between the first sub-pixel SPX1 and the second and third sub-pixels SPX2 and SPX3, or between two adjacent pixels PX (e.g., between two adjacent pixels PX in the first direction DR1), and/or the like. The second power line VSL may be electrically connected to the common electrode CE located on the backplane layer BPL. Accordingly, the voltage drop of the second driving voltage VSS applied to the common electrode CE through the second power line VSL may be prevented, and the image quality and power consumption of the display device 10 may be improved.

In one or more embodiments, the emission control lines EL of at least two sub-pixels SPX among the sub-pixels SPX constituting one pixel PX may be separated. For example, the first sub-pixel SPX1 and the second and third sub-pixels SPX2 and SPX3 may be connected to the different emission control lines EL. Accordingly, the emission period of the first sub-pixel SPX1 and the emission periods of the second and third sub-pixels SPX2 and SPX3 may be independently or individually controlled. For example, the driving current Ids of the first sub-pixel SPX1 and the driving currents Ids of the second and third sub-pixels SPX2 and SPX3 may be appropriately adjusted or differentiated according to the optimal consumption efficiency of the light emitting elements LE included in the sub-pixels SPX, and the emission periods of the first sub-pixel SPX1 and the second and third sub-pixels SPX2 and SPX3 may be individually adjusted according to each of the driving currents Ids, so that the luminance of the sub-pixels SPX may be uniformly maintained. Accordingly, the lifespan, image quality, and power consumption of the display device 10 may be improved.

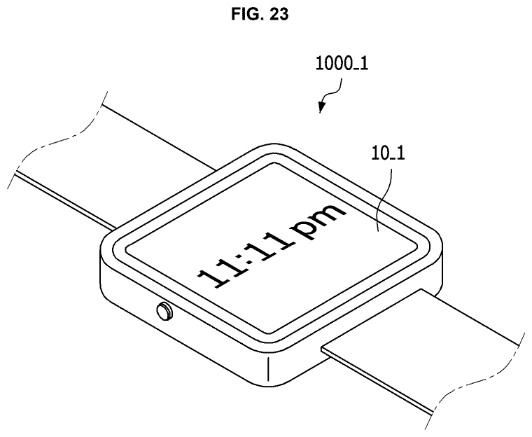

FIG. 23 is a diagram illustrating a smart watch including a display device according to one or more embodiments. Referring to FIG. 23, a display device 10_1 according to one or more embodiments may be applied to a smart watch 1000_1 that is one of the smart devices.

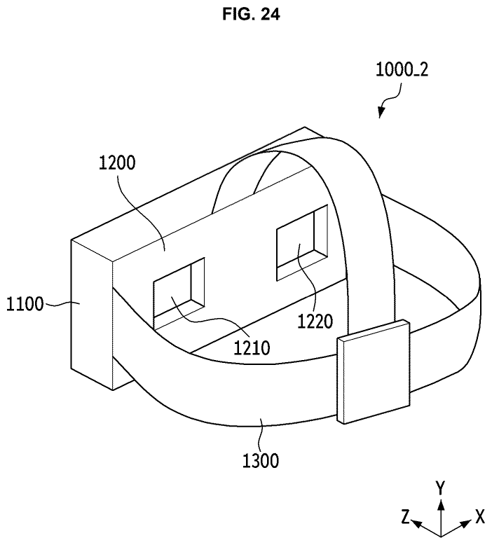

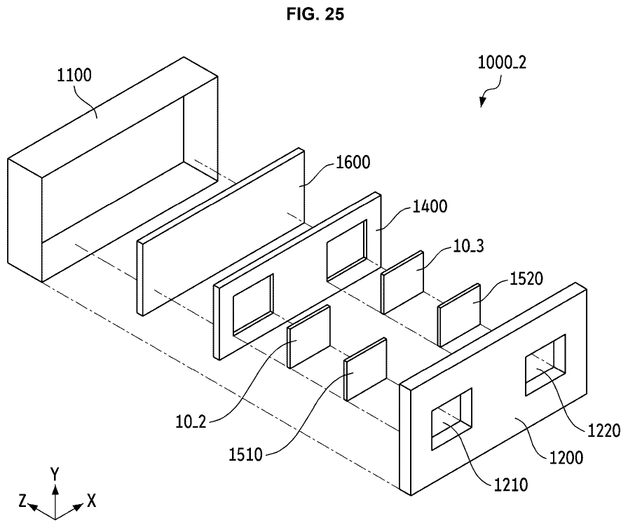

FIGS. 24 and 25 are views illustrating a head mounted display including a display device according to one or more embodiments. FIGS. 24 and 25 illustrate a virtual reality device as a head mounted display 1000_2 to which display devices 10_2 and 10_3 according to one or more embodiments are applied.

Referring to FIGS. 24 and 25, the head mounted display 1000_2 according to one or more embodiments includes a first display device 10_2, a second display device 10_3, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_2 provides an image to the user's left eye, and the second display device 10_3 provides an image to the user's right eye. Each of the first display device 10_2 and the second display device 10_3 may be the display device 10 according to at least one of the embodiments described above. Accordingly, description of the first display device 10_2 and the second display device 10_3 will be omitted.

The first optical member 1510 may be located between the first display device 10_2 and the first eyepiece 1210. The second optical member 1520 may be located between the second display device 10_3 and the second eyepiece 1220. Each of the first optical member 1510 and the second optical member 1520 may include at least one convex lens.

The middle frame 1400 may be located between the first display device 10_2 and the control circuit board 1600 and between the second display device 10_3 and the control circuit board 1600. The middle frame 1400 serves to support and fix the first display device 10_2, the second display device 10_3, and the control circuit board 1600.

The control circuit board 1600 may be located between the middle frame 1400 and the display device housing 1100. The control circuit board 1600 may be connected to the first display device 10_2 and the second display device 10_3 through the connector. The control circuit board 1600 may convert an image source inputted from the outside into the digital video data DATA, and transmit the digital video data DATA to the first display device 10_2 and the second display device 10_3 through the connector.

The control circuit board 1600 may transmit the digital video data DATA corresponding to a left-eye image optimized for the user's left eye to the first display device 10_2, and may transmit the digital video data DATA corresponding to a right-eye image optimized for the user's right eye to the second display device 10_3. Alternatively, the control circuit board 1600 may transmit the same digital video data DATA to the first display device 10_2 and the second display device 10_3.

The display device housing 1100 serves to accommodate the first display device 10_2, the second display device 10_3, the middle frame 1400, the first optical member 1510, the second optical member 1520, and the control circuit board 1600. The housing cover 1200 is located to cover one open surface of the display device housing 1100. The housing cover 1200 may include the first eyepiece 1210 at which the user's left eye is located and the second eyepiece 1220 at which the user's right eye is located. FIGS. 24 and 25 illustrate that the first eyepiece 1210 and the second eyepiece 1220 are located separately, but the present disclosure is not limited thereto. The first eyepiece 1210 and the second eyepiece 1220 may be combined into one.

The first eyepiece 1210 may be aligned with the first display device 10_2 and the first optical member 1510, and the second eyepiece 1220 may be aligned with the second display device 10_3 and the second optical member 1520. Therefore, the user may view, through the first eyepiece 1210, the image of the first display device 10_2 magnified as a virtual image by the first optical member 1510, and may view, through the second eyepiece 1220, the image of the second display device 10_3 magnified as a virtual image by the second optical member 1520.

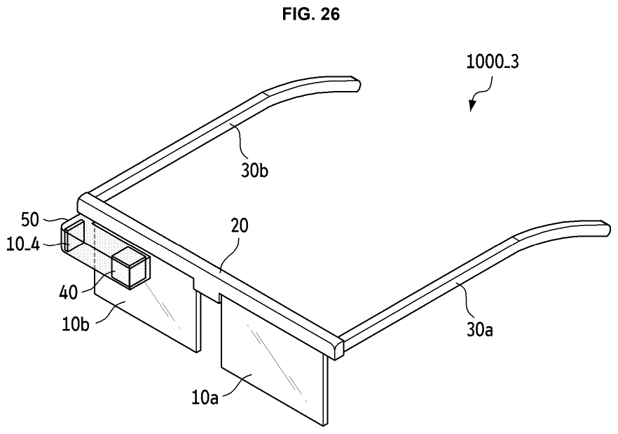

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1100 is implemented to be lightweight and compact, the head mounted display 1000_2 may be provided with, as shown in FIG. 26, an eyeglass frame instead of the head mounted band 1300.

Additionally, the head mounted display 1000_2 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, and/or a Bluetooth module.

FIG. 26 is a view illustrating a head mounted display including a display device according to one or more embodiments. FIG. 26 illustrates a virtual reality device (or augmented reality device) as a head mounted display to which a display device 10_4 according to one or more embodiments is applied.

Referring to FIG. 26, a head mounted display 1000_3 according to one or more embodiments may be a glasses-type device. The head mounted display 1000_3 according to one or more embodiments may include the display device 10_4, a left eye lens 10a, a right eye lens 10b, a support frame 20, temples 30a and 30b, a reflection member 40, and a display device housing 50.

FIG. 26 illustrates that the head mounted display 1000_3 is a glasses-type display device including the temples 30a and 30b. That is, the head mounted display 1000_3 according to one or more embodiments is not limited to that shown in FIG. 26, and may be applied in various forms to various electronic devices.

The display device housing 50 may include the display device 10_4 and the reflection member 40. An image displayed on the display device 10_4 may be reflected by the reflection member 40 and provided to the user's right eye through the right eye lens 10b. As a result, the user may view a virtual reality image displayed on the display device 10_4 with the right eye. For example, the user may view an augmented reality image, through the right eye, in which a virtual image displayed on the display device 10_4 and a real image seen through the right eye lens 10b are combined.

Although FIG. 26 illustrates that the display device housing 50 is located at the right end of the support frame 20, the present disclosure is not limited thereto. For example, the display device housing 50 may be located at the left end of the support frame 20, and in this case, the image displayed on the display device 10_4 may be reflected by the reflection member 40 and provided to a user's left eye through the left eye lens 10a. As a result, the user may view a virtual reality image displayed on the display device 10_4 with the left eye. Alternatively, the display device housing 50 may be located at both the left end and the right end of the support frame 20. In that case, the user can view the virtual reality image displayed on the display device 10_4 through both the left eye and the right eye.

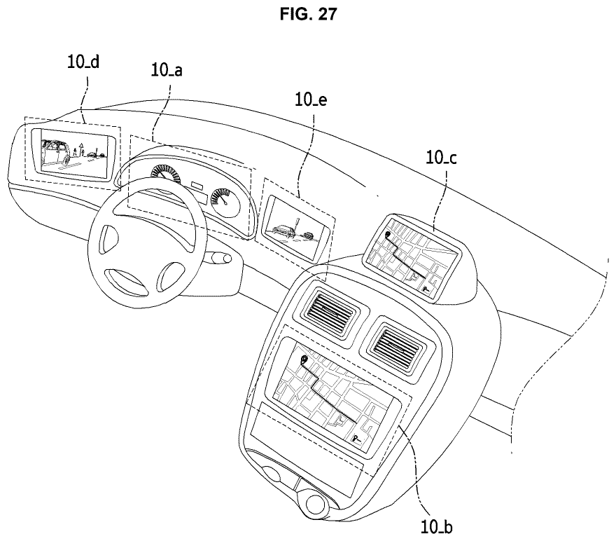

FIG. 27 is a diagram illustrating a center fascia and a dashboard of an automobile including display devices according to one or more embodiments. FIG. 27 illustrates a vehicle to which display devices 10_a, 10_b, 10_c, 10_d, and 10_e according to one or more embodiments are applied.

Referring to FIG. 27, the display devices 10_a, 10_b, and 10_c according to one or more embodiments may be applied to the dashboard of the automobile, the center fascia of the automobile, or the center information display (CID) of the dashboard of the automobile. Further, the display devices 10_d, and 10_e according to one or more embodiments may be applied to a room mirror display instead of side mirrors of the automobile.

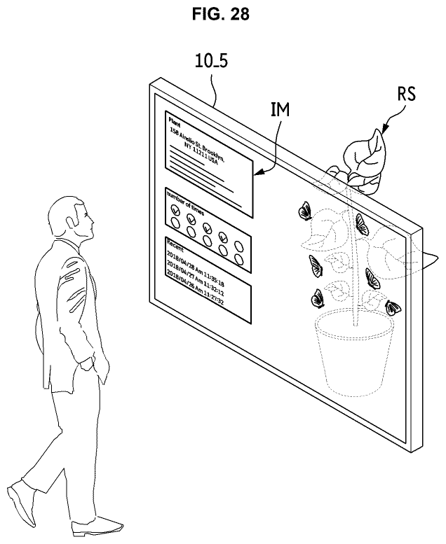

FIG. 28 is a diagram illustrating a transparent display device including a display device according to one or more embodiments.

Referring to FIG. 28, a display device 10_5 according to one or more embodiments may be applied to the transparent display device. The transparent display device may display an image IM, and also may transmit light. Thus, a user located on the front side of the transparent display device can view an object RS or a background on the rear side of the transparent display device as well as the image IM displayed on the display device 10_5. When the display device 10_5 is applied to the transparent display device, the substrate of the display device 10_5 may include a light transmitting portion capable of transmitting light or may include a material capable of transmitting light.

FIGS. 23-28 illustrate the smart watch 1000_1, the head mounted displays 1000_2 and 1000_3, a center fascia and a dashboard of an automobile, and a transparent display device as examples of the electronic devices that may include the display devices 10, 10_1, 10_2, 10_3, 10_4, 10_5, 10_a, 10_b, 10_c, 10_d, and 10_e according to the embodiments, but the present disclosure is not limited thereto. For example, the display device 10 according to at least one of the embodiments described above may be included in electronic devices of other types or structures in addition to the electronic devices illustrated in FIGS. 23-28.

The display device according to one or more embodiments of the present disclosure can be applied to various electronic devices. The electronic device according to one or more embodiments of the present disclosure includes the display device described above, and may further include modules or devices having additional functions in addition to the display device.

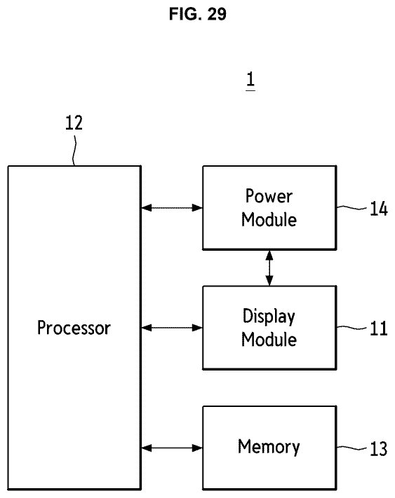

FIG. 29 is a block diagram of an electronic device according to one or more embodiments of the present disclosure.

Referring to FIG. 29, the electronic device 1 according to one or more embodiments of the present disclosure may include a display module 11, a processor 12, a memory 13, and a power module 14.

The display module 11 may include a display panel for displaying an image. For example, the display module 11 may include the display panel 100 according to at least one of the embodiments described above.

The processor 12 may include at least one of a central processing unit (CPU), an application processor (AP), a graphic processing unit (GPU), a communication processor (CP), an image signal processor (ISP), and/or a controller.

The memory 13 may store data information necessary for the operation of the processor 12 or the display module 11. The processor 12 may transmit an image data signal and/or an input control signal stored in the memory 13 to the display module 11. For example, the processor 12 executes an application stored in the memory 13, the image data signal and/or the input control signal is transmitted to the display module 11, and the display module 11 can process the received signal and output image information through a display screen.

The power module 14 may include a power supply module such as, for example a power adapter and/or a battery, and a power conversion module that converts the power supplied by the power supply module to generate power necessary for the operation of the electronic device 1.

At least one of the components of the electronic device 1 according to one or more embodiments of the present disclosure may be included in the display device according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 1 other than the display device 10.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A display device comprising:
a pixel located in a display area where an image is displayed, the pixel comprising a first sub-pixel comprising a first pixel circuit, a second sub-pixel comprising a second pixel circuit, and a third sub-pixel comprising a third pixel circuit;
a first emission control line electrically connected to the first pixel circuit;
a second emission control line electrically connected to the second pixel circuit and the third pixel circuit; and
first power lines electrically connected to the first pixel circuit, the second pixel circuit, and the third pixel circuit, the first power lines being arranged along a first direction in the display area and extending in a second direction,
wherein the first pixel circuit, the second pixel circuit, and the third pixel circuit are arranged along the first direction in the display area,
wherein the first pixel circuit overlaps a first power line of the first power lines, and
wherein the second pixel circuit and the third pixel circuit overlap an other first power line of the first power lines and have a symmetrical shape with respect to the other first power line.

2. The display device of claim 1, wherein the second pixel circuit and the third pixel circuit are commonly connected to the other first power line and have a symmetrical shape with respect to the other first power line.

3. The display device of claim 1, further comprising data lines arranged along the first direction in the display area, the data lines comprising a first data line electrically connected to the first pixel circuit, a second data line electrically connected to the second pixel circuit, and a third data line electrically connected to the third pixel circuit.

4. The display device of claim 3, wherein each of the first pixel circuit, the second pixel circuit, and the third pixel circuit comprises:
a first transistor configured to adjust a driving current in response to a data voltage transmitted from the first data line, the second data line, or the third data line; and
a second transistor electrically connected between the first data line, the second data line, or the third data line and the first transistor.

5. The display device of claim 4, wherein the first transistor comprises an active layer, a gate electrode overlapping a part of the active layer, and a source electrode and a drain electrode electrically connected to different portions of the active layer.

6. The display device of claim 5, wherein the first transistors of the first pixel circuit, the second pixel circuit, and the third pixel circuit are arranged sequentially along the first direction,
wherein the drain electrode of the first transistor in the first pixel circuit and the source electrode of the first transistor in the second pixel circuit are adjacent to each other in the first direction, and
wherein the drain electrode of the first transistor in the second pixel circuit and the drain electrode of the first transistor in the third pixel circuit are adjacent to each other in the first direction.

7. The display device of claim 4, wherein a size of the first transistor in the first pixel circuit is different from a size of the first transistor in each of the second pixel circuit and the third pixel circuit.

8. The display device of claim 4, wherein each of the first pixel circuit, the second pixel circuit, and the third pixel circuit further comprises a third transistor and a fourth transistor comprising an oxide semiconductor, which are commonly connected to a gate electrode of the first transistor through a first connection electrode, and
wherein the third transistor and the fourth transistor of the second pixel circuit are adjacent to the third transistor and the fourth transistor of the third pixel circuit in the first direction.

9. The display device of claim 8, wherein the first power line covers the first transistor, the third transistor, and the fourth transistor in the first pixel circuit, and
wherein the other first power line covers the first transistors, the third transistors, and the fourth transistors in the second pixel circuit and the third pixel circuit.

10. The display device of claim 4, wherein the first emission control line and the second emission control line are adjacent to each other in the second direction and extend in the first direction.

11. The display device of claim 10, wherein each of the first pixel circuit, the second pixel circuit, and the third pixel circuit further comprises a fifth transistor and a sixth transistor comprising respective active layers crossing the first emission control line and the second emission control line and respective gate electrodes overlapping parts of the respective active layers.

12. The display device of claim 11, wherein the active layer of the fifth transistor extends from one end of the active layer of the first transistor, has a U or Y shape around the first emission control line and the second emission control line, and crosses the first emission control line and the second emission control line, and
wherein the active layer of the sixth transistor extends from an other end of the active layer of the first transistor, and is electrically connected to a light emitting element located above the first pixel circuit, the second pixel circuit, or the third pixel circuit.

13. The display device of claim 12, wherein one end of the active layer of the fifth transistor is electrically connected to the first power line or the other first power line.

14. The display device of claim 13, wherein the second sub-pixel and the third sub-pixel further comprise one second connection electrode overlapping the other first power line and extending in the first direction in a region where the second pixel circuit and the third pixel circuit are located, and
wherein the active layers of the fifth transistors in the second pixel circuit and the third pixel circuit are commonly connected to the one second connection electrode and are electrically connected to the other first power line through the one second connection electrode.

15. The display device of claim 11, wherein the gate electrodes of the fifth transistor and the sixth transistor in the first pixel circuit are formed as one conductive pattern overlapping the first emission control line, and
wherein the one conductive pattern is electrically connected to the first emission control line through one contact hole located between the fifth transistor and the sixth transistor.

16. The display device of claim 11, wherein the gate electrodes of the fifth transistors and the sixth transistors in the second pixel circuit and the third pixel circuit are formed as one conductive pattern overlapping the second emission control line, and
wherein the one conductive pattern is electrically connected to the second emission control line through one contact hole located between the second pixel circuit and the third pixel circuit.

17. The display device of claim 3, wherein the first data line is located between a data line electrically connected to a third sub-pixel of another pixel adjacent to the first sub-pixel in the first direction and the first power line,
wherein the second data line is located between the first power line and the other first power line, and
wherein the third data line is located between the other first power line and a data line electrically connected to a first sub-pixel of another pixel adjacent to the third sub-pixel in the first direction.

18. The display device of claim 1, wherein the first sub-pixel further comprises a first light emitting element electrically connected to the first pixel circuit through a first anode contact hole overlapping the first pixel circuit,
wherein the second sub-pixel further comprises a second light emitting element electrically connected to the second pixel circuit through a second anode contact hole overlapping the second pixel circuit,
wherein the third sub-pixel further comprises a third light emitting element electrically connected to the third pixel circuit through a third anode contact hole overlapping the third pixel circuit, and
wherein the other first power line passes through a region between the second anode contact hole and the third anode contact hole.

19. The display device of claim 18, further comprising a second power line located between the first pixel circuit and the second pixel circuit, or between the pixel and another pixel adjacent to the pixel in the first direction,
wherein the second power line is electrically connected to the first light emitting element, the second light emitting element, and the third light emitting element through a cathode contact hole.

20. An electronic device comprising:
a display device comprising a display area where an image is displayed,
wherein the display device comprises:
a pixel located in the display area, the pixel comprising a first sub-pixel comprising a first pixel circuit, a second sub-pixel comprising a second pixel circuit, and a third sub-pixel comprising a third pixel circuit;
a first emission control line electrically connected to the first pixel circuit;
a second emission control line electrically connected to the second pixel circuit and the third pixel circuit; and
first power lines electrically connected to the first pixel circuit, the second pixel circuit, and the third pixel circuit, the first power lines being arranged along a first direction in the display area and extending in a second direction,
wherein the first pixel circuit, the second pixel circuit, and the third pixel circuit are arranged along the first direction in the display area,
wherein the first pixel circuit overlaps a first power line of the first power lines, and
wherein the second pixel circuit and the third pixel circuit overlap an other first power line of the first power lines and have a symmetrical shape with respect to the other first power line.
